(19) United States
(12) Patent Application Publication
(10) Pub. No.: US 2026/0231761 A1
(43) Pub. Date: Aug. 6, 2026

(54) SEMICONDUCTOR DEVICE

(71) Applicant: DENSO CORPORATION, Kariya-city (JP)

(72) Inventors: Norihisa IMAIZUMI, Kariya-city (JP); Yoshinori AKITSU, Kariya-city (JP); Hirotoshi KUSAMA, Kariya-city (JP)

(21) Appl. No.: 19/650,521

(22) Filed: Apr. 17, 2026

Related U.S. Application Data
(63) Continuation of application No. PCT/JP2024/036502, filed on Oct. 11, 2024.

(30) Foreign Application Priority Data
Oct. 19, 2023 (JP) 2023-180472
Oct. 1, 2024 (JP) 2024-172789

(51) Int. Cl. H10W 40/20; H10W 70/09; H10W 70/60; H10W 90/00; H10W 90/10; H10W 40/22

(52) U.S. Cl. CPC H10W 40/233; H10W 40/242; H10W 70/09; H10W 70/611; H10W 90/10; H10W 90/736; H10W 40/22

(57) ABSTRACT

A semiconductor device includes a semiconductor element, a heat sink, a core layer, a build-up layer, and a heat dissipation insulating layer. The heat sink has a front surface on which the semiconductor element is mounted and a back surface opposite to the front surface. The core layer has one surface and an opposite surface opposite to the one surface and is formed with a through-hole extending from the one surface to the opposite surface and in which the heat sink is disposed. The build-up layer is disposed to face the front surface and the one surface, and includes a wiring that includes a portion electrically connected to the semiconductor element. The heat dissipation insulating layer is in contact with the opposite surface of the core layer and the back surface of the heat sink.

### CROSS REFERENCE TO RELATED APPLICATIONS

The present application is a continuation application of International Patent Application No. PCT/JP2024/036502 filed on October 11, 2024, which designated the U.S. and claims the benefit of priority from Japanese Patent Application No. 2023-180472 filed on October 19, 2023 and Japanese Patent Application No. 2024-172789 filed on October 1, 2024. The entire disclosures of all of the above applications are incorporated herein by reference.

### TECHNICAL FIELD

The present disclosure relates to a semiconductor device.

### BACKGROUND

Conventionally, an example of a semiconductor device is a metal-oxide semiconductor (MOS)-transistor-built-in substrate. The MOS-transistor-built-in substrate includes four insulating resin layers and wiring layers located on respective surfaces of the insulating resin layers. Two MOS transistors are embedded in the third insulating resin layer. The electrode formed on the lower surface of the MOS transistor is connected to the wiring layer through a via conductor penetrating the first and second insulating resin layers. The electrode formed on the upper surface of the MOS transistor is connected to another wiring layer through a via conductor penetrating the third insulating resin layer.

### SUMMARY

According to an aspect of the present disclosure, a semiconductor device includes a semiconductor element, a heat sink, a core layer, a build-up layer, and a heat dissipation insulating layer. The heat sink has a front surface on which the semiconductor element is mounted and a back surface opposite to the front surface. The core layer has one surface and an opposite surface opposite to the one surface and is formed with a through-hole extending from the one surface to the opposite surface and in which the heat sink is disposed. The build-up layer is disposed to face the front surface and the one surface, and includes a wiring that includes a portion electrically connected to the semiconductor element. The heat dissipation insulating layer may be in contact with the opposite surface of the core layer and the back surface of the heat sink without passing through a via.

### BRIEF DESCRIPTION OF DRAWINGS

FIG. 1 is a plan view illustrating a schematic configuration of a semiconductor device in a first embodiment.

FIG. 2 is a cross-sectional view illustrating a schematic configuration of the semiconductor device.

FIG. 3 is a cross-sectional view illustrating a schematic configuration of a heat sink and a semiconductor element.

FIG. 4 is a partial cross-sectional view illustrating a schematic configuration of the semiconductor device.

FIG. 5 is a circuit diagram to which the semiconductor device is applied.

FIG. 6 is a process cross-sectional view illustrating a process of mounting the semiconductor element on the heat sink.

FIG. 7 is a process cross-sectional view illustrating a process of incorporating the semiconductor element in a wiring substrate.

FIG. 8 is a process cross-sectional view illustrating a process of forming wiring on the wiring substrate.

FIG. 9 is a cross-sectional view illustrating a schematic configuration of a heat sink and a semiconductor element of Modification 1.

FIG. 10 is a plan view illustrating a schematic configuration of a heat sink and a semiconductor element of Modification 2.

FIG. 11 is a cross-sectional view taken along line XI-XI of FIG. 10.

FIG. 12 is a cross-sectional view taken along line XII-XII of FIG. 10.

FIG. 13 is a plan view illustrating a schematic configuration of a heat sink of Modification 3.

FIG. 14 is a plan view illustrating a schematic configuration of a core layer of Modification 3.

FIG. 15 is a plan view illustrating a schematic configuration of the heat sink and the core layer of Modification 3.

FIG. 16 is a cross-sectional view illustrating a schematic configuration of a heat sink and a core layer of Modification 4.

FIG. 17 is a cross-sectional view taken along line XVII-XVII of FIG. 16.

FIG. 18 is a plan view illustrating a schematic configuration of a semiconductor device in a second embodiment.

FIG. 19 is a cross-sectional view illustrating a schematic configuration of a semiconductor device in a third embodiment.

FIG. 20 is a cross-sectional view illustrating a schematic configuration of a semiconductor device in a fourth embodiment.

FIG. 21 is a cross-sectional view illustrating a schematic configuration of a semiconductor device in a fifth embodiment.

FIG. 22 is a cross-sectional view illustrating a schematic configuration of a semiconductor device in a sixth embodiment.

FIG. 23 is a cross-sectional view illustrating a schematic configuration of a heat sink and a semiconductor element of Modification 5.

FIG. 24 is a cross-sectional view illustrating a schematic configuration of a heat sink and a semiconductor element of Modification 6.

FIG. 25 is a cross-sectional view illustrating a schematic configuration of a semiconductor device in a seventh embodiment.

FIG. 26 is a cross-sectional view illustrating a schematic configuration of a semiconductor device in an eighth embodiment.

FIG. 27 is a cross-sectional view illustrating a schematic configuration of a semiconductor device in a ninth embodiment.

FIG. 28 is a circuit diagram to which a semiconductor device according to a tenth embodiment is applied.

FIG. 29 is a cross-sectional view illustrating a schematic configuration of the semiconductor device in the tenth embodiment.

FIG. 30 is a circuit diagram to which a semiconductor device according to an eleventh embodiment is applied.

FIG. 31 is a cross-sectional view illustrating a schematic configuration of the semiconductor device in the eleventh embodiment.

FIG. 32 is a circuit diagram to which a semiconductor device according to a twelfth embodiment is applied.

FIG. 33 is a cross-sectional view illustrating a schematic configuration of a semiconductor device in a twelfth embodiment.

FIG. 34 is a cross-sectional view illustrating a schematic configuration of a semiconductor device in a modification.

FIG. 35 is a cross-sectional view illustrating a schematic configuration of a heat sink in a modification.

FIG. 36 is an enlarged cross-sectional view of a portion XXXVI in FIG. 34.

FIG. 37 is a cross-sectional view illustrating a schematic configuration of a semiconductor device in a modification.

FIG. 38 is a cross-sectional view illustrating a schematic configuration of a semiconductor device in a modification.

FIG. 39 is a process cross-sectional view illustrating a manufacturing method for a semiconductor device in a modification.

FIG. 40 is a cross-sectional view illustrating a schematic configuration of a semiconductor device in a modification.

FIG. 41 is an enlarged cross-sectional view illustrating a schematic configuration of a semiconductor device in a modification.

FIG. 42 is a cross-sectional view illustrating a schematic configuration of a semiconductor device before cutting according to a modification.

FIG. 43 is a cross-sectional view illustrating a schematic configuration of a core layer in a modification.

FIG. 44 is a plan view illustrating a schematic configuration of a core layer in a modification.

FIG. 45 is a plan view illustrating a schematic configuration of a core layer in a modification.

FIG. 46 is a cross-sectional view illustrating a schematic configuration of a core layer in a modification.

FIG. 47 is a cross-sectional view illustrating a schematic configuration of a semiconductor device in a modification.

FIG. 48 is a cross-sectional view illustrating a manufacturing method for a heat sink in a modification.

FIG. 49 is a plan view illustrating a schematic configuration of a heat sink in a modification.

FIG. 50 is a cross-sectional view taken along line L-L in FIG. 49.

FIG. 51 is a cross-sectional view taken along line LI-LI in FIG. 49.

FIG. 52 is a plan view illustrating a schematic configuration of a heat sink according to a modification.

FIG. 53 is a cross-sectional view taken along line LIII-LIII in FIG. 52.

FIG. 54 is a cross-sectional view taken along line LIV-LIV in FIG. 52.

FIG. 55 is a cross-sectional view illustrating a schematic configuration of a semiconductor device in a thirteenth embodiment.

FIG. 56 is a process cross-sectional view illustrating a process of incorporating the semiconductor element in a wiring substrate.

FIG. 57 is a process cross-sectional view illustrating a process of forming wiring on the wiring substrate.

FIG. 58 is a cross-sectional view illustrating a schematic configuration of a heat sink in a modification.

FIG. 59 is a cross-sectional view illustrating a schematic configuration of a heat sink in a modification.

FIG. 60 is a cross-sectional view illustrating a schematic configuration of a semiconductor device in a modification.

FIG. 61 is a cross-sectional view illustrating a manufacturing method for a semiconductor device in a modification.

FIG. 62 is a cross-sectional view illustrating a manufacturing method for a semiconductor device in a modification.

FIG. 63 is a cross-sectional view illustrating a schematic configuration of a heat sink in a modification.

FIG. 64 is a cross-sectional view taken along line LXIV-LXIV of FIG. 63.

FIG. 65 is a cross-sectional view illustrating a schematic configuration of a heat sink in a modification.

FIG. 66 is a cross-sectional view taken along line LXVI-LXVI of FIG. 65.

FIG. 67 is a cross-sectional view illustrating a schematic configuration of a semiconductor device in a modification.

FIG. 68 is a plan view illustrating a schematic configuration of a semiconductor element in a modification.

FIG. 69 is a cross-sectional view illustrating a manufacturing method for a semiconductor device in a modification.

FIG. 70 is a plan view illustrating a schematic configuration of a core layer in a modification.

FIG. 71 is a cross-sectional view taken along line LXXI-LXXI of FIG. 70 with a heat sink attached.

FIG. 72 is a cross-sectional view of a state in which a heat dissipation insulating layer and a build-up layer are provided on the heat sink.

FIG. 73 is a partial cross-sectional view illustrating a schematic configuration of a heat sink in a modification.

FIG. 74 is a partial cross-sectional view illustrating a state in which a build-up layer and a heat dissipation insulating layer are provided in a modification.

FIG. 75 is a partial plan view illustrating a schematic configuration of a heat sink in a modification.

FIG. 76 is a cross-sectional view illustrating a schematic configuration of a semiconductor device in a fourteenth embodiment.

FIG. 77 is a process cross-sectional view illustrating a manufacturing method for the semiconductor device of the fourteenth embodiment.

FIG. 78 is a cross-sectional view illustrating a schematic configuration of a semiconductor device in a modification.

FIG. 79 is a partial cross-sectional view illustrating a schematic configuration of a semiconductor element in a modification.

FIG. 80 is a cross-sectional view illustrating a schematic configuration of a semiconductor device in a modification.

FIG. 81 is a cross-sectional view taken along line LXXXI-LXXXI in FIG. 80.

FIG. 82 is a plan view illustrating a schematic configuration of a semiconductor device in a modification.

FIG. 83 is a cross-sectional view taken along line LXXXIII-LXXXIII of FIG. 82.

FIG. 84 is a partial cross-sectional view illustrating a schematic configuration of a semiconductor device in a modification.

FIG. 85 is a partial cross-sectional view illustrating a schematic configuration of a semiconductor device in a modification.

FIG. 86 is a plan view illustrating a heat sink, a core layer, and a semiconductor element in a modification.

FIG. 87 is a plan view illustrating wiring of a first layer LA1 in the modification.

FIG. 88 is a plan view illustrating wiring of a second layer LA2 in the modification.

FIG. 89 is a plan view illustrating overlapping of wiring in the modification.

FIG. 90 is a cross-sectional view taken along line XC-XC in FIG. 89.

FIG. 91 is a cross-sectional view taken along line XCI-XCI of FIG. 89.

FIG. 92 is a cross-sectional view taken along line XCII-XCII of FIG. 89.

FIG. 93 is a plan view illustrating a heat sink, a core layer, and a semiconductor element in a modification.

FIG. 94 is a plan view illustrating wiring according to the modification.

FIG. 95 is a cross-sectional view taken along line XCV-XCV of FIG. 94.

FIG. 96 is a plan view illustrating a heat sink, a core layer, and a semiconductor element in a modification.

FIG. 97 is a plan view illustrating wiring of a first layer LA1 in the modification.

FIG. 98 is a plan view illustrating wiring of a second layer LA2 in the modification.

FIG. 99 is a plan view illustrating overlapping of wiring in the modification.

FIG. 100 is a cross-sectional view taken along line C-C in FIG. 99.

FIG. 101 is a cross-sectional view taken along line CI-CI of FIG. 99.

FIG. 102 is a cross-sectional view illustrating a schematic configuration of an integrated substrate in a modification.

FIG. 103 is a plan view illustrating a schematic configuration of a semiconductor device in a modification.

FIG. 104 is a plan view illustrating a schematic configuration of a semiconductor device in a modification.

FIG. 105 is a plan view illustrating a schematic configuration of a core layer in a modification.

FIG. 106 is a cross-sectional view taken along line CVI-CVI in FIG. 105.

FIG. 107 is a plan view illustrating a schematic configuration of a heat sink according to a modification.

### DETAILED DESCRIPTION

In a MOS-transistor-built-in substrate, both the electrode on the lower surface and the electrode on the upper surface are connected to the wiring layer through the via conductors. Therefore, in the MOS-transistor-built-in substrate, heat dissipation performance is likely to be insufficient. From the above viewpoint or from other viewpoints not mentioned, further improvement is required for semiconductor devices.

The present disclosure provides a semiconductor device with improved heat dissipation performance.

According to an aspect of the present disclosure, a semiconductor device includes a semiconductor element, a heat sink, a core layer, a build-up layer, and a heat dissipation insulating layer. The heat sink has a front surface on which the semiconductor element is mounted and a back surface opposite to the front surface. The core layer has one surface and an opposite surface opposite to the one surface and is formed with a through-hole extending from the one surface to the opposite surface and in which the heat sink is disposed. The build-up layer is disposed to face the front surface and the one surface, and includes a wiring that includes a portion electrically connected to the semiconductor element. The heat dissipation insulating layer is in contact with the opposite surface of the core layer and the back surface of the heat sink.

As described above, the semiconductor device includes the heat dissipation insulating layer in contact with the back surface of the heat sink and the opposite surface of the core layer. Therefore, the semiconductor device can improve the heat dissipation performance as compared with a configuration in which a heat sink and a heat dissipation insulating layer are connected through a via.

According to another aspect of the present disclosure, a semiconductor device includes a plurality of semiconductor elements, a plurality of heat sinks, a plurality of heat dissipation insulating layers, a plurality of back-surface metal layers, a core layer, and a build-up layer. The plurality of heat sinks are provided for the respective semiconductor elements and each heat sink has a front surface on which a corresponding semiconductor element is mounted, and a back surface opposite to the front surface. The plurality of heat dissipation insulating layers are provided for the respective heat sinks and each heat dissipation insulating layer is in contact with the back surface of a corresponding heat sink. Each of the plurality of back-surface metal layers is in contact with a surface of a corresponding heat dissipation insulating layer opposite to the corresponding heat sink. The core layer has one surface and an opposite surface opposite to the one surface and is formed with a plurality of through-holes extending from the one surface to the opposite surface, and a set of the semiconductor element, the heat sink, the heat dissipation insulating layer, and the back-surface metal layer is disposed in each of the through holes. The build-up layer is disposed to face the front surface and the one surface, and includes a wiring that includes a portion electrically connected to the corresponding semiconductor element.

As described above, the semiconductor device includes the heat dissipation insulating layer in contact with the back surface of the heat sink and the back-surface metal layer in contact with the surface side of the heat dissipation insulating layer opposite to the heat sink. Therefore, the semiconductor device can improve the heat dissipation performance as compared with the configuration in which the heat sink and the heat dissipation insulating layer are connected through vias.

A plurality of aspects disclosed in the present specification employ different technical means to achieve their respective objects. Objects, features, and effects disclosed in the present specification will become more apparent by referring to the following detailed description of embodiments and the accompanying drawings.

Hereinafter, a plurality of embodiments for carrying out the present disclosure will be described with reference to the drawings. In each embodiment, portions corresponding to an item described in the prior embodiment are denoted by the same reference numerals, and redundant explanation may be omitted. In each embodiment, when only a part of a configuration is described, the other parts of the configuration can be applied with reference to other embodiments described above.

### (First Embodiment)

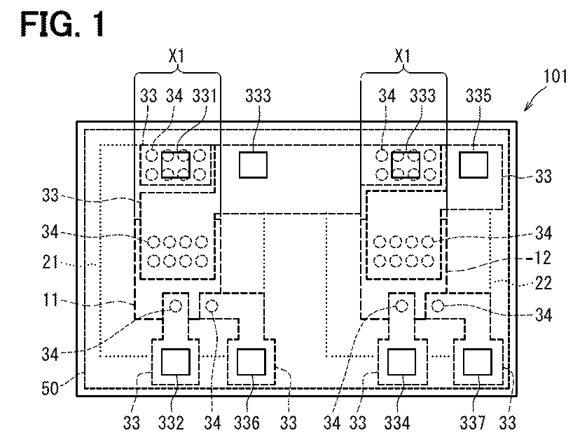

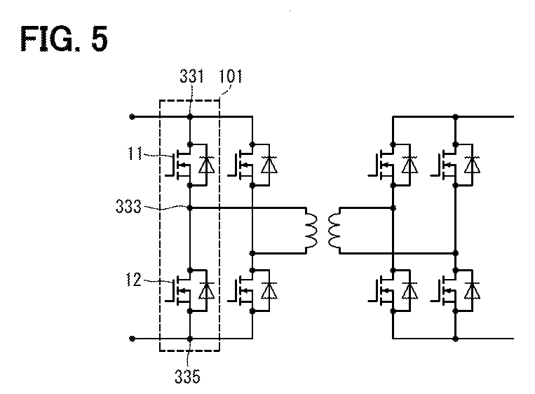

A semiconductor device 101 of a first embodiment will be described with reference to FIGS. 1 to 8. The semiconductor device 101 can be applied to, for example, a power converter. Further, the semiconductor device 101 can be applied to an in-vehicle substation or charger. In the present embodiment, as an example, a semiconductor device 101 including two semiconductor elements 11, 12 is employed. As illustrated in FIG. 5, the two semiconductor elements 11, 12 are connected in series. The first semiconductor element 11 is an upper arm element. The second semiconductor element 12 is a lower arm element. However, the semiconductor device 101 only needs to include at least one semiconductor element.

### <Overall Configuration of Semiconductor Device>

The semiconductor device 101 includes the semiconductor elements 11, 12, heat sinks 21, 22, a wiring substrate 30, a heat dissipation insulating layer 40, a back-surface metal layer 50, and the like. The semiconductor device 101 has a structure in which the semiconductor elements 11, 12 and the heat sinks 21, 22 are incorporated in the wiring substrate 30. The semiconductor device 101 can also be referred to as a semiconductor package or a power semiconductor package.

The semiconductor elements 11, 12 generate heat by operation. Therefore, the semiconductor device 101 is provided with the heat sinks 21, 22. The heat dissipation insulating layer 40 is joined to the heat sinks 21, 22. The back-surface metal layer 50 is joined to the surface of the heat dissipation insulating layer 40 opposite to the surface to which the heat sinks 21, 22 are joined. In the semiconductor device 101, the back-surface metal layer 50 is provided as a part of a portion exposed to the outside.

Therefore, the heat of the semiconductor elements 11, 12 is transferred to the heat dissipation insulating layer 40 and the back-surface metal layer 50 through the heat sinks 21, 22. The heat of the semiconductor elements 11, 12 is dissipated from the back-surface metal layer 50 to the outside of the semiconductor device 101.

### <Semiconductor Element>

The first semiconductor element 11 and the second semiconductor element 12 have the same configuration. For this reason, the first semiconductor element 11 will be described below. Hereinafter, the first semiconductor element 11 is also referred to simply as the semiconductor element 11. These points also apply to other modifications and the like.

As the semiconductor element 11, for example, metal-oxide-semiconductor field-effect transistor (MOSFET), an insulated gate bipolar transistor (IGBT), a transistor, or the like can be employed. It can also be said that a semiconductor switching element can be employed as the semiconductor element 11. The semiconductor element 11 can also be referred to as a power element. Here, a vertical semiconductor element having a vertical structure is employed as the semiconductor element 11. The semiconductor element 11 can employ Si, SiC, GaN, or the like as main constituents. That is, as the semiconductor element 11, for example, a Si-IGBT, a SiC-MOSFET, a GaN-transistor, or the like can be employed. The IGBT may be a reverse-conducting insulated gate bipolar transistor (RC-IGBT).

Moreover, the semiconductor element 11 may be a lateral semiconductor element having a lateral structure. Examples of the lateral semiconductor element include a GaN-based lateral transistor mainly composed of GaN. In the lateral semiconductor element, a gate electrode, a source electrode, a drain electrode, and the like are formed on an element front surface S12 to be described later. For stable operation, the back surface potential of the lateral semiconductor element is connected to the source electrode on the element front surface S12 side. Similarly, in the configuration in which the wiring substrate 30 includes the lateral semiconductor element, wiring from the heat sink 21 to the element front surface S12 is required.

In the present embodiment, similar elements are employed as the first semiconductor element 11 and the second semiconductor element 12. However, the first semiconductor element 11 and the second semiconductor element 12 may differ from each other. For example, the first semiconductor element 11 and the second semiconductor element 12 may differ in size or type.

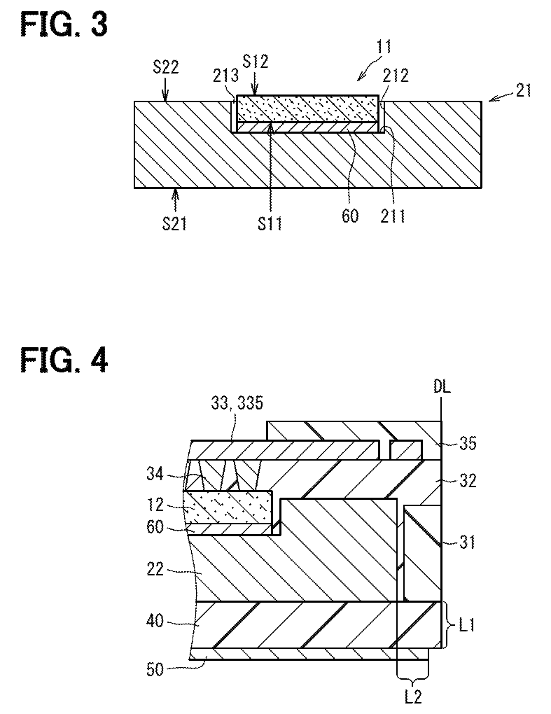

As illustrated in FIG. 3, the semiconductor element 11 has an element facing surface S11 that faces the heat sink 21 (bottom portion 211), and the element front surface S12 that is the surface opposite to the element facing surface S11. The semiconductor element 11 has, for example, an element facing surface S11, which is a flat surface, and an element front surface S12, which is a flat surface.

The semiconductor element 11 includes electrodes on the element facing surface S11 and the element front surface S12. The semiconductor element 11 includes a gate electrode, a source electrode, and a Kelvin source electrode on the element front surface S12. In addition, the semiconductor element 11 includes a drain electrode on the element facing surface S11. Copper plating or the like is applied to the front surface of each electrode to improve connectivity with a via 34 or the like.

### <Heat Sink>

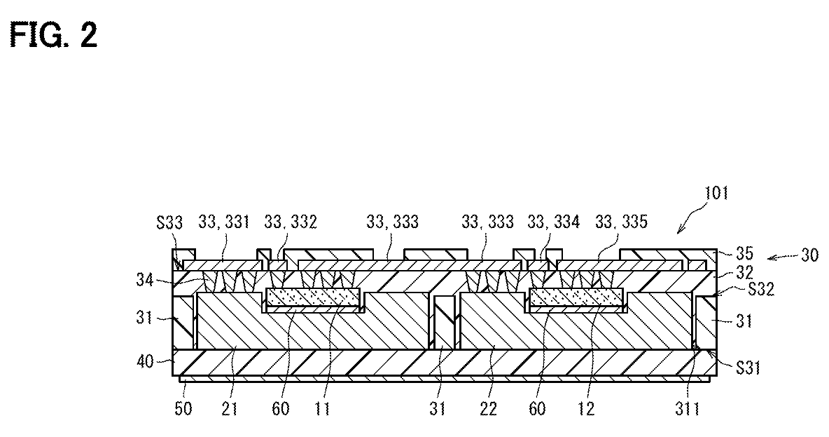

As illustrated in FIGS. 1 and 2, the semiconductor device 101 includes two heat sinks 21, 22. The first semiconductor element 11 is mounted on the first heat sink 21. The second semiconductor element 12 is mounted on the second heat sink 22. As described above, in the two heat sinks 21, 22, the two semiconductor elements 11, 12 are individually mounted.

The heat sinks 21, 22 have the same configuration. For this reason, the first heat sink 21 will be described below. The first heat sink 21 is also referred to simply as the heat sink 21. These points also apply to other modifications and the like.

As illustrated in FIGS. 1, 2, and 3, the heat sink 21 has a heat sink front surface S22 and a heat sink opposite surface S21 that is the surface opposite to the heat sink front surface S22. The heat sink front surface S22 and the heat sink opposite surface S21 are, for example, flat surfaces. The heat sink front surface S22 corresponds to the front surface of the heat sink 21. The heat sink opposite surface S21 corresponds to the back surface of the heat sink 21. The heat sink front surface S22 is also referred to as the front surface S22, and the heat sink opposite surface S21 is also referred to as the back surface S21.

The heat sink 21 is a plate-shaped or block-shaped member. The heat sink 21 is mainly composed of a metal such as aluminum or copper. The heat sink 21 is made of a member having higher thermal conductivity than the core layer 31 to be described later.

As illustrated in FIG. 3, the heat sink 21 is provided with a recess 213 recessed relative to the heat sink front surface S22. The recess 213 is a portion in which the semiconductor element 11 is mounted. The recess 213 is formed by a bottom portion 211 and an annular side wall 212. The side wall 212 is a surface continuous with the bottom portion 211 and the heat sink front surface S22. The bottom portion 211 is, for example, a flat surface. The state in which the semiconductor element 11 is mounted in the recess 213 can also be referred to as an element mounted state.

As illustrated in FIG. 2, the heat sink 21 has substantially the same thickness as the core layer 31. That is, the heat sink 21 has a sufficient thickness as compared with pattern wiring 33 to be described later. Therefore, the heat sink 21 has a greater heat capacity than the pattern wiring 33. The heat sink 21 has a plate thickness greater than the pattern wiring 33.

The thickness of the heat sink 21 differs between a portion in which the recess 213 is provided and a peripheral portion thereof. The thickness of the peripheral portion is sufficiently greater than the thickness of the pattern wiring 33. The thickness of the portion in which the recess 213 is provided is sufficiently greater than the thickness of the pattern wiring 33. The thickness of the portion in which the recess 213 is provided corresponds to the distance between the bottom portion 211 and the heat sink opposite surface S21. The thickness of the peripheral portion corresponds to the distance between the heat sink front surface S22 and the heat sink opposite surface S21.

The thickness here is a length along a virtual straight line orthogonal to the heat sink front surface S22 and the heat sink opposite surface S21. The virtual straight line coincides with the thickness direction of the heat sink 21 and the depth direction of the recess 213. The thickness direction of the heat sink 21 can also be referred to as a plate thickness direction. The thickness direction of the heat sink 21 and the like can also be referred to as a stacking direction of the semiconductor element 11 relative to the heat sink 21. A direction orthogonal to the stacking direction is also referred to as a planar direction.

The semiconductor element 11 is mounted in the recess 213 through a connection member 60. The semiconductor element 11 is electrically connected to the heat sink 21 through the connection member 60. The connection member 60 connects the drain electrode of the semiconductor element 11 and the heat sink 21. The connection member 60 is a joining material having conductivity. For example, a metal sintered material such as silver or copper can be employed as the connection member 60. The connection member 60 can also be referred to as a die attach material, a die bonding material, or the like. The recess 213 has an opening area sufficient to avoid contact between the side wall 212 and the semiconductor element 11.

As will be described later, in a manufacturing method for the semiconductor device 101, the semiconductor element 11 is mounted in the recess 213 by pressurizing (pressing) the semiconductor element 11 while the connection member 60 is disposed between the semiconductor element and the bottom portion 211 (die attach joining process). Therefore, the depth of the recess 213 is preferably shallower than the sum of the thickness of the semiconductor element 11 and the thickness of the connection member 60. Thus, pressure can be appropriately applied to the semiconductor element 11.

Therefore, in the element mounted state, the element front surface S12 is preferably at a position higher than the heat sink front surface S22. That is, the semiconductor element 11 is mounted in the recess 213 such that the element front surface S12 projects from the heat sink front surface S22. In the element mounted state, the element front surface S12 may be on the same virtual plane as the heat sink front surface S22. The virtual plane is a plane substantially parallel to the element front surface S12 and the heat sink front surface S22.

The thickness of the semiconductor element 11 corresponds to the distance between the element front surface S12 and the element facing surface S11. The thickness of the semiconductor element 11 can also be referred to as a length along the virtual straight line.

### <Wiring Substrate>

As illustrated in FIGS. 1 and 2, the wiring substrate 30 includes a core layer 31, a build-up layer 32, and a solder resist 35. The core layer 31 is provided with the heat dissipation insulating layer 40. The heat dissipation insulating layer 40 is provided with the back-surface metal layer 50. Thus, it can also be said that the wiring substrate 30 includes the heat dissipation insulating layer 40 and the back-surface metal layer 50.

In FIG. 1, a portion exposed from the solder resist 35 is indicated by a solid line, and a portion hidden by the solder resist 35 or the like is indicated by a broken line. FIG. 2 is a view illustrating cross sections of the semiconductor elements 11, 12, the heat sinks 21, 22, the core layer 31, the build-up layer 32, pads 331 to 335, and the solder resist 35.

As illustrated in FIG. 2, the core layer 31 has a core front surface S32 and a core opposite surface S31 that is the surface opposite to the core front surface S32. The core front surface S32 corresponds to one surface. The core opposite surface S31 corresponds to the opposite surface. The core layer 31 is mainly composed of an electrically insulating member. The core layer 31 is configured by stacking a plurality of electrically insulating resin layers, for example. The resin layer is equivalent to the pattern wiring 33 to be described later, or is thicker than the pattern wiring 33. Therefore, the core layer 31 is a member sufficiently thicker than the pattern wiring 33. The thickness of the core layer 31 is a length in the same direction as the thickness of the heat sink 21. The core layer 31 may be a single electrically insulating resin member having substantially the same thickness as a stack of a plurality of resin layers. The core layer 31 can also be referred to as a core material.

In the core layer 31, a through-hole 311 is provided extending from the core front surface S32 to the core opposite surface S31. The through-hole 311 is a region in which the heat sinks 21, 22 are disposed. The through-hole 311 has an opening area sufficient to form a gap with the heat sinks 21, 22.

The core layer 31 is provided with two through-holes 311 in which the two heat sinks 21, 22 are individually disposed. That is, the core layer 31 is provided with the through-hole 311 in which the first heat sink 21 is disposed and the through-hole 311 in which the second heat sink 22 is disposed. In this manner, the core layer 31 is provided with the same number of through-holes 311 as the heat sinks 21, 22. In the through-hole 311, the first heat sink 21 with the first semiconductor element 11 mounted therein and the second heat sink 22 with the second semiconductor element 12 mounted therein are disposed.

As illustrated in FIG. 2, the build-up layer 32 is provided on the core front surface S32. The build-up layer 32 is provided to face the core front surface S32 and the heat sink front surface S22. Moreover, the build-up layer 32 is also provided to face the element front surface S12.

The build-up layer 32 includes an electrically insulating resin portion and conductive wiring. The build-up layer 32 is provided to lead out the wiring. The build-up layer 32 can also be referred to as a wiring layer. Hereinafter, the resin portion of the build-up layer 32 is also referred to simply as the resin portion.

The resin portion is provided in contact with the element front surface S12, the heat sink front surface S22, and the core front surface S32. The resin portion is also provided in a gap between the heat sinks 21, 22 and the core layer 31. The resin portion is in contact with the heat sinks 21, 22 and the core layer 31 in the gap. Thus, the resin portion covers the semiconductor elements 11, 12 and the heat sinks 21, 22. The resin portion includes a layer front surface S33. The layer front surface S33 is a surface substantially parallel to the core front surface S32 and the element front surface S12.

As illustrated in FIGS. 1 and 2, the wiring includes the pattern wiring 33 and the via 34. The pattern wiring 33 is provided on the layer front surface S33. The pattern wiring 33 is provided to face the core front surface S32 and the element front surface S12. In other words, the pattern wiring 33 includes a portion facing the core front surface S32 and a portion facing the element front surface S12. The pattern wiring 33 is provided at a plurality of locations. That is, the pattern wiring 33 is formed by patterning a thin film of copper or the like. The pattern wiring 33 is a part of layer wiring. The pattern wiring 33 corresponds to the main wiring. The pattern wiring 33 and the via 34 correspond to a portion electrically connected to the semiconductor element 11.

The pattern wiring 33 is covered with the solder resist 35 while being partially exposed. The pattern wiring 33 includes pads 331 to 337 that are portions exposed from the solder resist 35. That is, the pattern wiring 33 includes a P pad 331, a first gate pad 332, an O pad 333, a second gate pad 334, an N pad 335, a first Kelvin source pad 336, and a second Kelvin source pad 337.

As illustrated in FIG. 5, the P pad 331 is a terminal on the high-potential side. The N pad 335 is a terminal on the low-potential side. The O pad 333 is an output terminal. Each of the pads 331 to 337 is, for example, a portion electrically connected to a circuit board provided outside the semiconductor device 101. The pads 331 to 337 can also be referred to as electrodes or external connection portions. The P pad 331, the O pad 333, and the N pad 335 can also be referred to as power connection portions. The first gate pad 332, the second gate pad 334, the first Kelvin source pad 336, and the second Kelvin source pad 337 can also be referred to as signal connection portions. Hereinafter, the first gate pad 332, the second gate pad 334, the first Kelvin source pad 336, and the second Kelvin source pad 337 are also collectively referred to as signal pads 332.

As illustrated in FIG. 1, the pattern wiring 33 is divided into portions including the respective pads 331 to 337. The portion including each of the pads 331 to 337 in the pattern wiring 33 will be described using a name obtained by replacing “pad” in each of the pads 331 to 337 with “wiring portion”. That is, the portion including the P pad 331 is referred to as a P wiring portion. The portion including the first gate pad 332 is referred to as a first gate wiring portion. The portion including the O pad 333 is referred to as an O wiring portion. The portion including the second gate pad 334 is referred to as a second gate wiring portion. The portion including the N pad 335 is referred to as an N wiring portion. The portion including the first Kelvin source pad 336 is referred to as a first Kelvin source wiring portion. The portion including the second Kelvin source pad 337 is referred to as a second Kelvin source wiring portion.

The P wiring portion is provided to face a peripheral portion of the first semiconductor element 11 in the first heat sink 21. The P wiring portion is connected to the first heat sink 21 through the via 34. Here, an example in which the P wiring portion and the first heat sink 21 are connected by a plurality of vias 34 is employed. The P wiring portion is provided to face a part of the heat sink front surface S22.

The O wiring portion is provided extending from above the source electrode of the first semiconductor element 11 to a peripheral portion of the second semiconductor element 12 in the second heat sink 22. The O wiring portion is connected to the source electrode of the first semiconductor element 11 and the second heat sink 22 through the via 34. Here, an example in which the O wiring portion and the source electrode are connected by a plurality of vias 34 is employed. Similarly, an example in which the O wiring portion and the second heat sink 22 are connected by a plurality of vias 34 is employed. The O wiring portion is provided to face a part of the heat sink front surface S22.

In this manner, the O wiring portion electrically connects the source electrode of the first semiconductor element 11 and the drain electrode of the second semiconductor element 12. That is, the pattern wiring 33 electrically connects the first semiconductor element 11 and the second semiconductor element 12.

The N wiring portion is provided extending from above the source electrode of the second semiconductor element 12 to outside of the facing region of the second semiconductor element 12. The N wiring portion is connected to the source electrode of the second semiconductor element 12 through the via 34. Here, an example in which the N wiring portion and the source electrode are connected by a plurality of vias 34 is employed.

The first gate wiring portion is provided extending from above the gate electrode of the first semiconductor element 11 to outside of the facing region of the first semiconductor element 11. The first gate wiring portion is connected to the gate electrode of the first semiconductor element 11 through the via 34. The second gate wiring portion is provided extending from above the gate electrode of the second semiconductor element 12 to outside of the facing region of the second semiconductor element 12. The second gate wiring portion is connected to the gate electrode of the second semiconductor element 12 through the via 34.

The first Kelvin source wiring portion is provided extending from above the Kelvin source electrode of the first semiconductor element 11 to outside of the facing region of the first semiconductor element 11. The first Kelvin source wiring portion is connected to the Kelvin source electrode of the first semiconductor element 11 through the via 34. The second Kelvin source wiring portion is provided extending from above the Kelvin source electrode of the second semiconductor element 12 to outside of the facing region of the second semiconductor element 12. The second Kelvin source wiring portion is connected to the Kelvin source electrode of the second semiconductor element 12 through the via 34.

As illustrated in FIG. 1, the P pad 331, the O pad 333, and the N pad 335 are arranged closer to the same direction on the wiring substrate 30. That is, the P pad 331, the O pad 333, and the N pad 335 are arranged closer to one side surface of the wiring substrate 30. Moreover, the via 34 for the drain electrode is preferably provided in a region narrower than a width X1 of each of the semiconductor elements 11, 12. This makes it possible to form mutual inductance between the drain wiring and the source wiring and to reduce the total inductance.

The vias 34 for the drain electrode are the via 34 connected to the P wiring portion and the via 34 connected to the second heat sink 22. The width direction of each of the semiconductor elements 11, 12 coincides with the arrangement direction of the two semiconductor elements 11, 12.

The vias 34 are provided at a plurality of locations in the resin portion. The build-up layer 32 includes the via 34 electrically connected to each of the gate electrode, the source electrode, and the Kelvin source electrode of the first semiconductor element 11, and the gate electrode, the source electrode, and the Kelvin source electrode of the second semiconductor element 12. The build-up layer 32 also includes the via 34 electrically connected to each of the first heat sink 21 and the second heat sink 22. A plurality of vias 34 are connected to each source electrode. Similarly, a plurality of vias 34 are connected to the respective heat sinks 21, 22.

In this manner, one wiring substrate 30 incorporates the two semiconductor elements 11, 12, and is provided with the O wiring portion that electrically connects the two semiconductor elements 11, 12. Therefore, the semiconductor device 101 can shorten the O wiring portion connecting the two semiconductor elements 11, 12. The semiconductor device 101 can reduce inductance by shortening the O wiring portion, and can improve the switching characteristics of the semiconductor elements 11, 12.

It can also be said that the wiring substrate 30 incorporates the heat sinks 21, 22 on which the semiconductor elements 11, 12 are mounted. Moreover, it can also be said that the two semiconductor elements 11, 12 are incorporated in one semiconductor package.

As illustrated in FIG. 2, the heat dissipation insulating layer 40 is provided on the core opposite surface S31 and the heat sink opposite surface S21. The heat dissipation insulating layer 40 is in contact with the core opposite surface S31 and the heat sink opposite surface S21. It can also be said that the heat dissipation insulating layer 40 is directly connected to the core opposite surface S31 and the heat sink opposite surface S21. The heat dissipation insulating layer 40 contains a filler having good thermal conductivity and an electrically insulating resin containing the filler. That is, the heat dissipation insulating layer 40 contains a filler and an electrically insulating resin. The heat dissipation insulating layer 40 has high thermal conductivity and is an electrically insulating layer.

The heat dissipation insulating layer 40 is mainly provided to dissipate heat transferred to the heat sinks 21, 22. The heat dissipation insulating layer 40 is provided to reduce thermal resistance between the heat sinks 21, 22 and the back-surface metal layer 50 while electrically insulating the heat sinks 21, 22 and the back-surface metal layer 50.

As described above, in the wiring substrate 30, a build-up layer including wiring such as a via is not provided on the core opposite surface S31 side of the core layer 31. That is, the core layer 31 and the heat sinks 21, 22 are connected to the heat dissipation insulating layer 40 without passing through the vias 34.

The relative permittivity of the heat dissipation insulating layer 40 is defined as Er2, and the relative permittivity of the build-up layer 32 is defined as Er1. It is preferable that Er1 < Er2. This enables the semiconductor device 101 to reduce leakage of common-mode noise from the heat dissipation insulating layer 40 to the outside. The thickness between the heat sink front surface S22 of the build-up layer 32 and the pattern wiring is defined as t1, and the thickness of the heat dissipation insulating layer 40 is defined as t2. In this case, Er1/t1 > Er2/t2 may hold. The parameter t2 corresponds to the spacing between the back-surface metal layer 50 and the heat sinks 21, 22.

As illustrated in FIG. 2, the back-surface metal layer 50 is provided in contact with the heat dissipation insulating layer 40. The back-surface metal layer 50 is, for example, a thin film mainly composed of a metal such as copper. As illustrated in FIGS. 1 and 4, it is preferable that the back-surface metal layer 50 also has a wide facing region between the heat sinks 21, 22. Therefore, the back-surface metal layer 50 includes an extension L2 provided to extend beyond the end portions of the heat sinks 21, 22. The facing region can also be referred to as a projected region in the plate thickness direction. The surface of the heat dissipation insulating layer 40 on which the back-surface metal layer 50 is provided can also be referred to as a metal formed surface.

Here, the thickness of the heat dissipation insulating layer 40 is defined as L1. The relationship between L1 and L2 is preferably L1 < L2. As a result, the semiconductor device 101 can improve the heat dissipation performance from the back-surface metal layer 50.

It is preferable that the heat dissipation insulating layer 40 does not contain glass cloth. That is, the heat dissipation insulating layer 40 contains the filler and the electrically insulating resin without containing glass cloth. The heat dissipation insulating layer 40 is made only of, for example, a filler and a resin. Thus, the heat dissipation insulating layer 40 can contain a greater amount of filler than in a configuration containing glass cloth. As described above, the filler has good thermal conductivity. The filler is a member for improving heat dissipation performance. Accordingly, the heat dissipation insulating layer 40 can realize high heat dissipation. Glass cloth corresponds to glass fiber.

The semiconductor device 101 is divided by dicing or the like from a multiple substrate on which a plurality of structures to be the semiconductor device 101 are formed. Thus, the side wall of the semiconductor device 101 can also be referred to as a dicing line DL.

As illustrated in FIGS. 1 and 4, the back-surface metal layer 50 is provided in a region surrounded by the annular end portion of the heat dissipation insulating layer 40. That is, the metal formed surface includes a portion exposed from the back-surface metal layer 50 so as to surround the back-surface metal layer 50. On the metal formed surface, the back-surface metal layer 50 is not provided in a predetermined range from the dicing line DL.

Therefore, when the multiple substrate is diced with a blade, clogging of the blade can be suppressed. In addition, scraping and scattering of the back-surface metal layer 50 can be suppressed. Therefore, the semiconductor device 101 can suppress an electrical defect due to adhesion of metal debris.

### <Manufacturing Method>

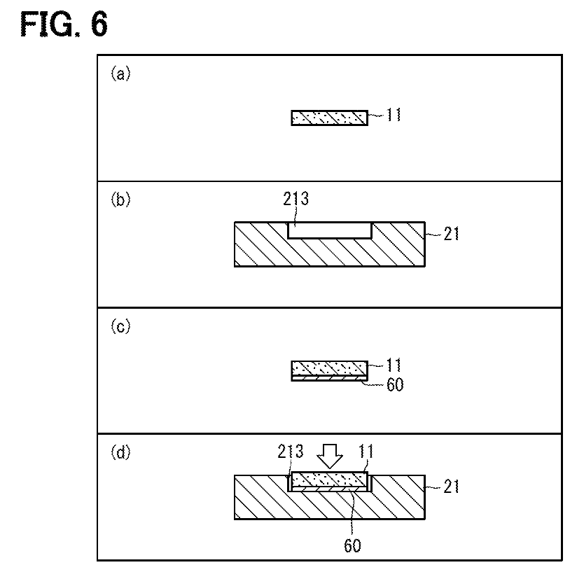

Here, a manufacturing method for the semiconductor device 101 will be described with reference to FIGS. 6 to 8. First, a manufacturing method for the first semiconductor element 11 and the first heat sink 21 incorporated in the wiring substrate 30 will be described with reference to FIG. 6. The same applies to a manufacturing method for the second semiconductor element 12 and the second heat sink 22.

As illustrated in (a) and (b) of FIG. 6, the first semiconductor element 11 and the first heat sink 21 are prepared. Here, the first heat sink 21 in which the recess 213 is formed is prepared. In the first heat sink 21, the recess 213 is formed by cutting, die casting, or the like.

Thereafter, as illustrated in (c) of FIG. 6, the connection member 60 is attached to the element facing surface S11. For example, the connection member 60 is attached by transfer or the like. As illustrated in (d) of FIG. 6, the first semiconductor element 11 to which the connection member 60 is attached is mounted in the recess 213. At this time, the first semiconductor element 11 is pressed in the direction of the arrow shown in outline (die attach joining process). When a metal sintered material is used as the connection member 60, the first semiconductor element 11 is mounted by heating and pressurizing the connection member 60.

In this way, the first semiconductor element 11 and the first heat sink 21 are electrically connected. The first heat sink 21 on which the first semiconductor element 11 is mounted and the second heat sink 22 on which the second semiconductor element 12 is mounted can also be referred to as semiconductor members.

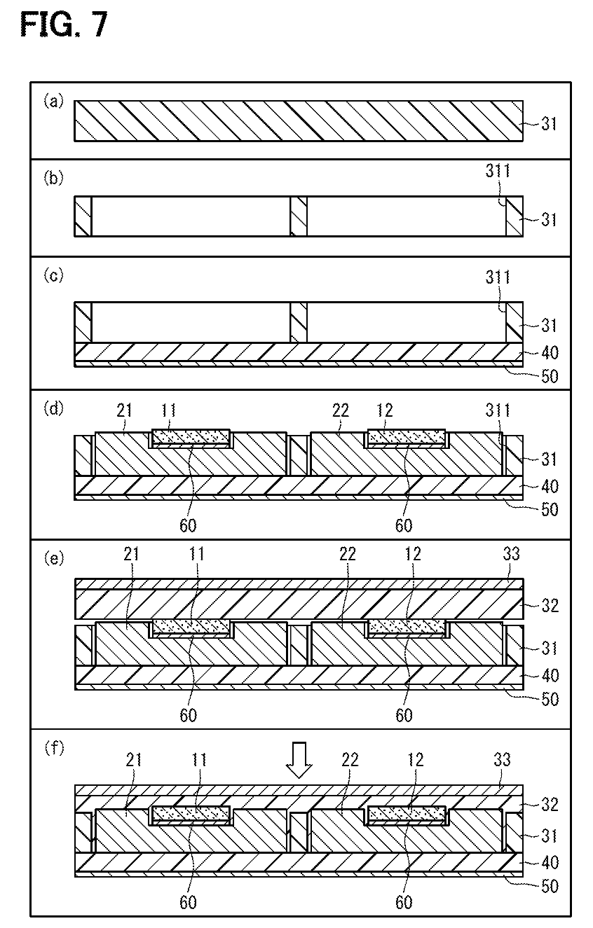

Next, a process of incorporating a semiconductor member in the wiring substrate 30 will be described with reference to FIG. 7. As illustrated in (a) of FIG. 7, the core layer 31 is prepared. As illustrated in (b) of FIG. 7, a through-hole 311 is formed in a region of the core layer 31 where the semiconductor member is to be disposed. The through-hole 311 is formed by, for example, punching.

Next, as illustrated in (c) of FIG. 7, the core layer 31 is disposed (laid up) on the heat dissipation insulating layer 40 provided with the back-surface metal layer 50. The heat dissipation insulating layer 40 can also be referred to as a high-heat-conductive-insulating-layer prepreg. Thereafter, as illustrated in (d) of FIG. 7, the semiconductor member is disposed (laid up) in the through-hole 311.

Furthermore, as illustrated in (e) of FIG. 7, a build-up layer 32 is disposed on the core layer 31. In this case, the pattern wiring 33 and the via 34 are not formed in the build-up layer 32. The reference numeral 33 denotes a thin film of copper or the like before being patterned. The build-up layer 32 can also be referred to as a wiring-layer prepreg.

As illustrated in (f) of FIG. 7, press molding is performed. Here, the build-up layer 32 is pressed in the direction of the arrow shown in outline. Thus, the resin portion of the build-up layer 32 enters a gap between the core layer 31 and the heat sinks 21, 22. In this manner, the semiconductor member is incorporated in the wiring substrate 30. The heat dissipation insulating layer 40 is connected to the core layer 31 and the heat sinks 21, 22.

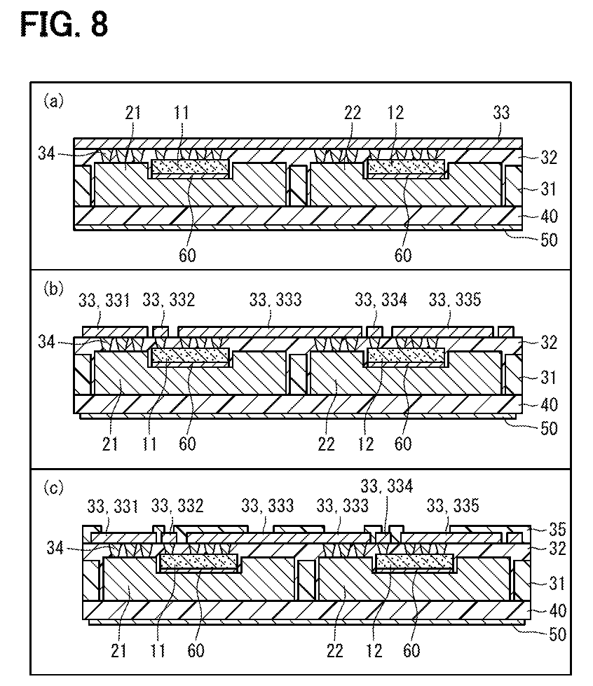

Next, a process of forming the wiring and the solder resist 35 will be described with reference to FIG. 8. As illustrated in (a) of FIG. 8, the via 34 is formed. A filled via is formed as the via 34 (filled via forming process). That is, the via 34 is a filled via in which a conductor is embedded in a hole formed by laser or the like. Thereafter, as illustrated in (b) of FIG. 8, a thin film is patterned to form pattern wiring 33 (pattern wiring forming process). As illustrated in (c) of FIG. 8, the solder resist 35 is formed (solder resist forming process). As a result, each of the pads 331 to 337 is formed.

### <Effects>

As described above, the semiconductor device 101 includes the heat dissipation insulating layer 40 in contact with the heat sink opposite surface S21 and the core opposite surface S31. Therefore, the semiconductor device 101 can improve the heat dissipation performance as compared with a configuration in which the heat sinks 21, 22 and the heat dissipation insulating layer 40 are connected through vias.

In the semiconductor device 101, no wiring layer is provided on the heat sink opposite surface S21 side. Therefore, the semiconductor device 101 does not require consideration of the resin fluidity of the wiring layer during manufacturing. Moreover, the semiconductor device 101 can improve thermal conduction performance on the heat sink opposite surface S21 side by increasing the amount of filler in the heat dissipation insulating layer 40.

As described above, the semiconductor device 101 can be manufactured at a relatively low temperature by using the core layer 31 and the build-up layer 32. Thus, the semiconductor device 101 can use the semiconductor elements 11, 12 and the like having low heat-resistant temperatures. Therefore, the semiconductor device 101 can be made inexpensive.

The preferred embodiment of the present disclosure has been described above. However, the present disclosure is not limited to the above embodiment, and various modifications can be made without departing from the gist of the present disclosure.

Other embodiments of the present disclosure will be described below. The above embodiment and other embodiments can be carried out independently, but can also be carried out in appropriate combination. The present disclosure is not limited to combinations shown in the embodiments but can be performed in various combinations. That is, Modifications 1 to 4 described below can also be applied to other embodiments.

### (Modification 1)

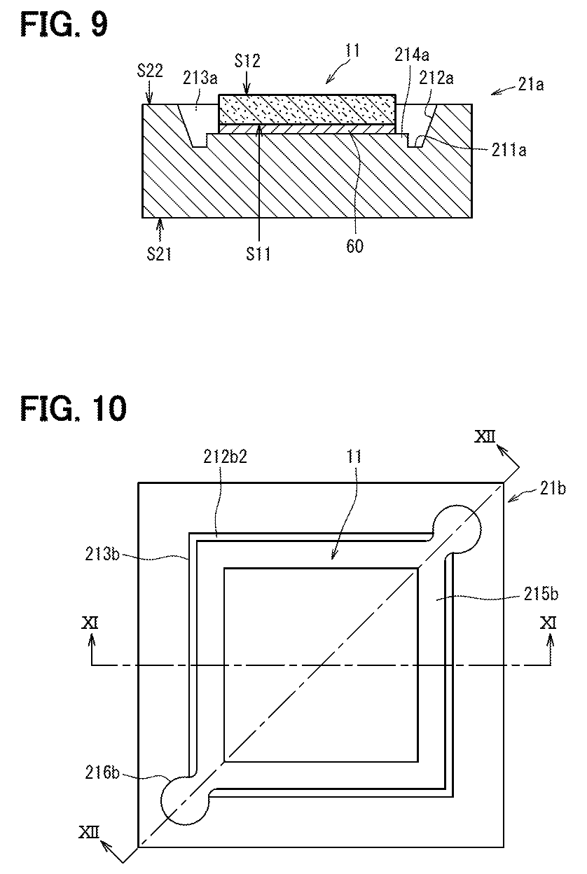

Modification 1 will be described with reference to FIG. 9. In Modification 1, a configuration of a first heat sink 21a differs from that of the first heat sink 21.

The heat sink 21a is provided with a recess 213a formed by a bottom portion 211a and an annular side wall 212a. Moreover, the heat sink 21a is provided with a protrusion 214a on the bottom portion 211a. The protrusion 214a is a portion on which the semiconductor element 11 is mounted. The protrusion 214a can also be referred to as a mounting portion of the semiconductor element 11. That is, the heat sink 21a includes a portion lower than the surface on which the semiconductor element 11 is mounted around the protrusion 214a on which the semiconductor element 11 is mounted. The side wall 212a is inclined such that the opening area of the recess 213a gradually increases from the bottom portion 211a toward the opening end.

Therefore, the heat sink 21a can reduce variation in the mounting position of the semiconductor element 11. In addition, the heat sink 21a can suppress stress concentration on the connection member 60. Since the heat sink 21a includes the protrusion 214a, the semiconductor element 11 easily projects from the recess 213a. Thus, it is easy to apply pressure to the semiconductor element 11 in the die attach joining process.

In the heat sink 21a, the opening area of the recess 213a gradually increases. Thus, it is easy to apply pressure to the semiconductor element 11 in the die attach joining process. Furthermore, the resin portion of the build-up layer 32 is easily inserted into the recess 213a. That is, the semiconductor element 11 and the connection member 60 are covered with the resin portion. Therefore, the semiconductor element 11 and the connection member 60 can suppress delamination because stress due to curing shrinkage of the resin portion is applied.

### (Modification 2)

Modification 2 will be described with reference to FIGS. 10 to 12. In Modification 2, a configuration of a first heat sink 21b mainly differs from that of the first heat sink 21.

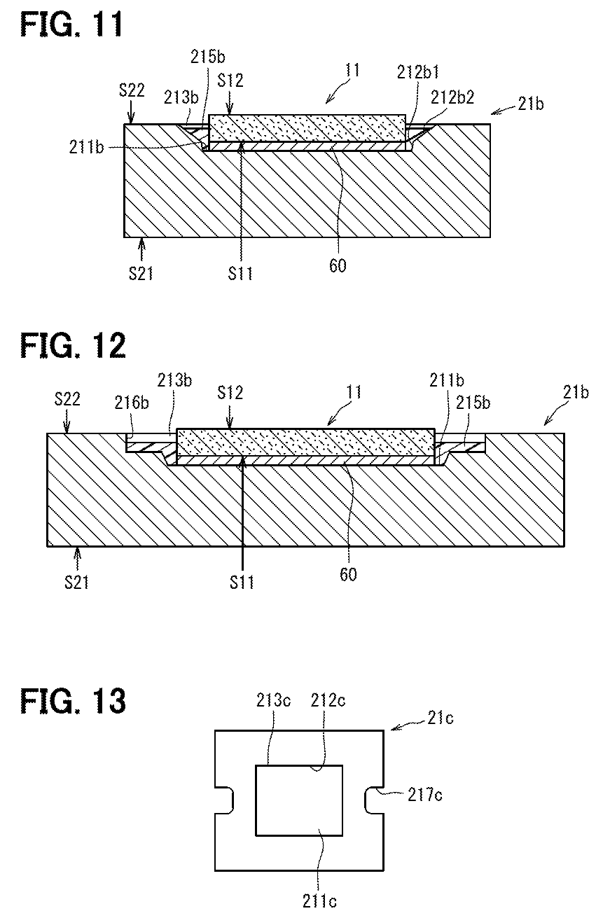

As illustrated in FIGS. 10 and 11, the heat sink 21b is provided with a recess 213b formed by a bottom portion 211b, an annular first side wall 212b1, and a second side wall 212b2. Moreover, in the heat sink 21b, the opening area of the recess 213b increases stepwise by the first side wall 212b1 and the second side wall 212b2.

The first side wall 212b1 is provided continuously with the bottom portion 211b. The second side wall 212b2 is provided continuously with the first side wall 212b1. Thus, the first side wall 212b1 and the second side wall 212b2 are provided in this order from the bottom portion 211b. An angle formed by the second side wall 212b2 and the bottom portion 211b is wider than an angle formed by the first side wall 212b1 and the bottom portion 211b.

The recess 213b is provided with a resin portion 215b. The resin portion 215b is an electrically insulating resin such as an epoxy material or polyimide. The resin portion 215b is provided to be in contact with the connection member 60 and a connection portion between the connection member 60 and the semiconductor element 11. Thus, the resin portion 215b is also in contact with a part of the side surface of the semiconductor element 11.

As illustrated in FIGS. 10 and 12, the heat sink 21b includes a resin reservoir portion 216b in which a part of the resin portion 215b is disposed. The resin reservoir portion 216b is provided at a position higher than the recess 213b.

The resin portion 215b is potted in the recess 213b in which the semiconductor element 11 is mounted. For example, the resin portion 215b is supplied to the resin reservoir portion 216b in a state having fluidity. The resin portion 215b is supplied from the resin reservoir portion 216b into the recess 213b by capillary action. However, the heat sink 21b may not be provided with the resin reservoir portion 216b.

The semiconductor device 101 is provided with the resin portion 215b as described above. Therefore, the semiconductor device 101 can suppress cracks and delamination of the connection member 60.

### (Modification 3)

Modification 3 will be described with reference to FIGS. 13 to 15. In Modification 3, configurations of a first heat sink 21c and a core layer 31c mainly differ from those of the first heat sink 21 and the core layer 31.

As illustrated in FIG. 13, the heat sink 21c is provided with a recess 213c formed by a bottom portion 211c and an annular side wall 212c. The heat sink 21c is provided with a positioning portion 217c. The positioning portion 217c is a recess provided on the surface facing the core layer 31c. The heat sink 21c is provided with two positioning portions 217c.

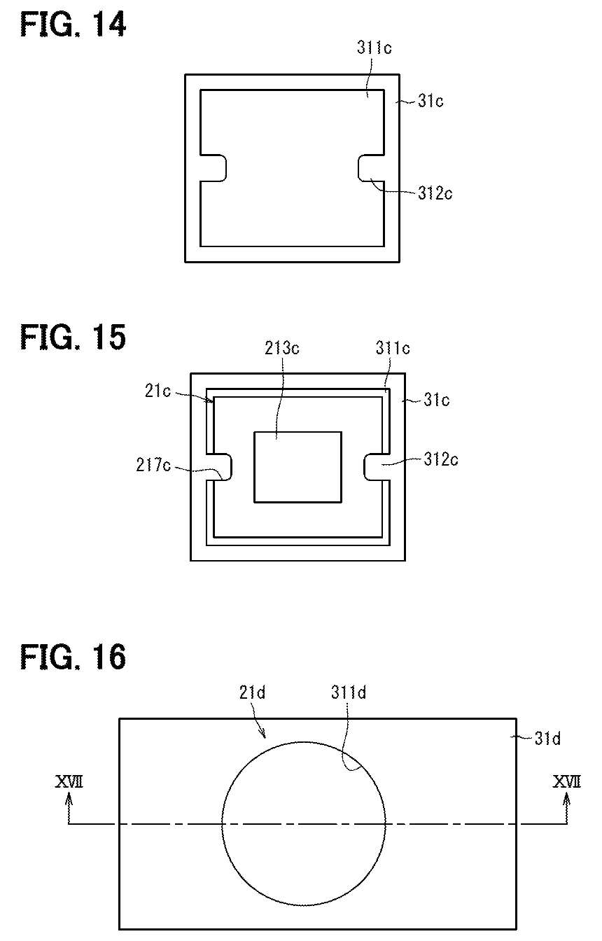

As illustrated in FIG. 14, the core layer 31c is provided with a through-hole 311c. The core layer 31c is provided with a positioning protrusion 312c. The positioning protrusion 312c is a projection provided on the surface facing the heat sink 21c. The core layer 31c is provided with two positioning protrusions 312c. The positioning protrusion 312c is provided at a position corresponding to the positioning portion 217c.

As illustrated in FIG. 15, the heat sink 21c is disposed in the through-hole 311c of the core layer 31c. In this state, the positioning protrusion 312c is disposed in the recess 213c. The positioning protrusion 312c and the recess 213c are arranged while being at least partially in contact with each other.

As a result, the semiconductor device 101 can suppress positional displacement of the heat sink 21c relative to the core layer 31c. The heat sink 21c may include a protrusion for positioning, and the core layer 31c may include a recess for positioning.

### (Modification 4)

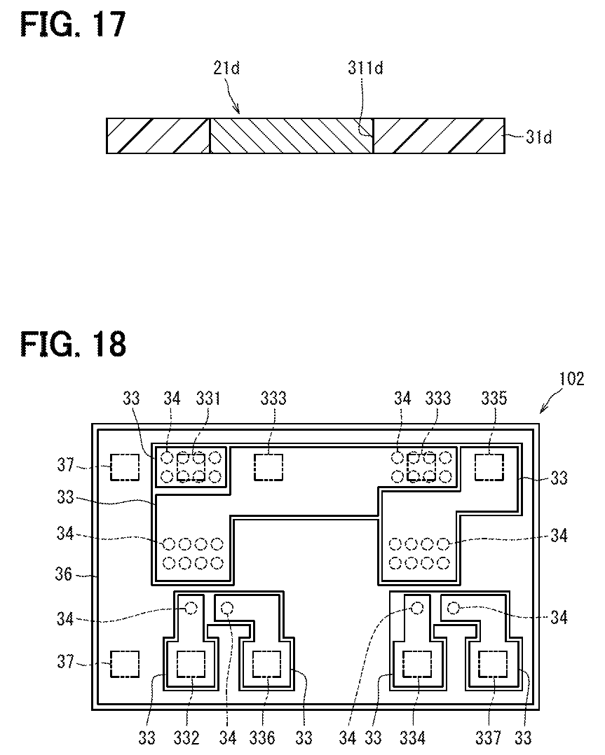

Modification 4 will be described with reference to FIGS. 16 and 17. In Modification 4, configurations of a first heat sink 21d and a core layer 31d mainly differ from those of the first heat sink 21 and the core layer 31.

As illustrated in FIG. 16, the heat sink 21d has a cylindrical shape. The core layer 31d is provided with a through-hole 311d corresponding to the shape of the heat sink 21d. The heat sink 21d is press-fitted into the through-hole 311d.

Thus, as illustrated in FIG. 17, substantially no gap is formed between the heat sink 21d and the core layer 31d. That is, the heat sink 21d is disposed in the through-hole 311d while being in contact with the core layer 31d. Similarly to the heat sink 21 and the like, the heat sink 21d includes a recess in which the semiconductor element 11 is disposed.

Thus, the semiconductor device 101 does not require insertion of the resin portion of the build-up layer 32 between the heat sink 21d and the core layer 31d. Therefore, it is possible to reduce the processing cost during press molding. It is also possible to reduce the weight of the semiconductor device 101, improve its reliability, and reduce the material cost of the heat sink 21d.

### Second Embodiment

A semiconductor device 102 of a second embodiment will be described with reference to FIG. 18. The semiconductor device 102 differs from the semiconductor device 101 in including a ground layer 36.

As illustrated in FIG. 18, the semiconductor device 102 includes layer wiring provided on the layer front surface S33 as a part of the wiring. The layer wiring includes pattern wiring 33 electrically connected to the semiconductor element 11 and the ground layer 36 provided around the pattern wiring 33 and electrically connected to the ground. The ground layer 36 includes a ground electrode 37. The ground layer 36 corresponds to dummy wiring.

The ground layer 36 is wiring of the same layer as the pattern wiring 33. The ground layer 36 is formed in the same process as the pattern wiring 33. Similarly to the pattern wiring 33, the ground layer 36 is formed by patterning a thin film of copper or the like.

The semiconductor device 102 can achieve an effect similar to that of the semiconductor device 101. Moreover, the semiconductor device 102 can reduce noise due to the provision of the ground layer 36.

### Third Embodiment

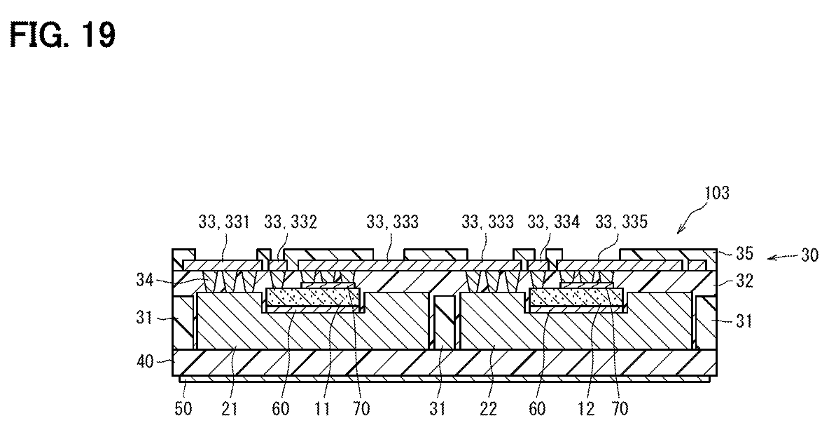

A semiconductor device 103 of a third embodiment will be described with reference to FIG. 19. The semiconductor device 103 differs from the semiconductor device 101 in that a heat sink pad 70 is provided.

As illustrated in FIG. 19, in the semiconductor device 103, the heat sink pad 70 is provided between each of the semiconductor elements 11, 12 and the via 34. The heat sink pad 70 is a member mainly composed of metal such as copper. The heat sink pad 70 is a chip-shaped or plate-shaped metal member.

More specifically, the heat sink pad 70 is provided on the source electrodes of the semiconductor elements 11, 12. The heat sink pad 70 is electrically connected to the source electrode and the via 34. The source electrode of the first semiconductor element 11 is electrically connected to the O wiring portion through the heat sink pad 70 and the via 34. The source electrode of the second semiconductor element 12 is electrically connected to the N wiring portion through the heat sink pad 70 and the via 34.

The semiconductor device 103 can achieve an effect similar to that of the semiconductor device 101. Furthermore, the semiconductor device 103 includes the heat sink pad 70. The semiconductor device 103 can temporarily store heat in response to rapid heat generation of the semiconductor elements 11, 12. Accordingly, the semiconductor device 103 can suppress element destruction of the semiconductor elements 11, 12. The semiconductor elements 11, 12 may generate heat rapidly during a short circuit or avalanche.

### Fourth Embodiment

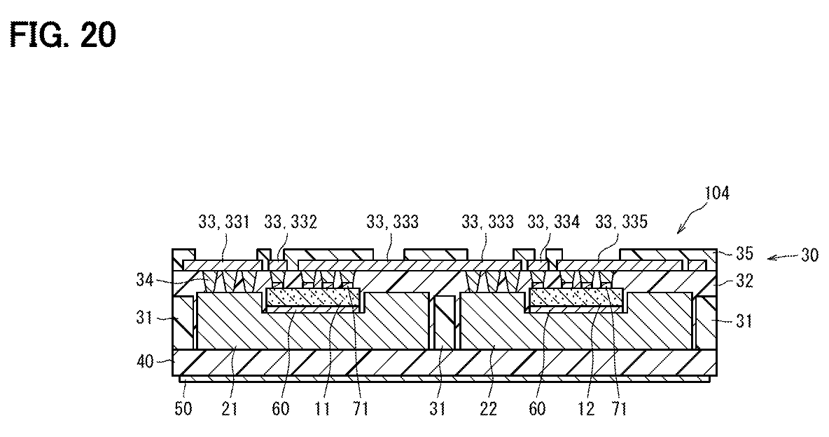

A semiconductor device 104 of a fourth embodiment will be described with reference to FIG. 20. The semiconductor device 104 differs from the semiconductor device 101 in that a stud bump 71 is provided.

As illustrated in FIG. 20, in each of the semiconductor elements 11, 12, the stud bump 71 is provided on the electrode on the element front surface S12 side. The stud bump 71 is a bump mainly composed of a metal such as copper. The stud bump 71 is formed using a bonding method.

The stud bump 71 is electrically connected to the via 34. Thus, the electrode on the element front surface S12 side is electrically connected to the via 34 through the stud bump 71.

The semiconductor device 104 can achieve an effect similar to that of the semiconductor device 101. Moreover, due to the provision of the stud bump 71, the semiconductor device 104 does not require formation of copper plating in advance on the electrode on the element front surface S12 side. This enables cost reduction of the semiconductor device 104.

### Fifth Embodiment

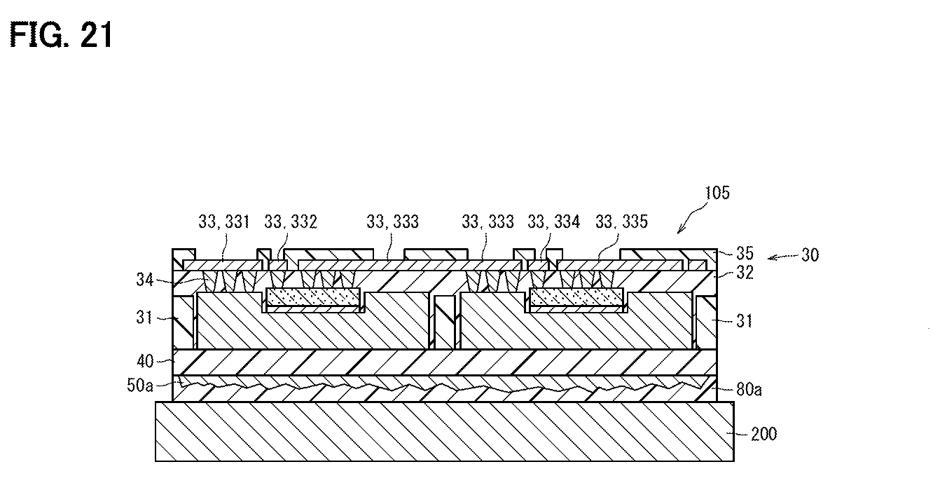

A semiconductor device 105 of a fifth embodiment will be described with reference to FIG. 21. The semiconductor device 105 differs from the semiconductor device 101 mainly in the configuration of a back-surface metal layer 50a.

As illustrated in FIG. 21, the semiconductor device 105 is mounted on a cooler 200 through a heat conductive portion 80a on the back-surface metal layer 50a side. The heat conductive portion 80a can also be referred to as a TIM. TIM is an abbreviation for thermal interface material. A semiconductor device according to another embodiment may also be mounted on the cooler 200 through the heat conductive portion 80a.

The back-surface metal layer 50a has a roughened shape to increase the contact area with the heat conductive portion 80a. In other words, the back-surface metal layer 50a has an irregular surface shape.

The semiconductor device 105 can achieve an effect similar to that of the semiconductor device 101. Furthermore, the semiconductor device 105 includes the roughened back-surface metal layer 50a. Therefore, the semiconductor device 105 can increase the contact area between the back-surface metal layer 50a and the heat conductive portion 80a, and can efficiently transfer heat from the back-surface metal layer 50a to the heat conductive portion 80a. Therefore, the semiconductor device 105 can improve the heat dissipation performance.

### Sixth Embodiment

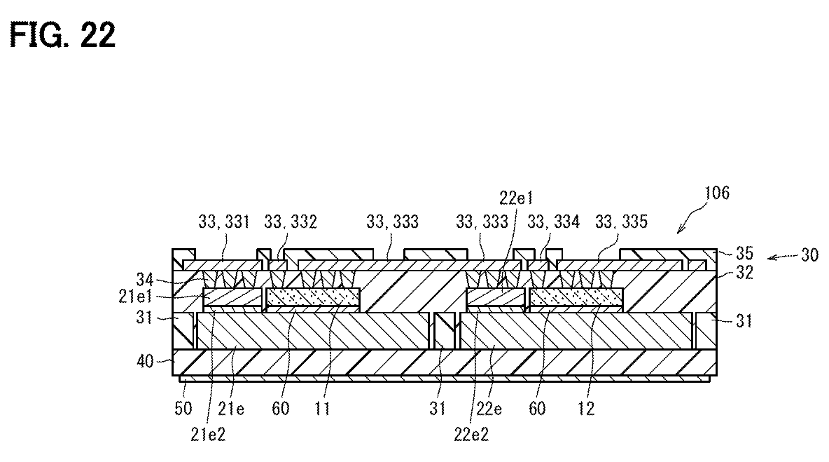

A semiconductor device 106 of a sixth embodiment will be described with reference to FIG. 22. The semiconductor device 106 differs from the semiconductor device 101 mainly in the configurations of heat sinks 21e, 22e.

As illustrated in FIG. 22, the heat sinks 21e, 22e each have a plate shape. The heat sinks 21e, 22e are not provided with the recess 213. The heat sinks 21e, 22e each have a rectangular parallelepiped shape. Thus, the heat sink front surface S22 is a flat surface. The semiconductor elements 11, 12 are mounted on the heat sink front surface S22.

The semiconductor device 106 includes pads 21e1, 22e1 having thicknesses equivalent to those of the semiconductor elements 11, 12. The first pad 21e1 is electrically connected to the first heat sink 21e through a connection member 21e2. The second pad 22e1 is electrically connected to the second heat sink 22e through a connection member 22e2. The front surfaces of the pads 21e1, 22e1 have the same height as the element front surface S12. The connection members 21e2, 22e2 can be made of the same material as the connection member 60. The pads 21e1, 22e1 correspond to terminal members.

The first pad 21e1 is electrically connected to the P wiring portion through the via 34. The second pad 22e1 is electrically connected to the O wiring portion through the via 34. Thus, the first heat sink 21e is electrically connected to the P wiring portion through the first pad 21e1 and the via 34. The second heat sink 22e is electrically connected to the O wiring portion through the second pad 22e1 and the via 34.

The semiconductor device 106 can achieve an effect similar to that of the semiconductor device 101. Moreover, the semiconductor device 106 does not require processing of the heat sinks 21e, 22e. In addition, since the semiconductor device 106 includes the pads 21e1, 22e1, the same vias 34 can be used on the semiconductor elements 11, 12 and the pads 21e1, 22e1. It can also be said that the vias 34 having the same thickness can be used.

### Modification 5

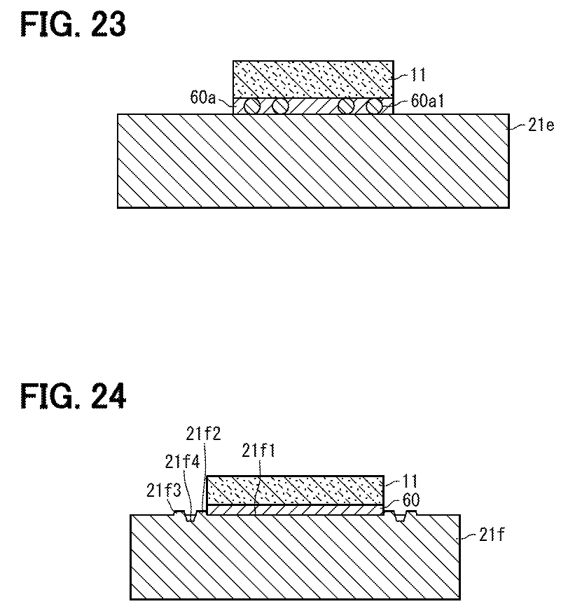

Modification 5, which is a modification of the sixth embodiment, will be described with reference to FIG. 23. As illustrated in FIG. 23, a connection member 60a includes a ball 60a1. That is, the connection member 60a is a metal sintered material including the ball 60a1. The ball 60a1 may be made of metal such as nickel or copper, resin, or the like. The ball 60a1 is for keeping the amount of pressurization constant when the connection member 60a is pressurized. A method of mounting the semiconductor element 11 using the connection member 60a is similar to that in the first embodiment.

The semiconductor device 106 can suppress variation in the connection member 60a after heating and pressurization. This makes it possible to reduce variation in the void volume of the connection member 60a. Moreover, the flatness of the semiconductor elements 11, 12 can be improved. Therefore, the wiring performance of the via 34, the connection reliability between the via 34 and the semiconductor elements 11, 12, and the heat dissipation performance can be improved.

The ball 60a1 can also be included in the connection members 21e2, 22e2. Modification 5 can also be applied to other embodiments and modifications.

### Modification 6

Modification 6, which is a modification of the sixth embodiment, will be described with reference to FIG. 24. As illustrated in FIG. 24, a heat sink 21f includes a mounting portion 21f1 on which the semiconductor element 11 is mounted and groove portions 21f2 to 21f4 provided around the mounting portion 21f1. The groove portions 21f2 to 21f4 are annularly provided to surround the mounting portion 21f1.

In the heat sink 21f, for example, the groove portions 21f2 to 21f4 are formed by coining. In the heat sink 21f, it can also be said that the groove portions 21f2 to 21f4 are formed by press working.

The groove portions 21f2 to 21f4 include two protrusions 21f2, 21f3 and a recess 21f4 provided between the protrusions 21f2, 21f3. The recess 21f4 is a portion recessed relative to the one protrusion 21f2 and the other protrusion 21f3. That is, it can be said that the heat sink 21f includes the recess 21f4, which is a portion recessed by press working, and the protrusions 21f2, 21f3, which are portions raised by press working. Therefore, the bottom of the recess 21f4 is located lower than the mounting portion 21f1. The second heat sink 22e is similarly configured.

As a result, the semiconductor device 106 can ensure positional recognition during mounting of the semiconductor elements 11, 12. In addition, the semiconductor device 106 can suppress the connection member 60 projecting from the facing region of each of the semiconductor elements 11, 12, and can ensure the pressure applied to the connection member 60. Therefore, an appropriate sintered state of the connection member 60 can be ensured. Accordingly, the semiconductor device 106 can improve connection reliability by the connection member 60. Modification 6 can also be applied to other embodiments and modifications.

### Seventh Embodiment

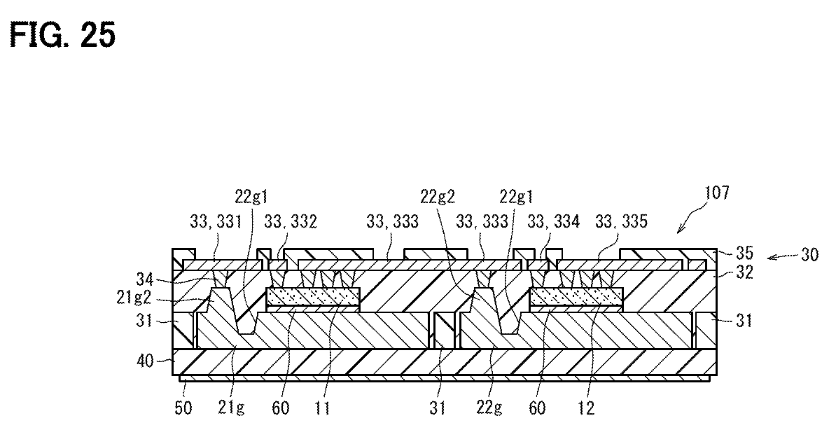

A semiconductor device 107 of a seventh embodiment will be described with reference to FIG. 25. The semiconductor device 107 differs from the semiconductor device 101 mainly in the configurations of heat sinks 21g, 22g.

As illustrated in FIG. 25, the heat sinks 21g, 22g each have an irregular surface shape. In the first heat sink 21 g, a recess 21g1 and a protrusion 21g2 are provided around a region in which the first semiconductor element 11 is mounted. The protrusion 21g2 is provided at a position facing the P wiring portion. The recess 21g1 is provided between a region in which the first semiconductor element 11 is mounted and the protrusion 21g2. Similarly, the second heat sink 22g is provided with a recess 22g1 and a protrusion 22g2. The protrusion 22g2 is provided at a position facing the O wiring portion. The heat sinks 21g, 22g are each formed in an irregular surface shape by, for example, coining.

The front surfaces of the protrusions 21g2, 22g2 have the same height as the element front surface S12. The protrusion 21g2 is electrically connected to the P wiring portion through the via 34. The protrusion 22g2 is electrically connected to the O wiring portion through the via 34.

The semiconductor device 107 can achieve an effect similar to that of the semiconductor device 101. Moreover, since the semiconductor device 107 is formed in the irregular surface shape by coining, the cost can be reduced compared with the semiconductor device 101.

### Eighth Embodiment

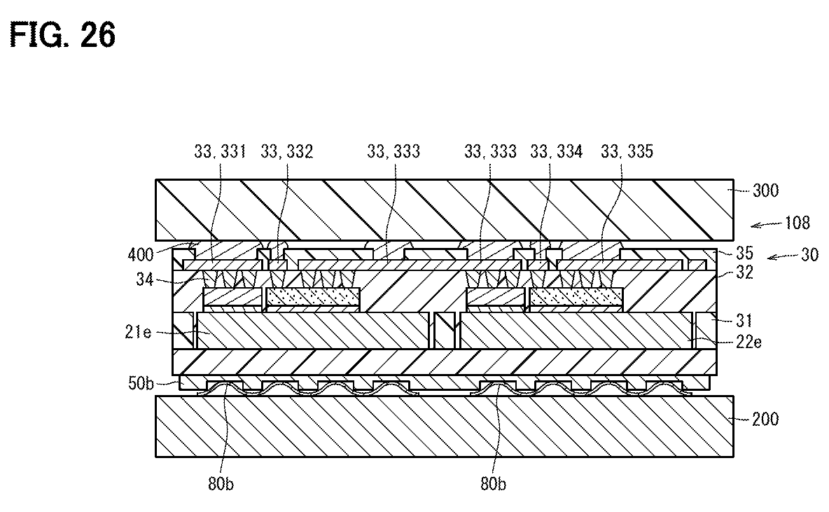

A semiconductor device 108 of an eighth embodiment will be described with reference to FIG. 26. The semiconductor device 108 differs from the semiconductor device 106 mainly in the configuration of the back-surface metal layer 50b and in that a heat-dissipating spring member 80b is attached.

As illustrated in FIG. 26, irregularities are formed on the back-surface metal layer 50b. The irregularities are formed by etching the back-surface metal layer 50b. The heat-dissipating spring member 80b is attached to the irregularities. The irregularities are provided according to the shape of the heat-dissipating spring member 80b. For example, irregularities may be formed on the back-surface metal layer 50b so that the heat-dissipating spring member 80b can be fitted and fixed. The heat-dissipating spring member 80b is a spring having good thermal conductivity, and can also be referred to as a heat conductive spring. The semiconductor device 108 is attached to the cooler 200 through the heat-dissipating spring member 80b.

Here, as an example, the semiconductor device 108 mounted on a circuit board 300 is employed. A conductive connection member 400 is electrically connected to each of the pads 331 to 337. The semiconductor device 108 is electrically connected to the circuit board 300 through the connection member 400. Similarly, other semiconductor devices 101 to 107, 109 may be connected to the circuit board 300.

The semiconductor device 108 can achieve an effect similar to that of the semiconductor device 105. In the semiconductor device 108, the heat-dissipating spring member 80b is fixed to the irregularities of the back-surface metal layer 50b. Thus, the semiconductor device 108 can suppress the positional displacement of the heat-dissipating spring member 80b. Therefore, the semiconductor device 108 can reduce the contact thermal resistance between the back-surface metal layer 50b and the heat-dissipating spring member 80b, and can improve the heat dissipation performance.

The back-surface metal layer 50b and the heat-dissipating spring member 80b can also be applied to the first to fourth embodiments and the seventh embodiment.

### Ninth Embodiment

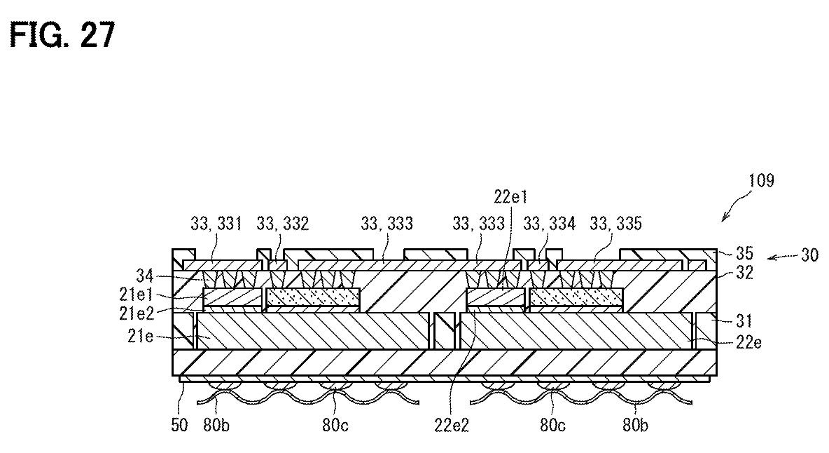

A semiconductor device 109 of a ninth embodiment will be described with reference to FIG. 27. The semiconductor device 109 differs from the semiconductor device 108 in that a connection member 80c is provided.

As illustrated in FIG. 27, the connection member 80c joins the back-surface metal layer 50 and the heat-dissipating spring member 80b. The connection member 80c may be made of solder, a sintered material, or the like.

The semiconductor device 109 can achieve an effect similar to that of the semiconductor device 108. Moreover, the semiconductor device 109 can reduce the contact thermal resistance between the back-surface metal layer 50 and the heat-dissipating spring member 80b, as compared with the semiconductor device 108. Accordingly, the semiconductor device 109 can improve the heat dissipation performance more than the semiconductor device 108.

### Tenth Embodiment

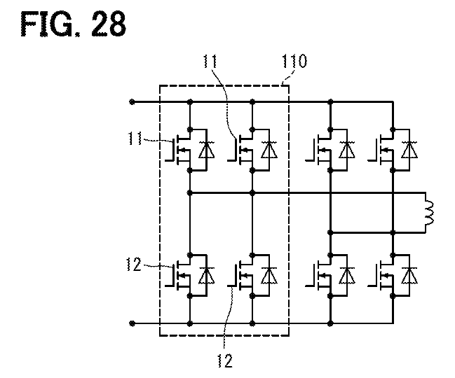

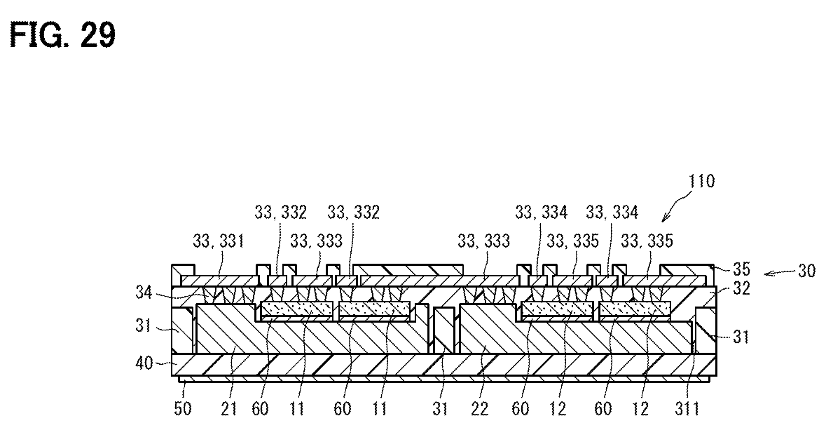

A semiconductor device 110 of a tenth embodiment will be described with reference to FIGS. 28 and 29. The semiconductor device 110 differs from the semiconductor device 101 in the configurations of the semiconductor elements 11, 12.

As illustrated in FIG. 28, the semiconductor device 110 has a configuration in which two first semiconductor elements 11 are connected in parallel as an upper arm element, and two second semiconductor elements 12 are connected in parallel as a lower arm element. The two first semiconductor elements 11 have the same configuration. The two second semiconductor elements 12 have the same configuration.

As illustrated in FIG. 29, the two first semiconductor elements 11 are mounted on one first heat sink 21 through the connection member 60. The two first semiconductor elements 11 are connected in parallel through wiring 33, 34. More specifically, the two first semiconductor elements 11 have a configuration in which their drain electrodes are electrically connected to each other through the first heat sink 21, and their source electrodes are electrically connected to each other through the wiring 33, 34. Thus, the two first semiconductor elements 11 are connected in parallel. The two second semiconductor elements 12 are mounted on one second heat sink 22 through the connection member 60. The two second semiconductor elements 12 are connected in parallel with a configuration similar to that of the first semiconductor element 11. In this manner, the wiring substrate 30 incorporates the two first semiconductor elements 11 and the two semiconductor elements 12.

Here, an example in which two semiconductor elements are connected in parallel is employed. However, in the semiconductor device 110, three or more semiconductor elements may be connected in parallel. Thus, three or more first semiconductor elements 11 may be mounted on the first heat sink 21. Similarly, three or more second semiconductor elements 12 may be mounted on the second heat sink 22.

The semiconductor device 110 can achieve an effect similar to that of the semiconductor device 101. Moreover, in the semiconductor device 110, the upper arm element includes a plurality of first semiconductor elements 11, and the lower arm element includes a plurality of second semiconductor elements 12. Therefore, the first semiconductor element 11 and the second semiconductor element 12 can be reduced in size as compared with the first embodiment. Accordingly, the number of semiconductor elements 11, 12 obtainable from the same wafer can be increased, thereby enabling cost reduction. In addition, for the same wafer size, the effective area increases as the sizes of the semiconductor elements 11, 12 decrease. The element yield also increases as the sizes of the semiconductor elements 11, 12 decrease.

The semiconductor device 110 can suppress heat concentration by dispersedly arranging the plurality of first semiconductor elements 11 in one first heat sink 21. The semiconductor device 110 can reduce a temperature difference between the plurality of first semiconductor elements 11. Therefore, in the semiconductor device 110, the characteristic difference between the plurality of first semiconductor elements 11 is reduced, and the load imbalance can be reduced. The same applies to the second semiconductor element 12 side.

The semiconductor device 110 can shorten the wiring length between the plurality of first semiconductor elements 11 as compared with a case where the plurality of first semiconductor elements 11 are mounted on different heat sinks. Therefore, switching variation in the plurality of first semiconductor elements 11 connected in parallel can be reduced. The same applies to the plurality of second semiconductor elements 12.

In the semiconductor device 110, a plurality of semiconductor elements 11 of different types that are connected in parallel may be mounted on one heat sink 21, and a plurality of semiconductor elements 12 of different types that are connected in parallel may be mounted on one heat sink 22. For example, a MOSFET and an IGBT connected in parallel may be mounted on the heat sink 21.

### Eleventh Embodiment

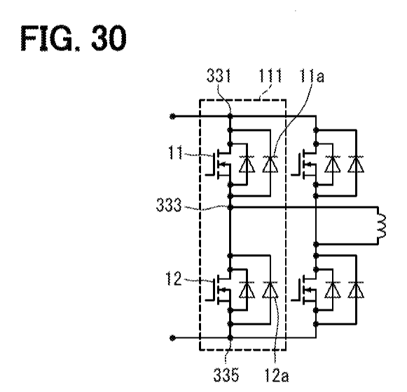

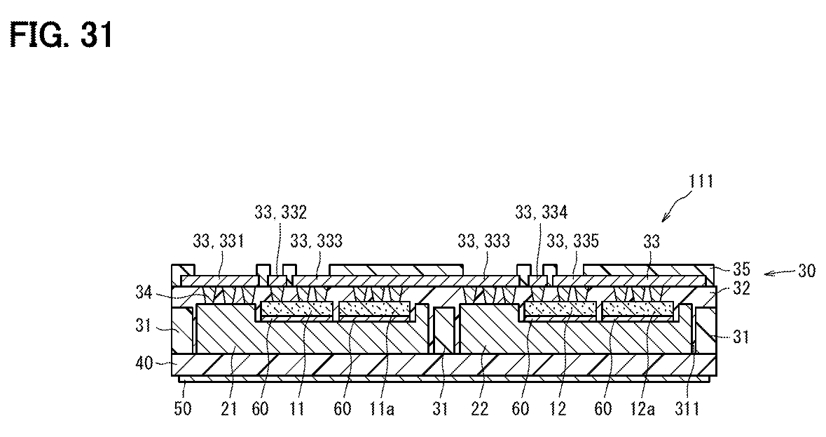

A semiconductor device 111 of an eleventh embodiment will be described with reference to FIGS. 30 and 31. The semiconductor device 111 differs from the semiconductor device 101 in the configuration of the element mounted on each of the heat sinks 21, 22.

As illustrated in FIG. 30, the semiconductor device 111 has a configuration in which the first semiconductor element 11 and a first diode 11a are connected in parallel, and the second semiconductor element 12 and a second diode 12a are connected in parallel. In this manner, the first semiconductor element 11 is connected in parallel with the first diode 11a that is a circuit element different from the first semiconductor element 11. The second semiconductor element 12 is connected in parallel with the second diode 12a that is a circuit element different from the second semiconductor element 12. The diodes 11a, 12a are freewheeling diodes.

As illustrated in FIG. 31, the first semiconductor element 11 and the first diode 11a are mounted on one first heat sink 21 through the connection member 60. The first semiconductor element 11 and the first diode 11a are connected in parallel through the wiring 33, 34. More specifically, the first semiconductor element 11 and the first diode 11a have a configuration in which the drain electrode and the cathode electrode are electrically connected through the first heat sink 21, and the source electrode and the anode electrode are electrically connected through the wiring 33, 34. Thus, the first semiconductor element 11 and the first diode 11a are connected in parallel. The second semiconductor element 12 and the second diode 12a are mounted on one second heat sink 22 through the connection member 60. The second semiconductor element 12 and the second diode 12a are connected in parallel with a configuration similar to that of the first semiconductor element 11 and the first diode 11a. In this manner, the wiring substrate 30 incorporates the two semiconductor elements 11, 12 and the two diodes 11a, 12a.

The semiconductor device 111 can achieve an effect similar to that of the semiconductor device 101. Moreover, the semiconductor device 111 can shorten the wiring length between the first semiconductor element 11 and the first diode 11a. Therefore, the semiconductor device 111 can reduce wiring inductance between the first semiconductor element 11 and the first diode 11a, and can reduce surge voltage, loss, and generated noise. The same applies to the relationship between the second semiconductor element 12 and the second diode 12a.

The first semiconductor element 11 and the first diode 11a do not operate simultaneously. That is, the timing at which the first semiconductor element 11 and the first diode 11a require heat dissipation through the first heat sink 21 differs. Therefore, the semiconductor device 111 can share the function of the first heat sink 21 between the first semiconductor element 11 and the first diode 11a. The same applies to the second heat sink 22 side.

### (Twelfth Embodiment)

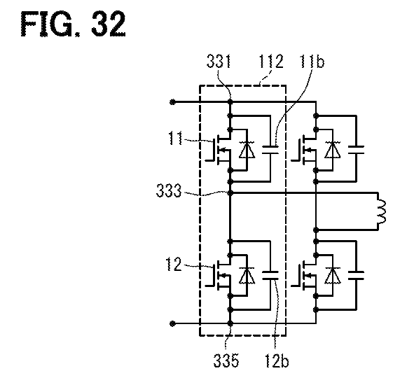

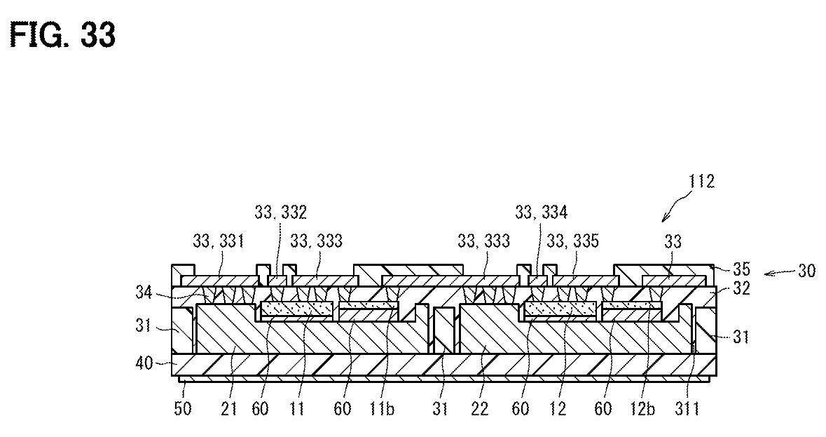

A semiconductor device 112 of a twelfth embodiment will be described with reference to FIGS. 32 and 33. The semiconductor device 112 differs from the semiconductor device 111 in the configuration of the element mounted on each of the heat sinks 21, 22.

As illustrated in FIG. 32, the semiconductor device 112 has a configuration in which the first semiconductor element 11 and a first capacitor 11b are connected in parallel, and the second semiconductor element 12 and a second capacitor 12b are connected in parallel. In this manner, the first semiconductor element 11 is connected in parallel with the first capacitor 11b that is a circuit element different from the first semiconductor element 11. The second semiconductor element 12 is connected in parallel with the second capacitor 12b that is a circuit element different from the second semiconductor element 12. The capacitors 11b, 12b are capacitor elements that function as snubber circuits.

As illustrated in FIG. 33, the first semiconductor element 11 and the first capacitor 11b are mounted on one first heat sink 21 through the connection member 60. The first semiconductor element 11 and the first capacitor 11b are connected in parallel through the wiring 33, 34. More specifically, the first semiconductor element 11 and the first capacitor 11b have a configuration in which the drain electrode and one electrode of the first capacitor 11b are electrically connected through the first heat sink 21, and the source electrode and the other electrode of the first capacitor 11b are electrically connected through the wiring 33, 34. Thus, the first semiconductor element 11 and the first capacitor 11b are connected in parallel. The second semiconductor element 12 and the second capacitor 12b are mounted on one second heat sink 22 through the connection member 60. The second semiconductor element 12 and the second capacitor 12b are connected in parallel with a configuration similar to that of the first semiconductor element 11 and the first capacitor 11b. In this manner, the wiring substrate 30 incorporates the two semiconductor elements 11, 12 and the two capacitors 11b, 12b.

The capacitors 11b, 12b are thinner than the semiconductor elements 11, 12. Therefore, by adjusting the thicknesses of the connection members 60, the heights of the capacitors 11b, 12b can be aligned with those of the semiconductor elements 11, 12. That is, the connection members 60 on the capacitors 11b, 12b side are thicker than the connection members 60 on the semiconductor elements 11, 12 side. Examples of the method of adjusting the thickness include increasing the supply of the connection member 60, adjusting the applied pressure, and changing the ball size for height adjustment.

This enables the semiconductor device 112 to use the same vias 34 on the semiconductor elements 11, 12 and the capacitors 11b, 12b. Since the same vias 34 are used, the semiconductor device 112 does not require individually changing the thicknesses of the heat sinks 21, 22. The semiconductor device 112 can achieve an effect similar to that of the semiconductor device 111.

The semiconductor device 112 can also employ a circuit element thicker than the semiconductor elements 11, 12 as a circuit element connected in parallel with the semiconductor elements 11, 12. In this case, a similar effect can be achieved by making the connection member 60 on the circuit element side thinner than the connection member 60 on the side of each of the semiconductor elements 11, 12.

Moreover, the capacitors 11b, 12b are narrower in width (element width) than the semiconductor elements 11, 12. That is, the capacitors 11b, 12b are elements smaller in size than the semiconductor elements 11, 12. However, the present disclosure can also be applied to capacitors 11b, 12b having sizes equivalent to those of the semiconductor elements 11, 12. In addition, the present disclosure can also employ capacitors 11b, 12b having widths equivalent to those of the semiconductor elements 11, 12 and being smaller in thickness than the semiconductor elements 11, 12.

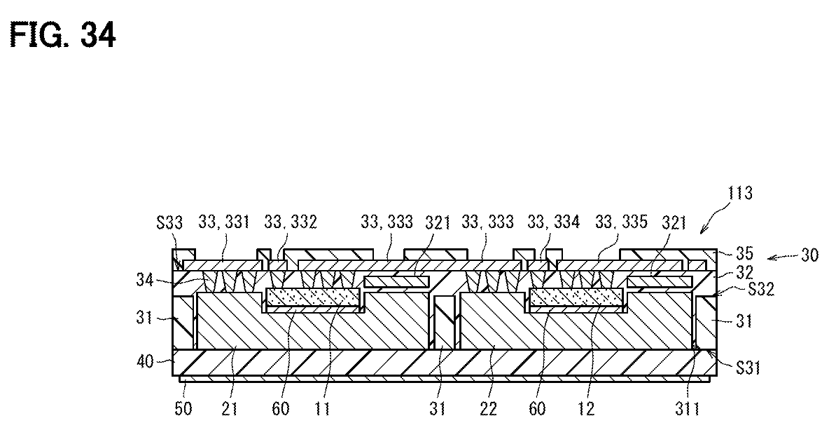

Other modifications and other embodiments will be described below. As in the modification illustrated in FIG. 34, the semiconductor device 113 may include a floating conductor layer 321. The floating conductor layer 321 is provided in the build-up layer 32. The floating conductor layer 321 is provided between the wiring (pattern wiring 33) and the heat sinks 21, 22 in the stacking direction. The floating conductor layer 321 is not electrically connected to the pattern wiring 33 and the via 34. The floating conductor layer 321 is not electrically connected to the ground. This enables the semiconductor device 113 to relax the electric field in the pattern wiring 33 and the heat sinks 21, 22. The semiconductor device 113 can improve insulation between the pattern wiring 33 and the heat sinks 21, 22.

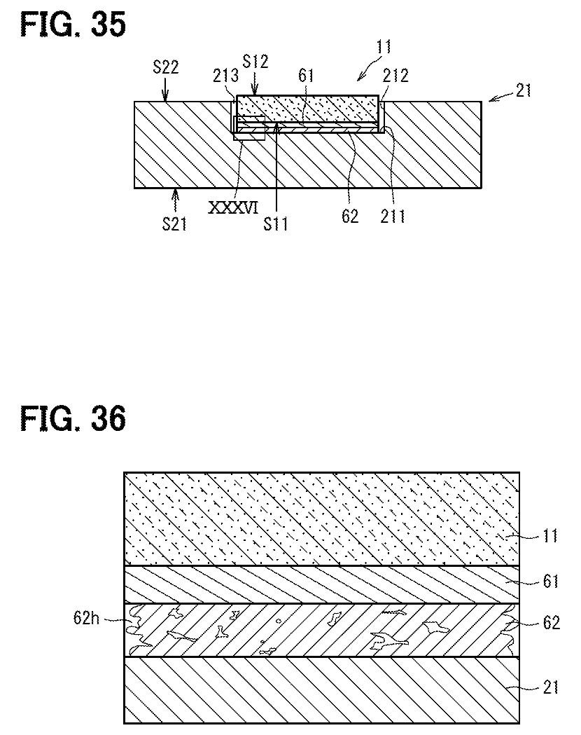

As in the modification illustrated in FIGS. 35 and 36, the semiconductor element 11 may be mounted on the first heat sink 21 through a connection member 61. The connection member 61 is a silver sintered material. That is, the connection member 61 is a joining material mainly composed of silver. The connection member 61 is sinter-bonded. It can be said that the connection member 61 includes a sintered silver layer.

On the other hand, the first heat sink 21 is plated. That is, a silver plating layer 62 is provided on the front surface of the first heat sink 21. FIGS. 35 and 36 illustrate, for convenience, a configuration in which the silver plating layer 62 is provided only on the bottom portion 211 of the recess 213. The silver plating layer 62 only needs to be provided on at least the bottom portion 211. Accordingly, the joining performance between the first semiconductor element 11 and the first heat sink 21 can be improved. The same applies to the relationship between the second semiconductor element 12 and the second heat sink 22.

Moreover, as in the modification illustrated in FIG. 36, the silver plating layer 62 is preferably porous with a gap 62h. The silver plating layer 62 can also be referred to as a porous plating layer. Accordingly, the silver plating layer 62 can also be referred to as a matte plating layer. This enables the silver plating layer 62 to mitigate stress generated due to thermal cycling or the like. That is, deformation of the porous silver plating layer 62 suppresses cracks in the sintered silver layer of the connection member 61.

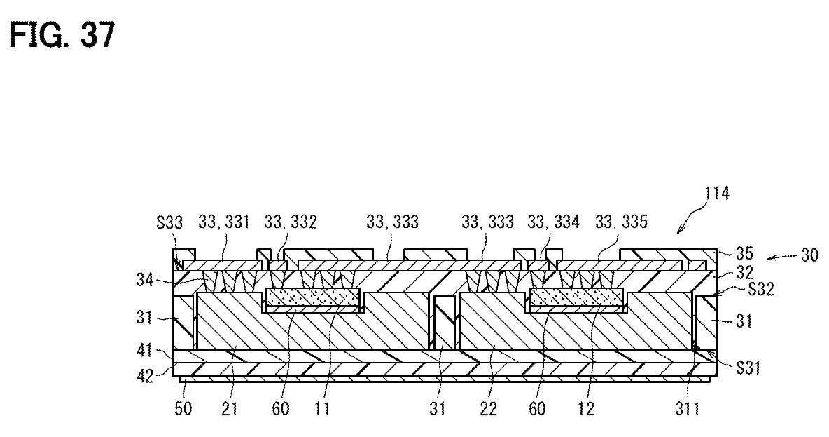

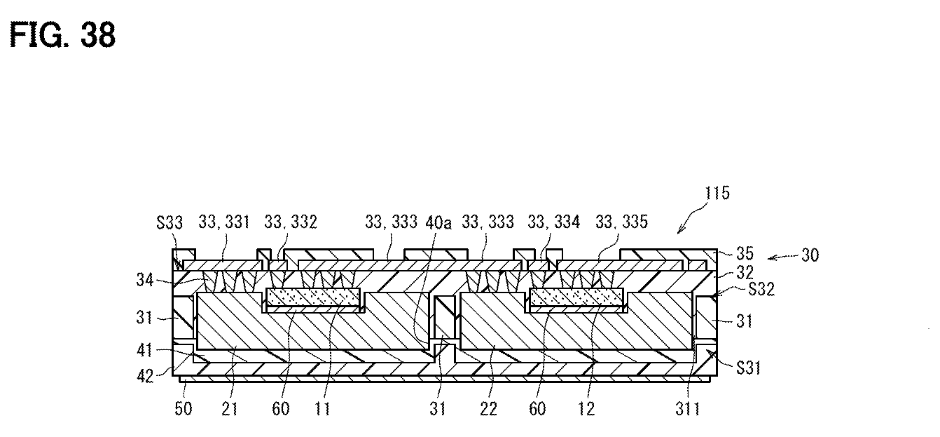

As illustrated in the modifications in FIGS. 37 and 38, heat dissipation insulating layers 41, 42 may have a two-layer structure. The heat dissipation insulating layers include the heat dissipation insulating adhesive layer 41 in contact with the heat sink opposite surface S21 and the high heat-conductive insulating layer 42 having high insulation properties in contact with the heat dissipation insulating adhesive layer 41. The heat dissipation insulating adhesive layer 41 is an adhesive material having higher adhesion to metal or the like than the high heat-conductive insulating layer 42. The high heat-conductive insulating layer 42 contains a filler having a good thermal conductivity and an electrically insulating resin containing the filler.

This makes it possible to connect the heat dissipation insulating layers 41, 42 to the core layer 31 and the heat sinks 21, 22. As an example of the manufacturing method, the build-up layer 32 may be press-molded while the core layer 31 and the heat sinks 21, 22 are fixed, and then the heat dissipation insulating layer 40 may be connected. Manufacturing is enabled by employing the heat dissipation insulating layers 41, 42. That is, the high heat-conductive insulating layer 42 needs to be molded under a higher pressing pressure than a normal pressing pressure to ensure heat dissipation performance. Thus, only the high heat-conductive insulating layer 42 is previously subjected to high-pressure press molding in a separate process, and then connected through the heat dissipation insulating adhesive layer 41. Therefore, element damage or the like caused by high-pressure pressing can be avoided.

As in the modification illustrated in FIG. 38, the heat dissipation insulating layers 41, 42 may be provided with positioning recesses 40a in which the heat sinks 21, 22 are disposed. That is, the heat dissipation insulating layers 41, 42 are provided with the positioning recesses 40a before the heat sinks 21, 22 are connected.

The positioning recess 40a has an opening area sufficient to enable the heat sinks 21, 22 to be disposed without a gap. It can also be said that the positioning recess 40a has an opening area sufficient to restrict the heat sinks 21, 22 disposed therein from moving in the planar direction. This improves assembly accuracy of the heat sinks 21, 22. A gap may be formed between the positioning recess 40a and the heat sinks 21, 22 as long as a manufacturing error or positional deviation is within an allowable range.

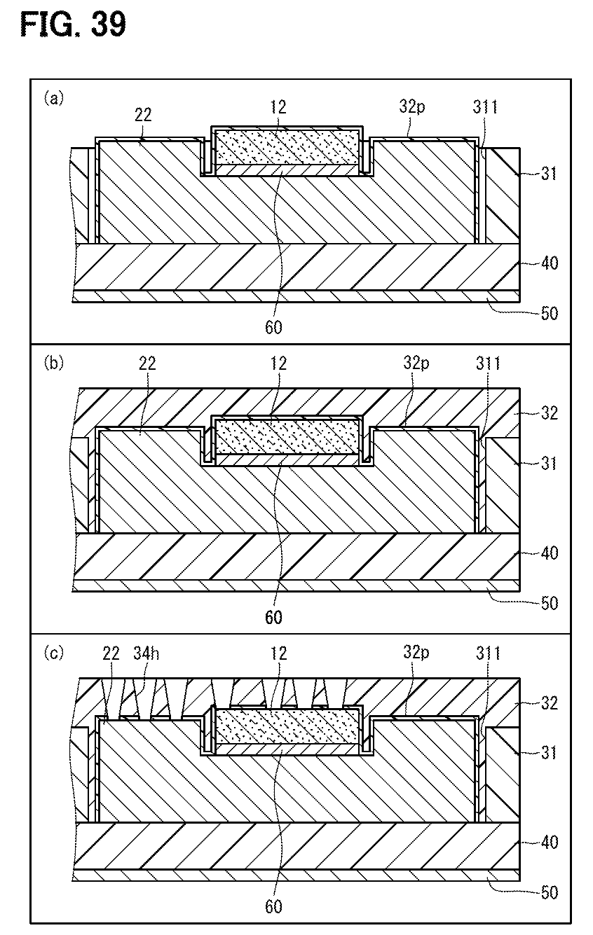

As in the modification illustrated in (a) of FIG. 39, before the build-up layer 32 is provided, a polyamide layer 32p mainly composed of polyamide may be provided on the front surfaces of the second heat sink 22 and the second semiconductor element 12. The process of providing the polyamide layer 32p is performed between the processes illustrated in (d) of FIG. 7 and (e) of FIG. 7. The polyamide layer 32p is provided to improve adhesion between the resin portion of the build-up layer 32 and the second heat sink 22 or the second semiconductor element 12, and to protect the second semiconductor element 12 from laser.

Thereafter, as illustrated in (b) of FIG. 39, the build-up layer 32 is provided. The process of (b) of FIG. 39 is similar to that of (e) and (f) of FIG. 7.

As illustrated in (c) of FIG. 39, a hole 34h is provided in the build-up layer 32 by laser to form the via 34. At this time, the polyamide layer 32p is partially removed by laser irradiation. Thereafter, resin residues generated during laser processing and the polyamide layer 32p irradiated with the laser are removed by a desmear treatment. As illustrated in FIG. 8a, a conductor is embedded in the hole 34h to form the via 34.

Therefore, in the semiconductor device 101, on at least the element front surface S12, the polyamide layer 32p is provided around the plurality of electrodes. That is, on at least the element front surface S12, the polyamide layer 32p is provided around the plurality of electrodes (gate electrodes, etc.) exposed on the element front surface S12. Naturally, the polyamide layer 32p may be provided on the side surface of the second semiconductor element 12. In the semiconductor device 101, the polyamide layer 32p is also provided on a part of the front surface of the second heat sink 22. That is, in the semiconductor device 101, the polyamide layer 32p is provided around portions of the second semiconductor element 12 and the second heat sink 22 where the vias 34 are electrically connected.

Similarly, the polyamide layer 32p may be provided for the first semiconductor element 11 and the first heat sink 21. The portions of the semiconductor elements 11, 12 and the heat sinks 21, 22 to which the vias 34 are electrically connected can also be referred to as energization portions.

Therefore, the semiconductor device 101 can be configured to improve adhesion between the resin portion of the build-up layer 32 and the heat sinks 21, 22. In addition, the semiconductor device 101 can be configured to include the semiconductor elements 11, 12 in which damage caused by laser is suppressed.

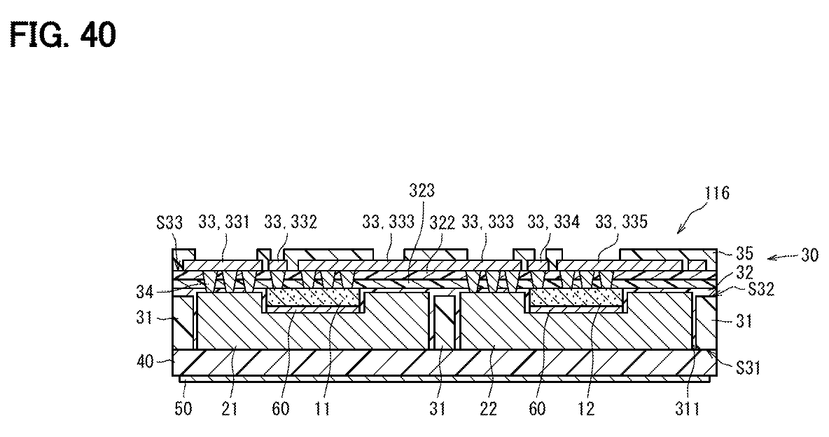

As in the modification illustrated in FIG. 40, a semiconductor device 116 may include a build-up layer 32 having a two-layer structure. The build-up layer 32 includes, above the heat sinks 21, 22, a first resin layer 323 not containing glass cloth and a second resin layer 322 containing glass cloth. That is, the first resin layer 323 is mainly composed of resin without containing glass cloth. On the other hand, the second resin layer 322 is mainly composed of glass cloth and resin. In the stacking direction, the first resin layer 323 and the second resin layer 322 are arranged in a stacked manner. The resin of the first resin layer 323 may be the same material as or a different material from the resin of the second resin layer 322. This makes it possible to suppress a decrease in insulation between the pattern wiring 33 and the heat sinks 21, 22.

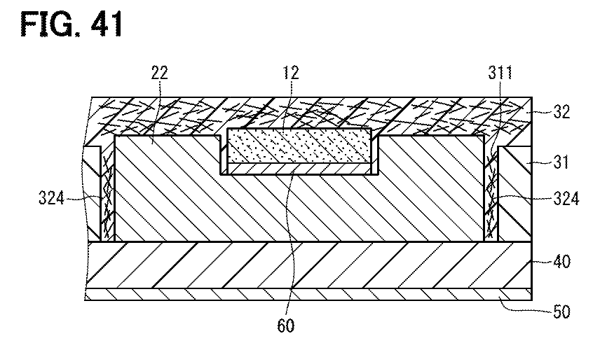

As in the modification illustrated in FIG. 41, a fiber filler 324 may be embedded in the build-up layer 32. This makes it possible to suppress deformation of the build-up layer 32 in the stacking direction.

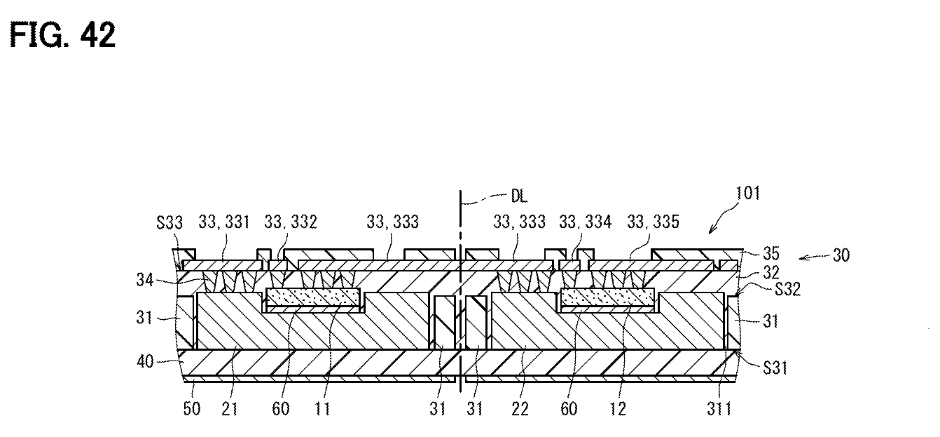

As in the modification illustrated in FIG. 42, the semiconductor device 101 may be cut from a large-format substrate on which a plurality of semiconductor devices 101 is formed and then individualized. The large-format substrate is a substrate including a plurality of semiconductor devices 101. In this case, the dicing line DL in the large-format substrate may include the resin portion of the build-up layer 32. That is, the core layer 31 may be covered with resin in the build-up layer 32. The side wall of the individualized semiconductor device 101 may be the resin in the build-up layer 32. Furthermore, the pattern wiring 33 and the back-surface metal layer 50 are not provided on the dicing line DL. Thus, it is possible to suppress generation of metal foreign matter during cutting of the large-format substrate. Moreover, it is possible to suppress adhesion of metal foreign matter to wiring exposed on the front surface. Metal foreign matter can also be referred to as metal waste or cutting residue.

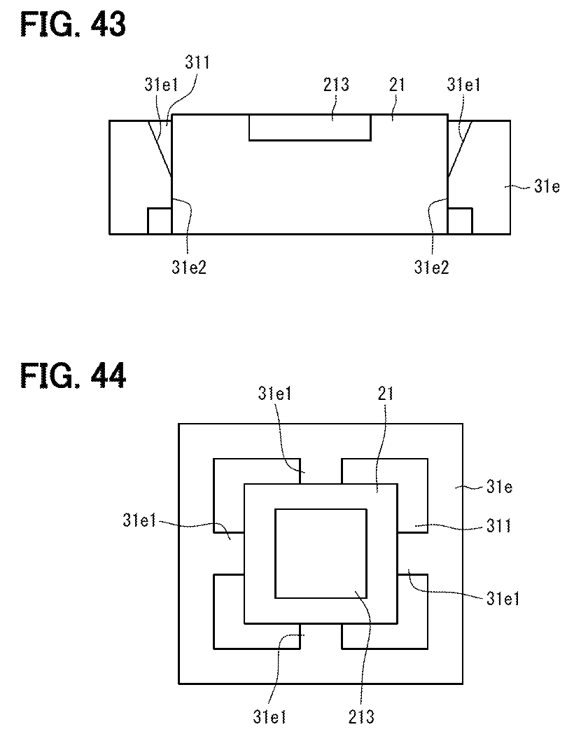

As in the modifications illustrated in FIGS. 43, 44, and 45, a core layer 31e may be provided with a through-hole 311 having an opening area that increases stepwise (gradually) from the heat dissipation insulating layer 40 side. The first heat sink 21 is in contact with a portion of the core layer 31e having the narrowest opening area. The portion having the narrowest opening area is a portion in contact with the first heat sink 21 and is thus referred to as a contact portion 31e2.

For example, as illustrated in FIG. 43, a surface of the core layer 31e facing the first heat sink 21 is a tapered portion 31e1. That is, a part of the through-hole 311 is surrounded by the tapered portion 31e1.

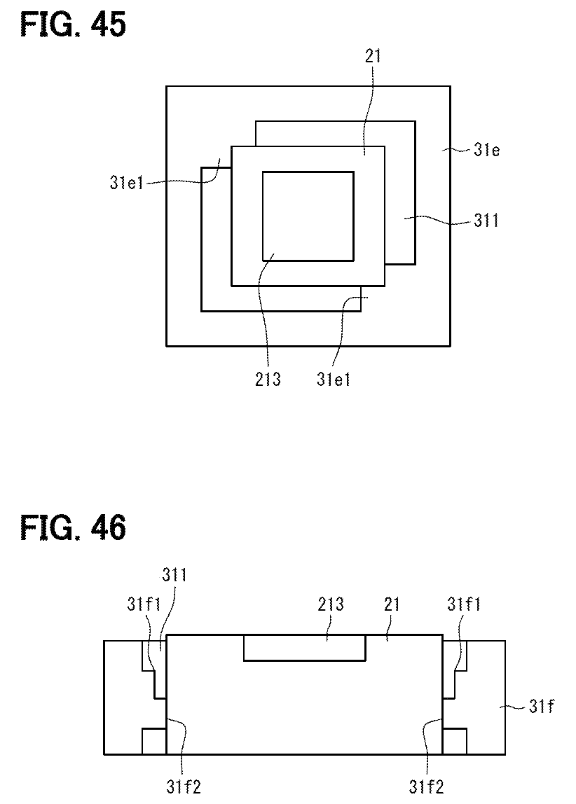

As illustrated in FIG. 44, the tapered portion 31e1 and the contact portion 31e2 are provided at positions facing the side surface of the first heat sink 21. As in the modification illustrated in FIG. 45, the tapered portion 31e1 and the contact portion 31e2 may be provided at positions facing a corner portion of the first heat sink 21.

Moreover, as in the modification illustrated in FIG. 46, the configuration can also be employed in a core layer 31f provided with a through-hole 311 having an opening area that increases stepwise from the heat dissipation insulating layer 40 side. In the core layer 31f, a surface facing the first heat sink 21 is a stepped portion 31f1. That is, a part of the through-hole 311 is surrounded by the stepped portion 31f1. The first heat sink 21 is in contact with a contact portion 31f2 having the narrowest opening area in the core layer 31f. Similarly to the above, the stepped portion 31f1 and the contact portion 31f2 are provided at positions facing the side surface of the first heat sink 21 or positions facing the corner portion of the first heat sink 21.

The core layers 31e, 31f are similarly configured at the location where the second heat sink 22 is disposed. As a result, the positional accuracy of the heat sinks 21, 22 relative to the core layers 31e, 31f can be improved.

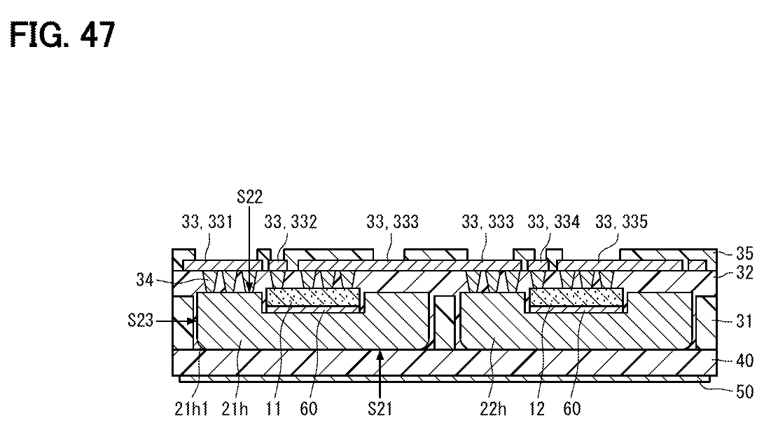

As in the modification illustrated in FIG. 47, in each of heat sinks 21h, 22h, a corner portion 21h1 between a back surface S21 and a side surface S23 continuous with the back surface S21 may have a chamfered shape. FIG. 47 illustrates a corner portion 21h1 having a curved surface shape as an example.

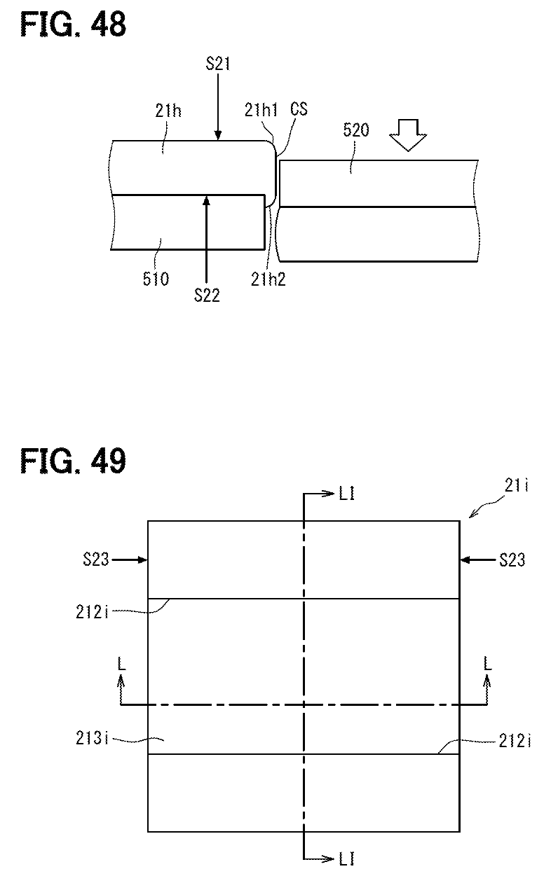

As illustrated in FIG. 48, the heat sinks 21h, 22h can be manufactured by press working. That is, in the press working, a plate-shaped member including portions to be the heat sinks 21h, 22h is disposed on a die 510 and pressed in the direction of the arrow shown in outline by a punch 520. Thus, the plate-shaped member is cut along a cut surface CS to form the heat sinks 21h, 22h. At this time, a burr 21h2 and the corner portion 21h1 having a curved surface shape are formed around the cut surface CS. The cut surface CS becomes the side surface S23. The burr 21h2 can also be referred to as a projection.

The heat sinks 21h, 22h are used such that a surface continuous with the corner portion 21h1 is the back surface S21 and a surface continuous with the burr 21h2 is the front surface S22. Thus, the heat sinks 21h, 22h are disposed on the heat dissipation insulating layer 40 such that the surface continuous with the corner portion 21h1 is the back surface S21. The heat sinks 21h, 22h are disposed on the heat dissipation insulating layer 40 such that the burr 21h2 projecting relative to the front surface S22 is on the pattern wiring 33 side. The continuous surface here is a surface other than the side surface S23.

As a result, the burr 21h2 is not formed on the back surface S21 side, so that the semiconductor device 101 can suppress electric field concentration on the back surface S21 side. Therefore, the semiconductor device 101 can reduce the thickness of the heat dissipation insulating layer 40, and can achieve high heat dissipation. That is, it becomes easier to ensure insulation and heat dissipation performance in the heat dissipation insulating layer 40.

Even when the corner portion 21h1 has a flat chamfered shape, a similar effect can be obtained. Further, by increasing the thickness of the resin in the build-up layer 32, the spacing between the pattern wiring 33 and the burr 21h2 can be increased.

Moreover, the resin portion of the build-up layer 32 has a greater linear expansion coefficient than the heat sinks 21, 22. In particular, the resin portion and the heat sinks 21, 22 have a large difference in linear expansion coefficient in the stacking direction. In the stacking direction, the linear expansion coefficient of the resin portion is significantly greater than those of the heat sinks 21, 22. Thus, the resin portion thermally expands more than the heat sinks 21, 22.

For this reason, stress associated with a difference in linear expansion coefficient tends to be applied to the portion where the resin portion and the heat sinks 21, 22 are in contact with each other. In particular, cracks or delamination may occur at the corner portion 21h1 of the resin portion and the heat sinks 21, 22 due to repeated application of stress during solder reflow or thermal cycling.

However, the semiconductor device 101 has a curved surface shape at the corner portion 21h1. Therefore, the stress at the location where the resin portion is in contact with the corner portion 21h1 is reduced.

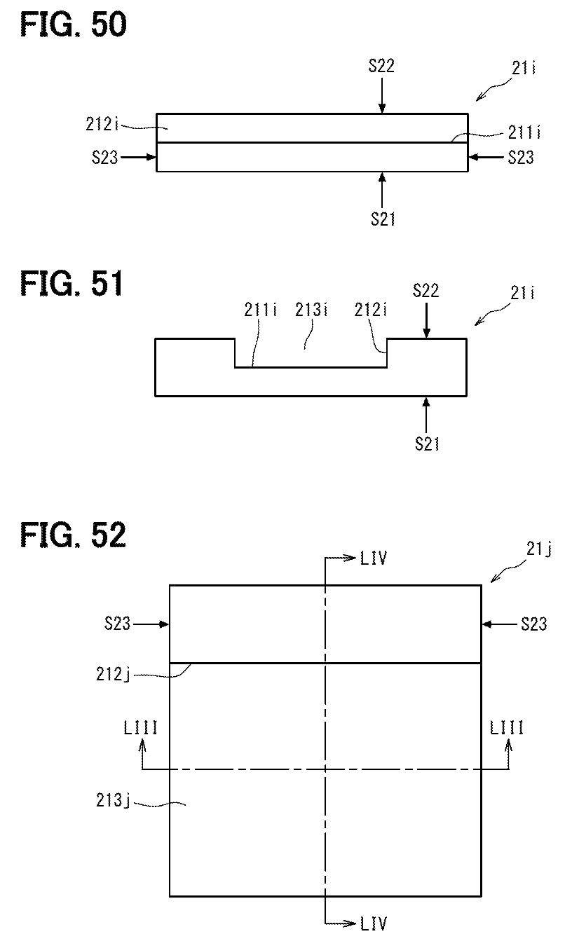

As in the modification illustrated in FIGS. 49, 50, and 51, a first heat sink 21i has a plurality of side surfaces S23 continuous with the back surface S21. The first heat sink 21i may be provided with a groove-shaped recess 213i provided over two side surfaces S23. That is, the first heat sink 21i is provided with the groove-shaped recess 213i as the portion in which the first semiconductor element 11 is mounted. The groove-shaped recess 213i is provided by a bottom portion 211i and two side walls 212i continuous with both ends of the bottom portion 211i. It can also be said that the groove-shaped recess 213i is defined by the bottom portion 211i and two side walls 212i facing each other. Therefore, the groove-shaped recess 213i is provided between the two side surfaces S23 in a facing positional relationship.

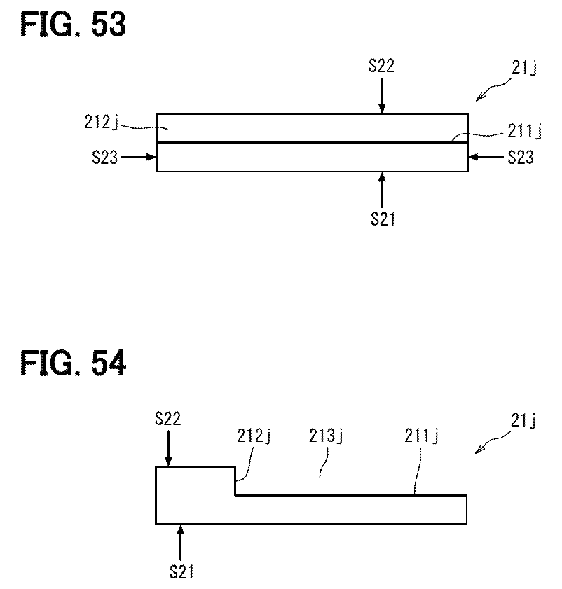

As in the modification illustrated in FIGS. 52, 53, and 54, a first heat sink 21j may be provided with a groove-shaped recess 213j provided over the two side surfaces S23. That is, the first heat sink 21j is provided with the groove-shaped recess 213j as the portion in which the first semiconductor element 11 is mounted. The groove-shaped recess 213j is provided by a bottom portion 211j and one side wall 212j continuous with one end of the bottom portion 211j. It can also be said that the groove-shaped recess 213j is defined by the bottom portion 211j and one side wall 212j.

The first heat sinks 21i, 21j can be manufactured by roll forming. Thus, the first heat sinks 21i, 21j can be manufactured relatively inexpensively. Therefore, the cost of the first heat sinks 21i, 21j can be reduced. The heat sink 22 on which the second semiconductor element 12 is mounted may be similarly configured.

The other modifications described thus far can be applied to the above embodiments and modifications. Moreover, other modifications can be applied to embodiments and modifications to be described below.

### Thirteenth Embodiment

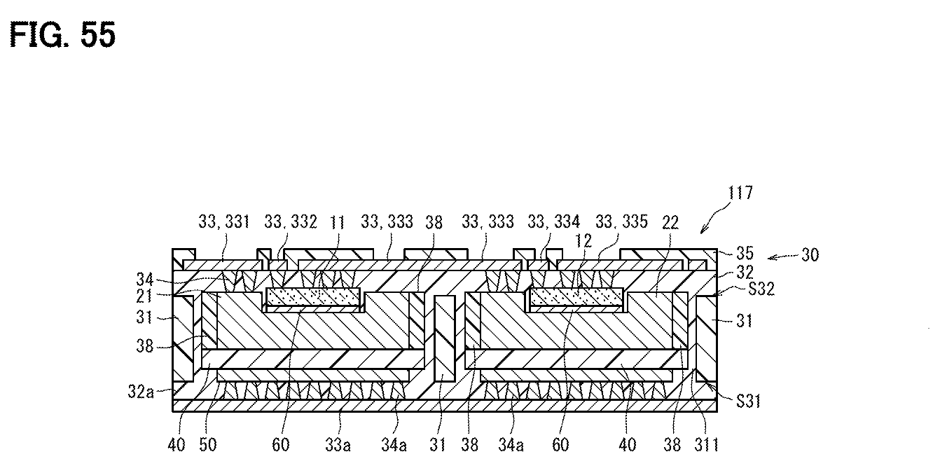

A semiconductor device 117 of a thirteenth embodiment will be described with reference to FIGS. 55, 56, and 57. The semiconductor device 117 differs from the above embodiments and the above modifications mainly in that a heat dissipation insulating layer 40 is provided for each of the heat sinks 21, 22.

As illustrated in FIG. 55, the semiconductor device 117 includes a plurality of integrated substrates each formed by integrating one heat sink and one heat dissipation insulating layer 40. That is, in the semiconductor device 117, the semiconductor elements 11, 12 are provided with the heat sinks 21, 22 and the heat dissipation insulating layers 40, respectively. That is, the semiconductor device 117 includes the same number of heat sinks 21, 22 as the semiconductor elements 11, 12, and the same number of heat dissipation insulating layers 40 as the semiconductor elements 11, 12.

More specifically, the first semiconductor element 11 is mounted on the first heat sink 21. The heat dissipation insulating layer 40 is provided on the back surface S21 of the first heat sink 21. The heat dissipation insulating layer 40 is in contact with the back surface S21 of the first heat sink 21. The first heat sink 21 and the heat dissipation insulating layer 40 to which the first heat sink 21 is connected can also be referred to as a first integrated substrate.

The second semiconductor element 12 is mounted on the second heat sink 22. The heat dissipation insulating layer 40 is provided on the back surface S21 of the second heat sink 22. The heat dissipation insulating layer 40 is in contact with the back surface S21 of the second heat sink 22. The second heat sink 22 is connected to the heat dissipation insulating layer 40 that is separate from the heat dissipation insulating layer 40 in the first integrated substrate. The second heat sink 22 and the heat dissipation insulating layer 40 to which the second heat sink 22 is connected can also be referred to as a second integrated substrate.

Moreover, the semiconductor device 117 includes the back-surface metal layer 50 in contact with the surface side of each heat dissipation insulating layer 40 opposite to each of the heat sinks 21, 22. That is, the heat sinks 21, 22 are connected to one surface of the heat dissipation insulating layer 40, and the back-surface metal layer 50 is connected to the other surface. The other surface is a surface opposite to the one surface.

The first integrated substrate may include the back-surface metal layer 50. Similarly, the second integrated substrate may include the back-surface metal layer 50. In this case, the first integrated substrate includes a set of the first heat sink 21, the heat dissipation insulating layer 40, and the back-surface metal layer 50. On the other hand, the second integrated substrate includes a set of the second heat sink 22, the heat dissipation insulating layer 40, and the back-surface metal layer 50. The first heat sink 21 and the back-surface metal layer 50 in the first integrated substrate are electrically insulated by the heat dissipation insulating layer 40 in the first integrated substrate. The second heat sink 22 and the back-surface metal layer 50 in the second integrated substrate are electrically insulated by the heat dissipation insulating layer 40 in the second integrated substrate.

In the present embodiment, as an example, the heat sinks 21, 22 each having a plate thickness greater than that of the back-surface metal layer 50 are employed. However, the heat sinks 21, 22 and the back-surface metal layer 50 may have substantially the same plate thickness. The heat sinks 21, 22 and the back-surface metal layer 50 may be configured so as to be capable of being patterned. Each of the heat sinks 21, 22 can also be referred to as a first metal layer or a first metal film. On the other hand, the back-surface metal layer 50 can also be referred to as a second metal layer or a second metal film.

Each integrated substrate is disposed in the through-hole 311 of the core layer 31. That is, the core layer 31 is provided with the plurality of through-holes 311. In the through-holes 311, the respective integrated substrates are individually disposed.

Similarly to the semiconductor device 101, the semiconductor device 117 includes the build-up layer 32. Moreover, in the semiconductor device 117, a back-surface-side build-up layer 32a is provided on the heat dissipation insulating layer 40 side. In the present embodiment, as an example, the back-surface-side build-up layer 32a including an electrically insulating resin portion, a conductive heat-dissipating via 34a, and a conductive heat-dissipating metal layer 33a is employed.

The heat-dissipating via 34a is connected to the surface of the back-surface metal layer 50 opposite to the surface in contact with the heat dissipation insulating layer 40. The heat-dissipating metal layer 33a is connected to the plurality of heat-dissipating vias 34a. In the back-surface-side build-up layer 32a, the heat-dissipating metal layer 33a is exposed from the resin portion. The heat-dissipating metal layer 33a has a function as a heat dissipation member on the back surface side.

However, the present disclosure may not include the heat-dissipating via 34a and the heat-dissipating metal layer 33a. In this case, in the semiconductor device 117, the back-surface metal layer 50 is preferably exposed from the resin portion of the back-surface-side build-up layer 32a. As a result, the semiconductor device 117 can dissipate heat from the back-surface metal layer 50 even when the heat-dissipating via 34a and the heat-dissipating metal layer 33a are not provided.

Here, the integrated substrate will be described in detail. As illustrated in FIG. 55, the heat dissipation insulating layer 40 is provided to project relative to the heat sink side surface of each of the heat sinks 21, 22 and the back-surface metal layer side surface of the back-surface metal layer 50 in the planar direction. That is, the heat dissipation insulating layer 40 is longer than the heat sinks 21, 22 and the back-surface metal layer 50 in the planar direction. In other words, the heat sinks 21, 22 and the back-surface metal layer 50 are shorter than the heat dissipation insulating layer 40 in the planar direction.

Thus, it is possible to increase the creepage distance (insulation distance) between the first heat sink 21 and the back-surface metal layer 50 in the first integrated substrate. Similarly, it is possible to increase the creepage distance between the second heat sink 22 and the back-surface metal layer 50 in the second integrated substrate. That is, in the semiconductor device 117, the creepage distance can be made longer than that in a configuration where the heat dissipation insulating layer 40 does not project. The semiconductor device 117 can ensure an insulation distance between the heat sinks 21, 22 and the back-surface metal layer 50 in the integrated substrate. The heat dissipation insulating layer 40 only needs to project in the planar direction relative to at least one of the heat sinks 21, 22 and the back-surface metal layer 50.

In addition, the semiconductor device 117 has a configuration in which the heat dissipation insulating layer 40 projects relative to each of the heat sinks 21, 22 and the back-surface metal layer 50 as described above. Therefore, in the semiconductor device 117, the spacing between the core layer 31 and the heat sinks 21, 22, and the spacing between the core layer 31 and the back-surface metal layer 50 are wider than those in the semiconductor device 101. The spacing here is a distance in the planar direction. The spacing here can also be referred to as a gap between the core layer 31 and the heat sinks 21, 22 or the back-surface metal layer 50.

Therefore, the semiconductor device 117 needs to have a greater amount of resin in the build-up layer 32 than the semiconductor device 101. However, in the semiconductor device 117, there is a concern that the amount of resin of the build-up layer 32 is insufficient and overall thickness variation increases. The resin portion of the build-up layer 32 has a greater linear expansion coefficient than the heat sinks 21, 22. Therefore, in the semiconductor device 117, there is a possibility that stress associated with a difference in linear expansion coefficient increases when the amount of resin is increased. In the semiconductor device 117, there is a concern that cracks may occur in the resin portion due to the stress, or that delamination may occur at a boundary between the resin portion and the heat sinks 21, 22 or the like.

Therefore, in the integrated substrate, an insulating member 38 having electrical insulation properties is provided on the heat sink side surface. The insulating member 38 is provided on one side in the stacking direction relative to the heat dissipation insulating layer 40, and is provided in the planar direction relative to the heat sinks 21, 22. The insulating member 38 is in contact with the heat dissipation insulating layer 40 and the heat sinks 21, 22. The insulating member 38 is preferably made of a material having a linear expansion coefficient close to the linear expansion coefficients of the heat sinks 21, 22. When the heat sinks 21, 22 are mainly composed of copper, the insulating member 38 is preferably made of a material having a linear expansion coefficient close to the linear expansion coefficient of copper. The insulating member 38 can be provided by molding or the like.

As a result, the semiconductor device 117 can suppress an increase in the amount of resin of the build-up layer 32. Therefore, the semiconductor device 117 can suppress thickness variation, cracks, and delamination as described above. The insulating member 38 only needs to be provided on at least one of the heat sink side surface and the back-surface metal layer side surface.

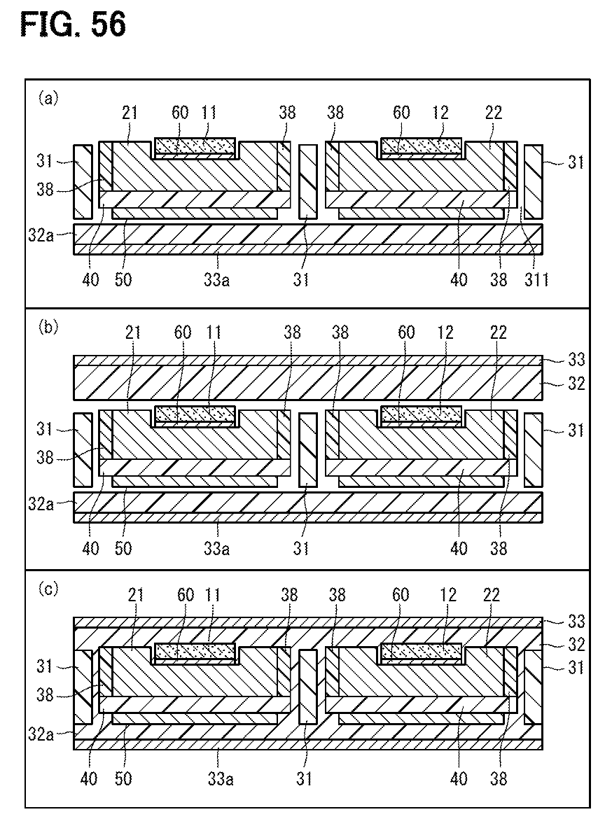

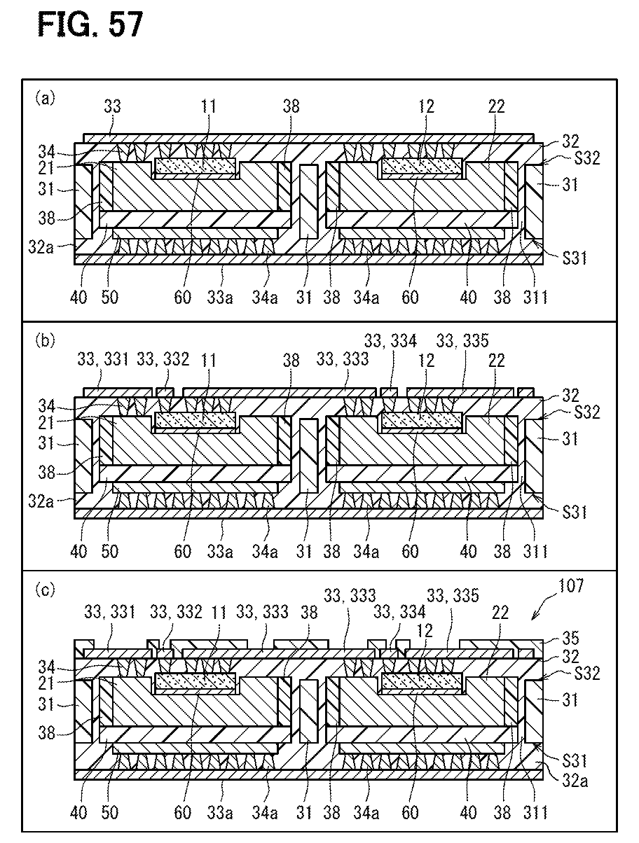

Here, a manufacturing method for the semiconductor device 117 will be described with reference to FIGS. 56 and 57. In the present manufacturing method, the process illustrated in (a) of FIG. 56 is performed after the process illustrated in (b) of FIG. 7. In (a) of FIG. 56, the core layer 31 is disposed on the back-surface-side build-up layer 32a, and the integrated substrate is disposed in the through-hole 311. In addition, here, an integrated substrate provided with the insulating member 38 is disposed.

In (b) of FIG. 56, the build-up layer 32 is then disposed on the core layer 31, as in (e) of FIG. 7. In this case, the pattern wiring 33 and the via 34 are not formed in the build-up layer 32. The reference numeral 33 denotes a thin film of copper or the like before being patterned. In (c) of FIG. 56, as in (f) of FIG. 7, press molding is performed.

Next, as illustrated in (a) of FIG. 57, the via 34 and the heat-dissipating via 34a are formed. Filled vias are formed as the via 34 and the heat-dissipating via 34a (filled via forming process). Thereafter, as illustrated in (b) of FIG. 57, a thin film is patterned to form the pattern wiring 33 (pattern wiring forming process). As illustrated in (c) of FIG. 57, the solder resist 35 is formed (solder resist forming process).

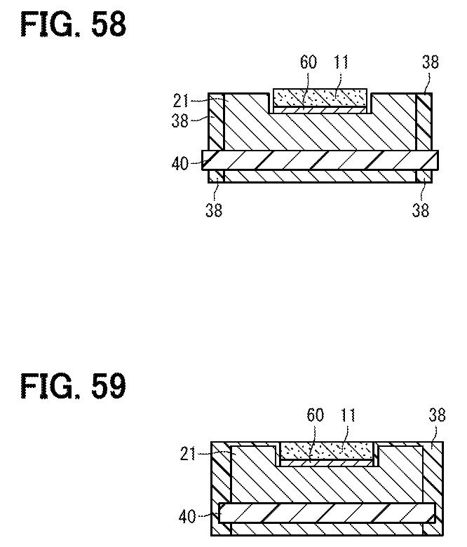

As illustrated in FIG. 58, the insulating member 38 may be provided on both the heat sink side surface and the back-surface metal layer side surface. The insulating member 38 is provided on one side in the stacking direction relative to the heat dissipation insulating layer 40, and is provided in the planar direction relative to the heat sinks 21, 22. Furthermore, the insulating member 38 is provided on the other side in the stacking direction relative to the heat dissipation insulating layer 40, and is provided in the planar direction relative to the back-surface metal layer 50. The insulating member 38 is in contact with the heat dissipation insulating layer 40, the heat sinks 21, 22, and the back-surface metal layer 50. The insulating member 38 can be provided by molding or the like.

As illustrated in FIG. 59, the insulating member 38 may be provided to entirely cover the integrated substrate and to cover the semiconductor elements 11, 12 mounted on the heat sinks 21, 22. The insulating member 38 is also provided in a gap between the semiconductor elements 11, 12 and the heat sinks 21, 22. The insulating member 38 may be provided to cover the electrodes of the semiconductor elements 11, 12. In this case, the insulating member 38 at the location where wiring needs to be led out may be removed by laser. The insulating member 38 can be provided by potting or the like.

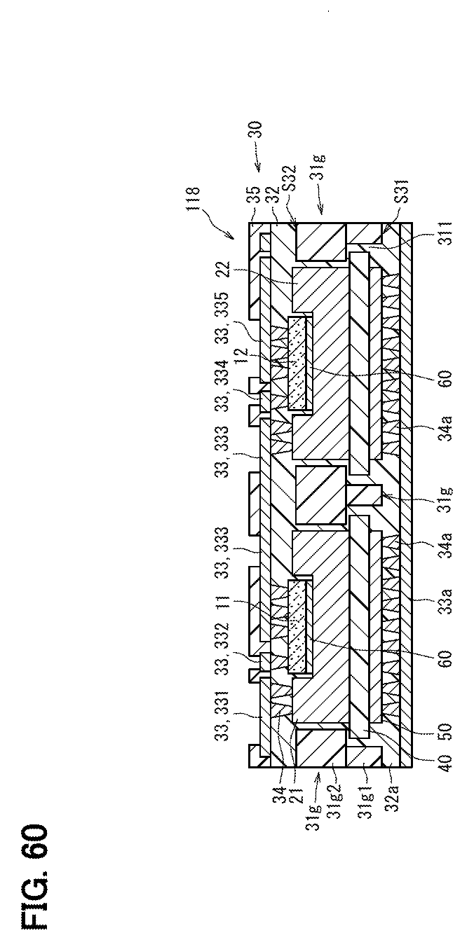

Moreover, as illustrated in FIGS. 60 to 62, an increase in the spacing between the heat sink and the core may be suppressed by the shape of the core layer 31g, and an increase in the amount of resin of the build-up layer 32 may be suppressed. A semiconductor device 118 is a modification of the semiconductor device 117. The semiconductor device 118 includes a core layer 31g. The core layer 31g includes a core base portion 31g1 and a core projection 31g2 that projects in the planar direction relative to the core base portion 31g1. The core projection 31g2 is provided adjacent to each of the heat sinks 21, 22 in the planar direction. The core base portion 31g1 is similar to the core layer 31. The planar direction can also be referred to as a direction intersecting the stacking direction. This enables the semiconductor device 118 to suppress an increase in the amount of resin of the build-up layer 32 without including the insulating member 38.

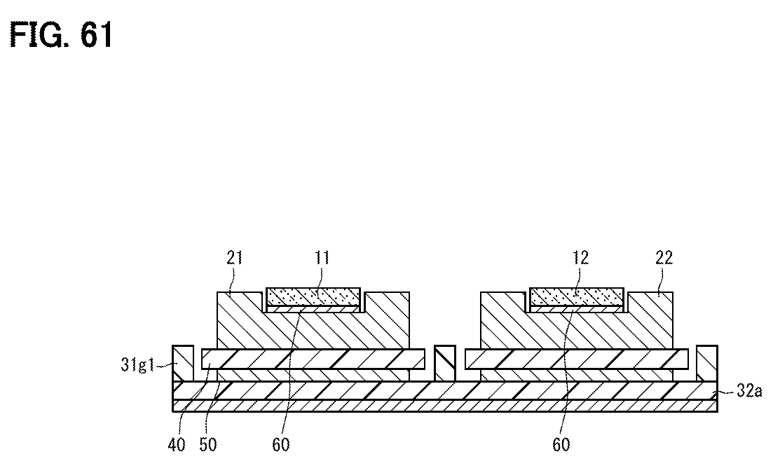

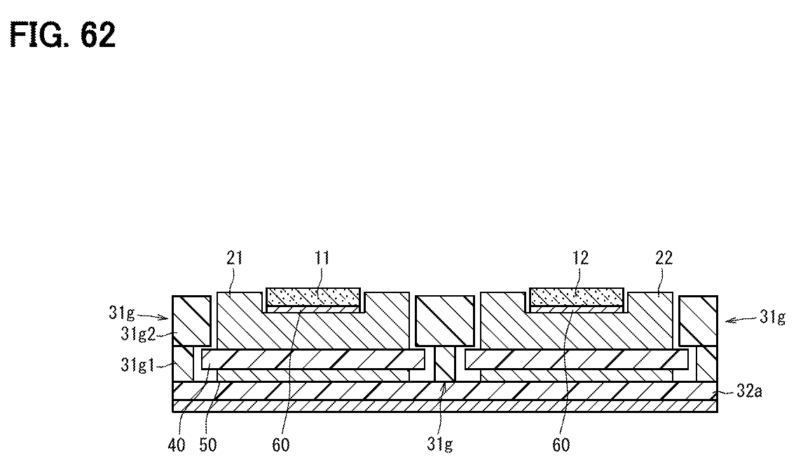

For the core base portion 31g1 and the core projection 31g2, separate components can be used. In this case, as illustrated in FIG. 61, the core base portion 31g1 is disposed on the back-surface-side build-up layer 32a, and the integrated substrate is disposed in the through-hole 311. Thereafter, as illustrated in FIG. 62, the core projection 31g2 is disposed on the core base portion 31g1. However, the core base portion 31g1 and the core projection 31g2 may be provided as an integral body.

As illustrated in (c) of FIG. 39, the via 34 is formed by embedding a conductor in the hole 34h formed by laser. Laser irradiation is performed using a positioning reference. The core layer 31 is embedded in the build-up layer 32. Therefore, the positioning reference is detected by an X-ray or the like. The positioning reference can also be referred to as an alignment mark.

The positioning reference is provided on the front surface of the core layer 31 or the like. In this case, the positioning references are located at a position relatively far from the electrodes of the semiconductor elements 11, 12. Therefore, there is a concern that, with this positioning reference, positional tolerance variation to the electrode increases. When the positional tolerance increases, it is necessary to enlarge the electrodes of the semiconductor elements 11, 12 as target values. Therefore, the semiconductor elements 11, 12 have small active areas when the element sizes remain unchanged. Further, the semiconductor elements 11, 12 require larger element sizes to ensure the active areas. The electrodes of the semiconductor elements 11, 12 are electrodes (gate electrodes, etc.) provided on the element front surface S12.

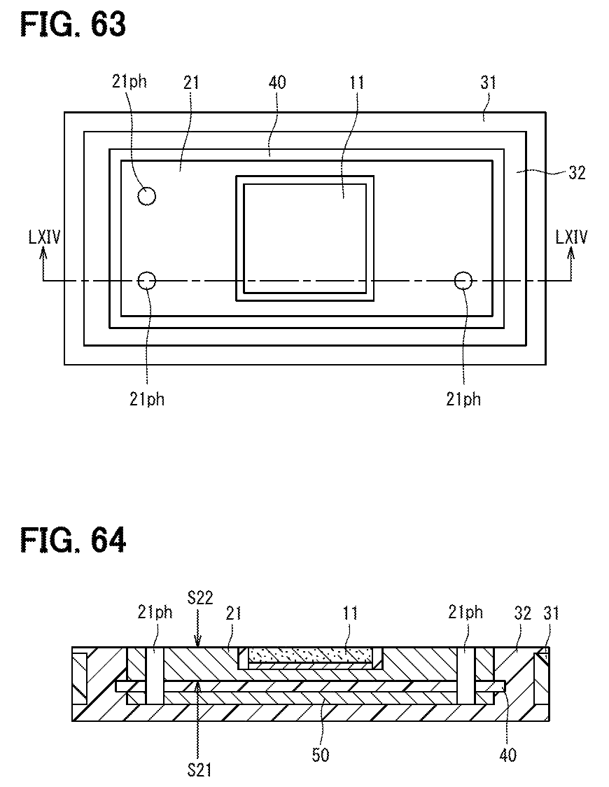

Therefore, as illustrated in FIGS. 63 and 64, as a modification of the semiconductor device 117, a first integrated substrate provided with a positioning hole 21ph penetrating in the thickness direction may be used. That is, as illustrated in FIG. 64, the heat sink 21, the heat dissipation insulating layer 40, and the back-surface metal layer 50 are each provided with the positioning hole 21ph penetrating in the stacking direction. The positioning hole 21ph is a hole serving as a positioning reference for laser irradiation.

Therefore, when the via 34 is formed, the positioning hole 21ph is detected by X-rays or the like. Laser irradiation is performed at the position for forming the via 34, using the positioning hole 21ph as a reference. The position at which the via 34 is formed is, for example, a portion formed on the electrode of the element front surface S12 in the build-up layer 32. FIG. 63 illustrates the element front surface S12 of semiconductor element 11. Therefore, the gate electrode and the like are provided within the semiconductor element 11 illustrated in FIG. 63. The positioning hole 21ph may be provided in the second integrated substrate.

This enables a reduction in positional tolerance variation. Therefore, the semiconductor elements 11, 12 can ensure active areas without increasing the element sizes.

The positioning hole 21ph can also be applied to configurations other than the semiconductor device 117. That is, even in configurations other than the semiconductor device 117, the positioning hole 21ph can be used as a positioning reference for laser irradiation. The configurations other than the semiconductor device 117 are the configurations of the semiconductor device 118, the first to twelfth embodiments, and the modifications. The configurations other than the semiconductor device 117 include embodiments and modifications to be described below.

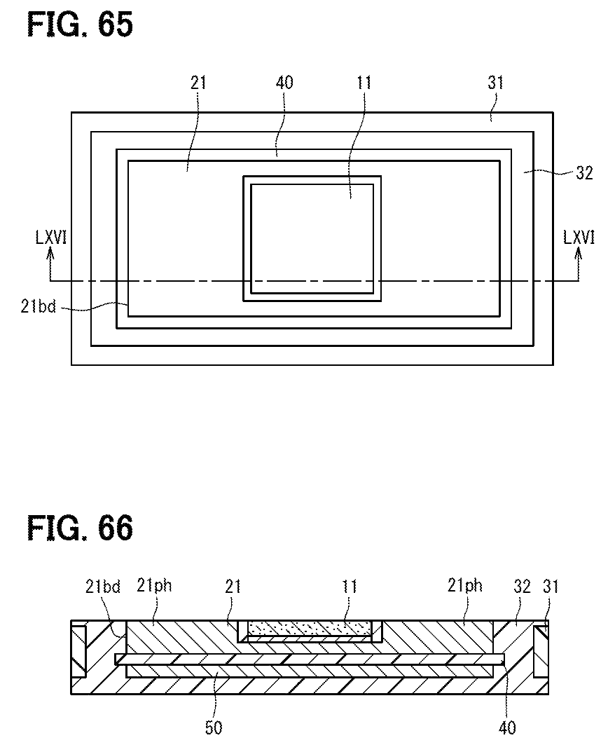

As illustrated in FIGS. 65 and 66, as a modification of the semiconductor device 117, a first integrated substrate provided with a positioning boundary portion 21bd may be used. The first integrated substrate includes the first heat sink 21 mainly composed of copper and the heat dissipation insulating layer 40 mainly composed of resin. Therefore, as illustrated in FIG. 65, in the first integrated substrate, the boundary between the first heat sink 21 and the heat dissipation insulating layer 40 is provided as a positioning boundary portion 21bd in plan view. The positioning boundary portion 21bd is a positioning reference using a difference in X-ray transmittance.

In this manner, even when the positioning boundary portion 21bd is formed, positional tolerance variation can be reduced. Therefore, the semiconductor elements 11, 12 can ensure active areas without increasing the element sizes.

The positioning boundary portion 21bd can also be applied to configurations other than the semiconductor device 117. That is, even in configurations other than the semiconductor device 117, the positioning boundary portion 21bd can be used as a positioning reference for laser irradiation. The positioning boundary portion 21bd can be applied as long as the heat dissipation insulating layer 40 projects in the planar direction relative to the heat sinks 21, 22.

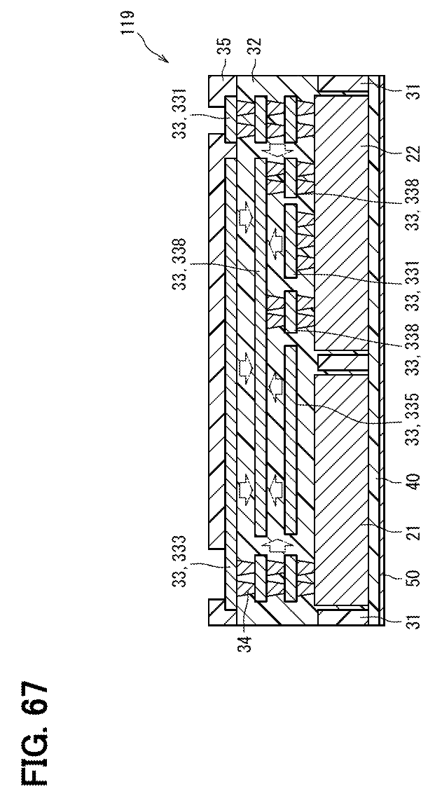

As illustrated in a modification of FIG. 67, a semiconductor device 119 may include heat-dissipating wiring 338. The semiconductor device 119 is a modification of the semiconductor device 101. The build-up layer 32 includes the pattern wiring 33 that is arranged in a stacked manner. The semiconductor device 119 is a cross-sectional view of the location in which the semiconductor elements 11, 12 are not provided.

Reference numeral 331 in FIG. 67 denotes a P wiring portion including the P pad 331 in the pattern wiring 33. The P pad 331 is a terminal on the high-potential side. Thus, the P wiring portion can also be referred to as a high-potential-side wiring portion. Here, reference numeral 331 is also used for the P wiring portion. The P wiring portion 331 is connected to the high-potential-side electrodes of the semiconductor elements 11, 12. The P wiring portion 331 only needs to be electrically connected to the high-potential side electrode, and may not be directly connected.

Reference numeral 335 in FIG. 67 denotes an N wiring portion including the N pad 335 in the pattern wiring 33. The N pad 335 is a terminal on the low-potential side. Thus, the N wiring portion can also be referred to as a low-potential-side wiring portion. Here, reference numeral 335 is also used for the N wiring portions. The N wiring portion 335 is connected to the low-potential-side electrodes of the semiconductor elements 11, 12. The N wiring portion 335 only needs to be electrically connected to the low-potential-side electrode, and may not be directly connected. Reference numeral 333 in FIG. 67 denotes an O wiring portion including the O pad 333 in the pattern wiring 33. The O pad 333 is an output terminal. Here, reference numeral 333 is also used for the O wiring portion. The O wiring portion can also be referred to as an output wiring portion.

As illustrated in FIG. 67, the heat-dissipating wiring 338 is a part of the pattern wiring 33. The heat-dissipating wiring 338 is disposed between the P wiring portion 331 or the N wiring portion 335 and the O wiring portion 333 in the stacking direction. The heat-dissipating wiring 338 is disposed between the P wiring portion 331 and the O wiring portion 333, between the P wiring portion 331 and the N wiring portion 335, and between the N wiring portion 335 and the O wiring portion 333 in the planar direction. The heat-dissipating wiring 338 is connected to the second heat sink 22 through the via 34. The heat-dissipating wiring 338 may be connected to the first heat sink 21.

In the heat-dissipating wiring 338, heat is transferred from the P wiring portion 331, the O wiring portion 333, and the N wiring portion 335 as indicated by arrows of alternate long and short dash lines. The heat-dissipating wiring 338 can release heat to the second heat sink 22 through the via 34. That is, the heat-dissipating wiring 338 functions as a heat dissipation path.

This enables the semiconductor device 119 to improve the heat dissipation performance of the wiring in the build-up layer 32. The heat-dissipating wiring 338 also functions as an electric field relaxation layer.

The heat-dissipating wiring 338 can also be applied to configurations other than the semiconductor device 101. The configurations other than the semiconductor device 101 are the configurations of the second to thirteenth embodiments and the modifications. The configurations other than the semiconductor device 101 include the configurations of embodiments and each modification to be described below.

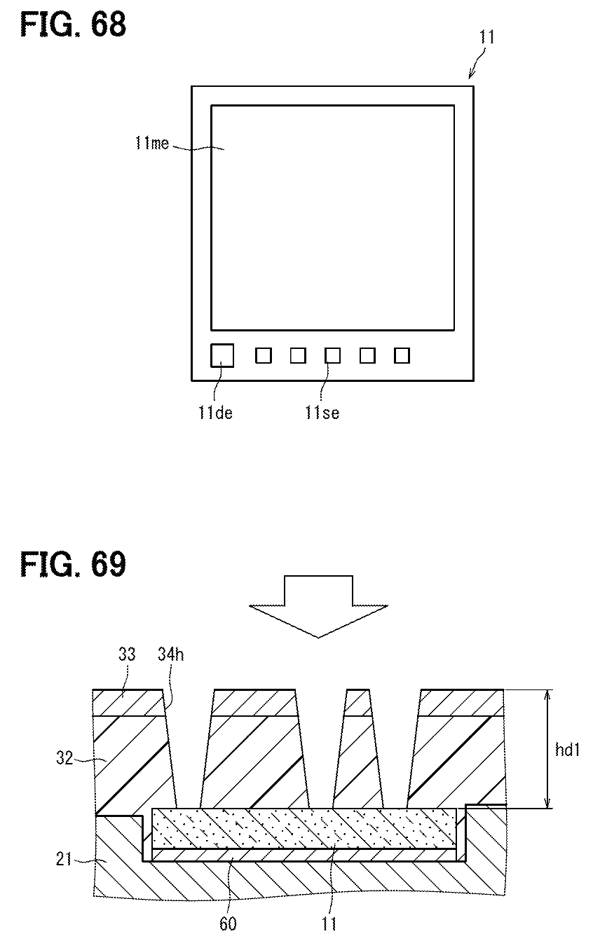

As illustrated in FIGS. 68 and 69, the first semiconductor element 11 may include a dummy electrode 11de on the element front surface S12. The dummy electrode 11de can also be referred to as a dummy pad provided on the element front surface S12 of the first semiconductor element 11. The dummy electrode 11de is a non-conductive electrode. That is, the dummy electrode 11de does not have an electrical function unlike the gate electrode and the like.

The dummy electrode 11de is provided at the same position as a gate electrode or the like provided on the element front surface S12 of the first semiconductor element 11. The position here is a position in the stacking direction.

The dummy electrode 11de is preferably provided in an inactive region of the first semiconductor element 11. As will be described later, the dummy electrode 11de is irradiated with laser. By providing the dummy electrode 11de in the inactive region, it is possible to suppress an influence on the characteristics of the first semiconductor element 11 even when damage is caused by the laser irradiation.

The dummy electrode 11de is preferably composed mainly of silver or aluminum having a high laser reflectance. Silver and aluminum can be formed by electrode plating, stud bonding, paste coating, sputtering, or the like.

As illustrated in FIG. 69, when the via 34 is formed, the hole 34h is provided by performing laser irradiation from the direction of the arrow shown in outline. The distance by which the laser forms holes varies depending on the thickness of the build-up layer 32. Usually, holes are formed by laser under a predetermined laser machining condition. Therefore, when the thickness of the build-up layer 32 is smaller than expected, damage may occur to the first semiconductor element 11. It is conceivable to increase the thickness of the electrode on the element front surface S12 to mitigate damage to the first semiconductor element 11. However, an increase in the plating thickness of the electrode leads to an increase in cost.

The dummy electrode 11de is used for distance measurement when the hole 34h is provided. That is, the dummy electrode 11de is used to measure a depth hd1 of the hole 34h. The depth hd1 can also be referred to as the spacing from the front surface of the pattern wiring 33 to the electrode of the element front surface S12. The depth hd1 can also be referred to as the distance by which the hole 34h is formed.

Thus, when the via 34 is formed, the dummy electrode 11de is first irradiated with laser to measure a depth hd1 of the hole 34h to be provided. Thereafter, using the measurement result as a laser processing condition, the hole 34h is provided in the build-up layer 32 by laser. This makes it possible to suppress damage to the first semiconductor element 11 without increasing the plating thickness.

The dummy electrode 11de can also be applied to configurations other than the semiconductor device 101. The dummy electrode 11de may be provided in the second semiconductor element 12.

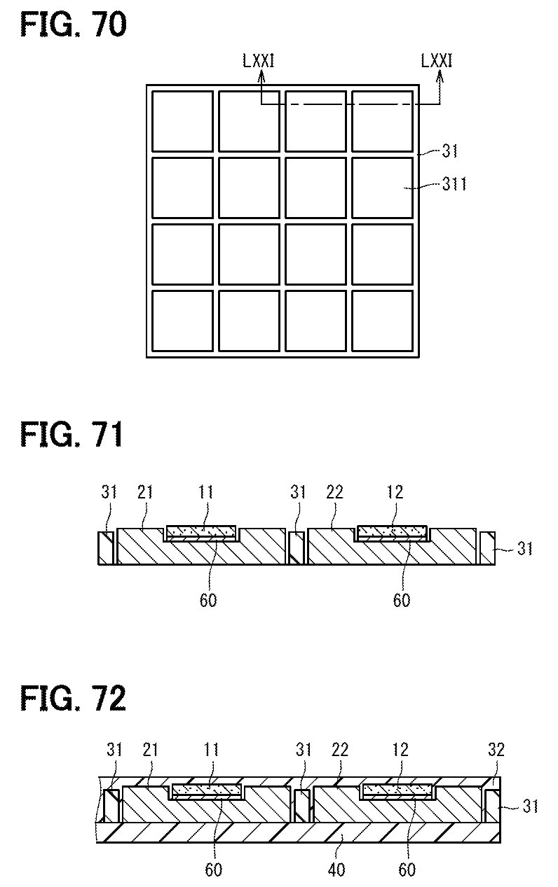

In the first embodiment, an example in which the through-hole 311 is formed by punching the core layer 31 has been employed. However, as a modification of the semiconductor device 101, the core layer 31 manufactured by injection molding using a liquid crystal polymer or transfer molding using an epoxy resin may be used. As illustrated in FIG. 70, the core layer 31 is provided with a through-hole 311 in advance without performing punching, drilling, or the like.

In this case, the core layer 31 may be a liquid crystal polymer containing no glass cloth or an epoxy resin containing no glass cloth. It can be said that the core layer 31 is made of a resin having an isotropic thermal expansion coefficient.

As illustrated in FIG. 71, the heat sinks 21, 22 are disposed in the through-holes 311 of the core layer 31. FIG. 71 is a cross-sectional view of the location corresponding to the section-indicating line of FIG. 70. As illustrated in FIG. 72, the build-up layer 32 is formed. In FIG. 72, illustration of the wiring is omitted to simplify the drawing. A part of the build-up layer 32 is also disposed in a gap between each of the heat sinks 21, 22 and the core layer 31. However, in the present disclosure, the build-up layer 32 is referred to as such for convenience.

The core layer 31 is provided by resin molding using a mold. Thus, the core layer 31 can suppress dimensional variation more effectively than when the through-hole 311 is provided by drilling or the like. Therefore, variation in the gap between the core layer 31 and each of the heat sinks 21, 22 can be suppressed. Therefore, variation in the amount of resin of the build-up layer 32 provided in the gap can also be suppressed. In addition, the semiconductor device 101 can suppress cracks and delamination caused by an increase in the amount of resin in the build-up layer 32.

Furthermore, the core layer 31 is preferably made of a material having a linear expansion coefficient close to the linear expansion coefficient of the resin portion of the build-up layer 32. This enables the core layer 31 and the build-up layer 32 to mitigate stress caused by a difference in linear expansion coefficient. Therefore, the semiconductor device 101 can suppress the application of stress to the pattern wiring 33, the via 34, and each of the semiconductor elements 11, 12, and can improve reliability.

The core layer 31 provided by resin molding using a mold can also be applied to configurations other than the semiconductor device 101. The core layer 31 made of a resin having an isotropic thermal expansion coefficient can also be applied to configurations other than the semiconductor device 101.

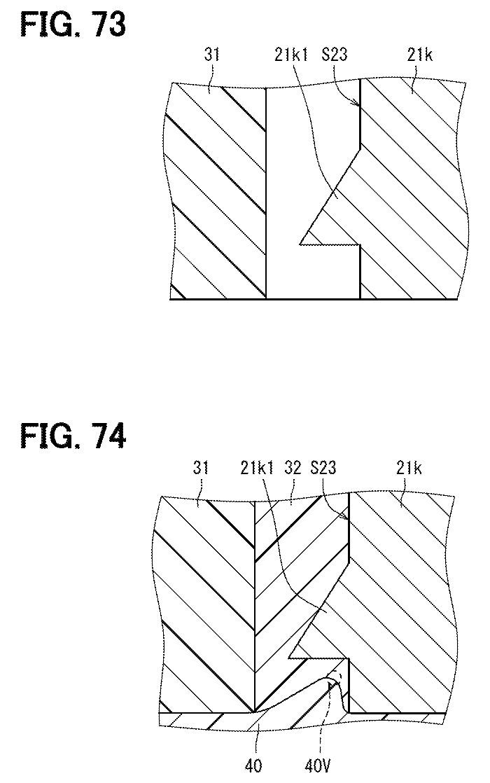

As in the modification illustrated in FIGS. 73 and 74, the semiconductor device 101 can also employ a heat sink 21k in which a heat sink protrusion 21k1 is provided on the surface facing the core layer 31. The heat sink protrusion 21k1 is a portion that projects relative to the side surface S23. The surface facing the core layer 31 corresponds to the side surface S23.

As illustrated in FIG. 73, the semiconductor device 101 forms the build-up layer 32 in a state where a gap has been formed between the core layer 31 and the heat sink 21k in the manufacturing process. At this time, the build-up layer 32 may not be completely filled in a space between the core layer 31 and the heat sink 21k. That is, in the build-up layer 32, a depression is formed between the core layer 31 and the heat sink 21k.

Thus, as illustrated in FIG. 74, the heat dissipation insulating layer 40 is connected to the core layer 31 and the heat sink 21k in a state where a depression is formed between the core layer 31 and the heat sink 21k. Therefore, the heat dissipation insulating layer 40 has a shape that enters the depression. That is, a part of the heat dissipation insulating layer 40 is also formed between the core layer 31 and the heat sink 21k. The depression may not be filled with the heat dissipation insulating layer 40. That is, a void may be generated between the heat dissipation insulating layer 40 and the build-up layer 32.

FIG. 74 illustrates a state in which the depression is filled with the heat dissipation insulating layer 40. Reference numeral 40V denotes a vertex of the heat dissipation insulating layer 40. When the depression is not filled with the heat dissipation insulating layer 40, a void is formed at the vertex 40V.

In this case, in the build-up layer 32, stress concentrates in the vicinity of the vertex 40V of the heat dissipation insulating layer 40. There is a possibility that a crack occurs in the build-up layer 32 starting from the vicinity of the vertex 40V of the heat dissipation insulating layer 40. When the crack reaches the heat sink 21k, the interface between the build-up layer 32 and the heat sink 21k may delaminate.

However, the heat sink 21k is provided with the heat sink protrusion 21k1. Therefore, the semiconductor device 101 can suppress the development of cracks and the development of delamination. The heat sink protrusion 21k1 may be provided on the second heat sink 22.

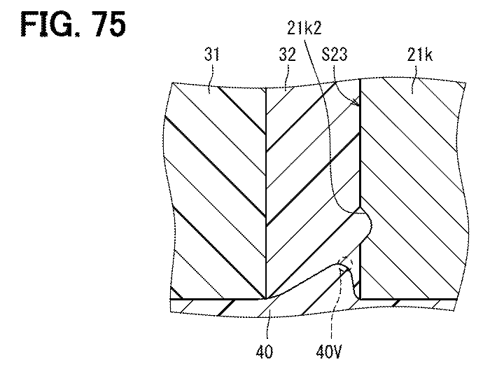

As in the modification illustrated in FIG. 75, the semiconductor device 101 can also employ a heat sink 21k having a heat sink recess 21k2 provided on a surface facing the core layer 31. The heat sink recess 21k2 is a portion recessed relative to the side surface S23. Even when the semiconductor device 101 includes the heat sink 21k provided with the heat sink recess 21k2, the development of cracks and the development of delamination can be suppressed. The heat sink recess 21k2 may be provided in the second heat sink 22. The heat sink protrusion 21k1 and the heat sink recess 21k2 can also be applied to configurations other than the semiconductor device 101.

(Fourteenth Embodiment)

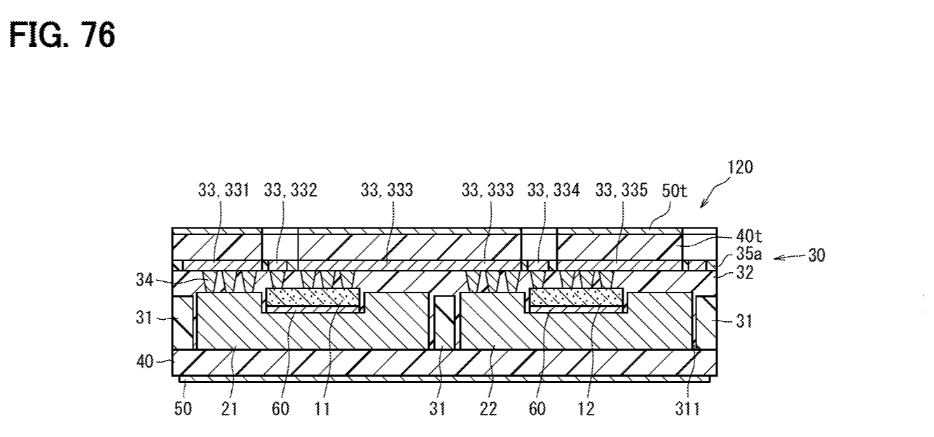

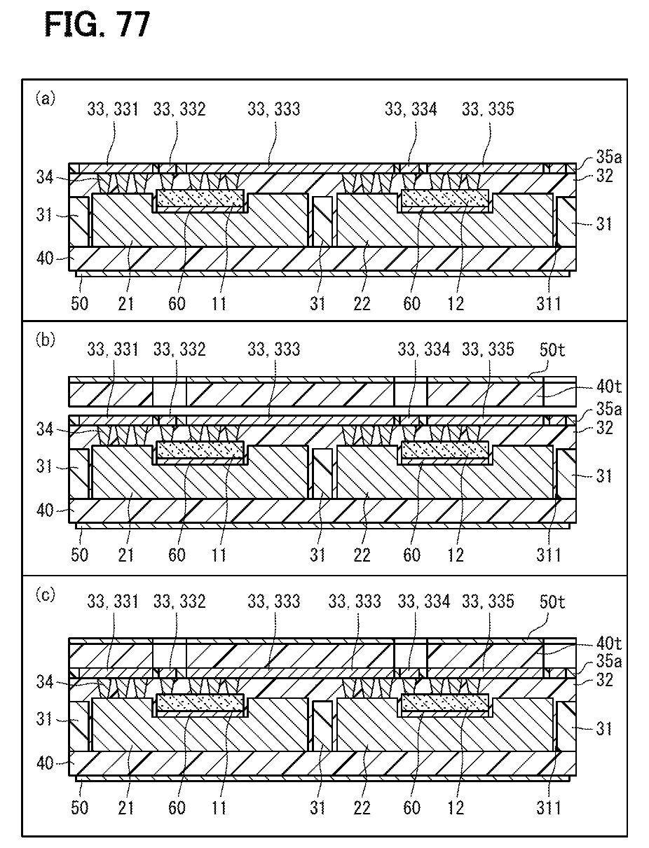

A semiconductor device 120 of a fourteenth embodiment will be described with reference to FIGS. 76 and 77. The semiconductor device 120 differs from the above embodiments and the above modifications mainly in that a front surface heat dissipation insulating layer 40t is provided.

As illustrated in FIG. 76, the semiconductor device 120 has a configuration similar to that of the semiconductor device 101. Moreover, the semiconductor device 120 includes the front surface heat dissipation insulating layer 40t. The front surface heat dissipation insulating layer 40t is provided to be in contact with the build-up layer 32. That is, in the semiconductor device 120, the core layer 31 is provided between the heat dissipation insulating layer 40 and the front surface heat dissipation insulating layer 40t. In the semiconductor device 120, the heat dissipation insulating layer 40, the core layer 31, and the front surface heat dissipation insulating layer 40t are provided in this order in the stacking direction. The heat dissipation insulating layer 40 and the front surface heat dissipation insulating layer 40t may be made of the same material or different materials.

In the semiconductor device 120, the pattern wiring 33 and the via 34 are provided between the front surface heat dissipation insulating layer 40t and each of the semiconductor elements 11, 12. The front surface heat dissipation insulating layer 40t and each of the semiconductor elements 11, 12 are connected by the pattern wiring 33 and the via 34. The front surface heat dissipation insulating layer 40t and each of the semiconductor elements 11, 12 are connected by the pattern wiring 33 and the via 34 provided immediately above each of the semiconductor elements 11, 12. Therefore, in the semiconductor device 120, heat from the semiconductor elements 11, 12 is more easily transferred to the front surface heat dissipation insulating layer 40t, and heat dissipation performance can be improved.

Moreover, the semiconductor device 120 includes a front-surface metal layer 50t in contact with a surface side of the front surface heat dissipation insulating layer 40t opposite to the build-up layer 32. That is, the semiconductor device 120 includes the back-surface metal layer 50 on one surface and the front-surface metal layer 50t on the opposite surface. The front-surface metal layer 50t may be made of the same material as the back-surface metal layer 50, or may be made of a different material. Thus, the semiconductor device 120 can also be said to have a double-sided heat dissipation structure.

The wiring of the semiconductor device 120 includes a plurality of external connection portions 331 to 337 exposed from the front surface heat dissipation insulating layer 40t. It can also be said that a part of the wiring in the semiconductor device 120 is exposed to the outside of the build-up layer 32. In the present embodiment, the front-surface metal layer 50t is provided on the front surface heat dissipation insulating layer 40t. Therefore, the plurality of external connection portions 331 to 337 are exposed from the front surface heat dissipation insulating layer 40t and the front-surface metal layer 50t. In FIG. 76, the first gate pad 332 and the second gate pad 334 are illustrated as an example of the external connection portion.

That is, the front surface heat dissipation insulating layer 40t and the front-surface metal layer 50t are provided with holes to expose the external connection portions 331 to 337. It can also be said that the front surface heat dissipation insulating layer 40t and the front-surface metal layer 50t are provided with holes so that the external connection portions 331 to 337 and terminals of an external device can be electrically connected. The external device is a device provided outside the semiconductor device 120.

Here, a manufacturing method for the semiconductor device 120 will be described with reference to FIG. 77. In the present manufacturing method, the process illustrated in (a) of FIG. 77 is performed after the process illustrated in (b) of FIG. 8. In (a) of FIG. 77, an electrically insulating resin 35a is filled between portions of the patterned pattern wiring 33. Thereafter, in (b) of FIG. 77, the front surface heat dissipation insulating layer 40t and the front-surface metal layer 50t are disposed on the build-up layer 32. As illustrated in (c) of FIG. 77, press molding is performed. The front surface heat dissipation insulating layer 40t may be subjected to patterning (hole formation) to take out the electrode after being joined to the build-up layer 32. Thus, the gap between portions of the pattern wiring can be filled with the resin of the front surface heat dissipation insulating layer 40t. That is, the resin can be provided between portions of the pattern wiring 33 without using the resin 35a.

The semiconductor device 120 can dissipate heat not only from the back-surface metal layer 50 side but also from the front-surface metal layer 50t side. Therefore, the semiconductor device 120 can improve the heat dissipation performance more than the semiconductor device 101.

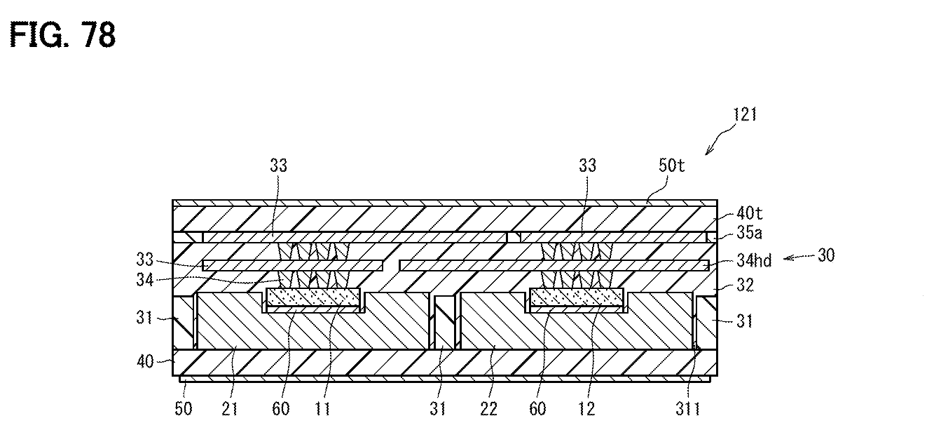

As illustrated in FIG. 78, a semiconductor device 121 may include, in a part of the wiring, a thermal diffusion wiring portion 34hd wider than the heat sinks 21, 22. That is, the length of the thermal diffusion wiring portion 34hd in the planar direction is longer than those of the heat sinks 21, 22.

Thus, in the semiconductor device 121, heat from the semiconductor element 12 is transferred to the thermal diffusion wiring portion 34hd through the via 34. The semiconductor device 121 can diffuse heat through the thermal diffusion wiring portion 34hd.

The semiconductor device 121 is a modification of the semiconductor device 120. The thermal diffusion wiring portion 34hd can also be applied to configurations other than the semiconductor device 121. The configurations other than the semiconductor device 121 are the configurations of the first to thirteenth embodiments and the modifications. The configurations other than the semiconductor device 121 include the configuration of each modification to be described below.

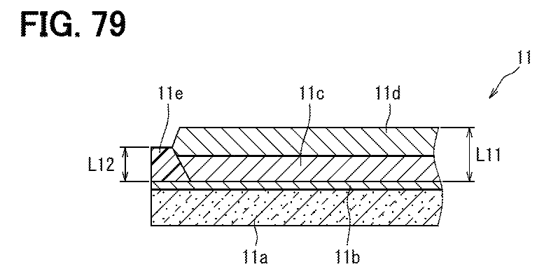

As in the modification illustrated in FIG. 79, in the first semiconductor element 11, an element protective film 11e for protecting the first semiconductor element 11 may be provided around the electrode on the element front surface S12. The element protective film 11e is mainly composed of polyimide or the like. The electrode has, for example, a two-layer structure of a nickel plating layer 11c and a copper plating layer 11d.

The electrode on the element front surface S12 may be higher than the element protective film 11e. The height here is the thickness in the stacking direction. That is, a value obtained by subtracting an element protective film height L12 from an electrode height L11 is 0 or more.

The first semiconductor element 11 is mounted on (joined to) the first heat sink 21 by sintering, using a metal sintered material such as silver or copper as the connection member 60. In sintering, a pressurizing process is required in which the first semiconductor element 11 and the first heat sink 21 are pressurized in a direction approaching each other.

In the pressurizing process, a pressurizing jig comes into contact with element front surface S12 of the first semiconductor element 11. At this time, the pressurizing process may be performed in a state where foreign matter has entered between the pressurizing jig and the element protective film 11e. In this case, the element protective film 11e may be damaged by foreign matter. When the element protective film 11e is damaged, there is a possibility that an electrical defect such as a short circuit occurs in the first semiconductor element 11.

However, since the electrode height L11 and the element protective film height L12 are set in the first semiconductor element 11 as described above, the pressurizing jig is unlikely to come into contact with the element protective film 11e. Therefore, the semiconductor device 120 can suppress an electrical defect.

The configuration of the first semiconductor element 11 can also be applied to configurations other than the semiconductor device 120. The configurations other than the semiconductor device 120 are the configurations of the first to thirteenth embodiments and the modifications. The configurations other than the semiconductor device 120 include the configuration of each modification to be described below. The second semiconductor element 12 may also have a similar configuration.

The solder resist 35 used in the semiconductor device 101 and the like has relatively low heat resistance and a linear expansion coefficient greater than those of other components. Therefore, in the semiconductor device 101, a crack may occur with the solder resist 35 as a starting point. It is also conceivable that the crack of the semiconductor device 101 develops inside the build-up layer 32.

Therefore, in the semiconductor device 101, the solder resist 35 may be made of a material used for the element protective film 11e. That is, the element protective film 11e may cover a part of the portion of the wiring exposed to the outside. As a result, the semiconductor device 101 can suppress occurrence and development of cracks. The solder resist 35 made of a material used for the element protective film 11e can also be applied to configurations other than the semiconductor device 101.

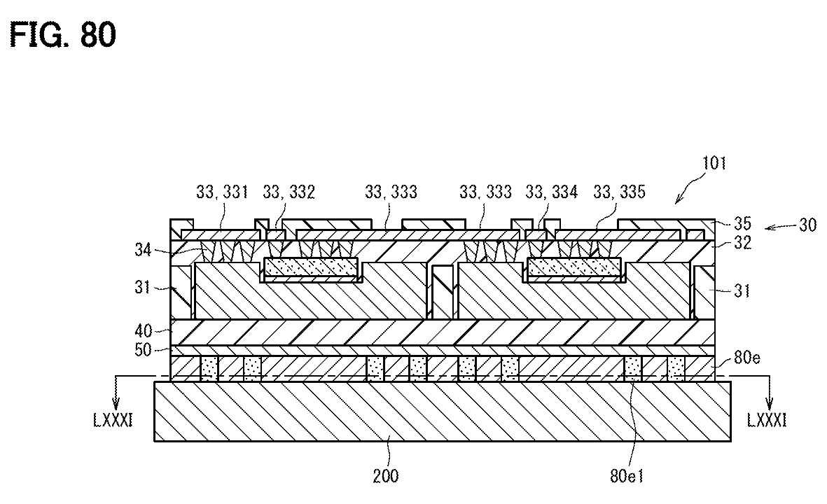

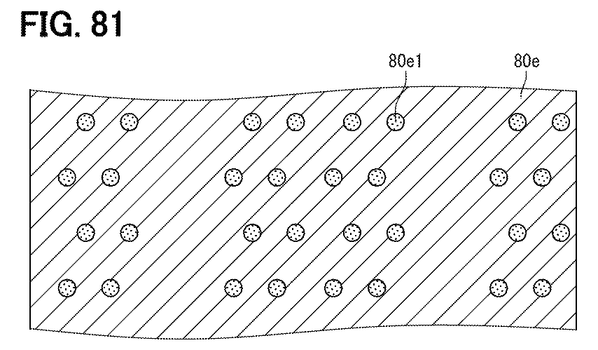

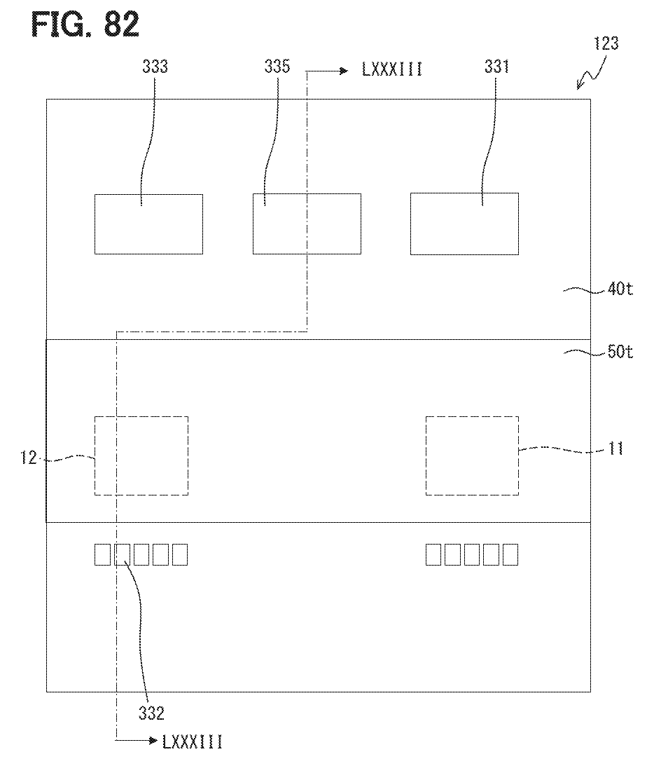

As illustrated in FIGS. 80 and 81, the semiconductor device 101 may be mounted on the cooler 200. A graphite sheet 80e is provided between the semiconductor device 101 and the cooler 200. The graphite sheet 80e is a sheet-shaped member mainly composed of graphite. The graphite sheet 80e is a heat conductive sheet having high thermal conductivity.

An adhesive 80e1 is embedded in the graphite sheet 80e. The adhesive 80e1 is provided to be exposed on both surfaces of the graphite sheet 80e. That is, the adhesive 80e1 is provided over the graphite sheet 80e in the thickness direction. The adhesive 80e1 is preferably provided, for example, around the facing region of the semiconductor elements 11, 12 in the stacking direction. The adhesive 80e1 can be filled in a through-hole formed in the graphite sheet 80e. A graphite sheet not including the adhesive 80e1 is also referred to as a heat conductive sheet.

The heat conductive sheet generally does not include the adhesive 80e1 and does not have an adhesive function. Thus, the heat conductive sheet is used while being pressurized between the back-surface metal layer 50 and the cooler 200 to facilitate contact between the back-surface metal layer 50 and the cooler 200. In addition, the heat conductive sheet is used while being pressurized to reduce thermal resistance between the back-surface metal layer 50 and the cooler 200. For the pressurization, a pressurizing member such as a spring member is used.

However, the graphite sheet 80e includes an adhesive 80e1. Therefore, the graphite sheet 80e easily adheres to the back-surface metal layer 50 and the cooler 200. Therefore, the semiconductor device 101 can bring the back-surface metal layer 50 and the cooler 200 into contact with each other without using a pressurizing member. The semiconductor device 101 can suppress an increase in size because there is no need to use a pressurizing member.

The adhesive 80e1 has lower thermal conductivity than a member mainly composed of graphite. However, in the graphite sheet 80e, the adhesive 80e1 is provided around the facing regions of the semiconductor elements 11, 12. That is, in the graphite sheet 80e, a portion mainly composed of graphite is disposed in the facing region of the semiconductor elements 11, 12. Therefore, the graphite sheet 80e can improve the heat dissipation performance of the semiconductor elements 11, 12 while having an adhesive function. In other words, the graphite sheet 80e can suppress a decrease in heat dissipation performance due to the adhesive 80e1.

Both surfaces of the graphite sheet 80e are two surfaces in the stacking direction. Both surfaces of the graphite sheet 80e correspond to the surfaces of the sheet-shaped member. The thickness direction of the graphite sheet 80e coincides with the stacking direction.

As illustrated in FIG. 82, a semiconductor device 123 includes a P pad 331, an O pad 333, and an N pad 335 that are power connection portions. In addition, the semiconductor device 123 includes signal pads 332 that are signal connection portions. That is, the semiconductor device 123 includes a plurality of power connection portions and a plurality of signal connection portions. The semiconductor device 123 is a modification of the semiconductor device 120.

The P pad 331, the O pad 333, and the N pad 335 are arranged closer to one side wall of the semiconductor device 123. The plurality of signal pads 332 are arranged closer to the other side wall side of the semiconductor device 123. Both side walls are side walls in a facing positional relationship.

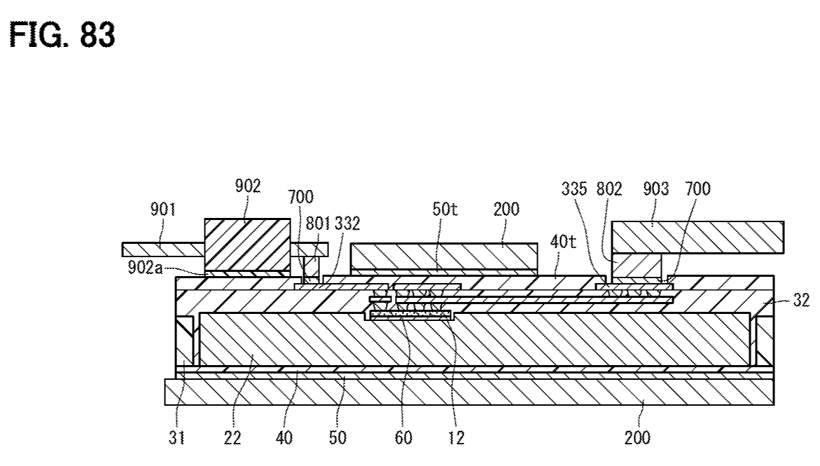

As illustrated in FIGS. 82 and 83, the P pad 331, the O pad 333, the N pad 335, and the plurality of signal pads 332 are spaced apart from each other. The front-surface metal layer 50t is provided among the O pad 333, the N pad 335, and the plurality of signal pads 332. Therefore, in the semiconductor device 123, the cooler 200 can be easily attached not only to the back-surface metal layer 50 side but also to the front-surface metal layer 50t side.

FIG. 83 is a cross-sectional view taken along the section-indicating line of FIG. 82. Moreover, FIG. 83 illustrates the cooler 200, a connector 902, an external power terminal 903, and the like connected to the semiconductor device 123.

The connector 902 includes a plurality of external signal terminals 901. The external signal terminal 901 is electrically connected to the signal pad 332 through a conductive block body 801 and solder 700. That is, the external signal terminals 901 are individually electrically connected to the signal pads 332.

The external power terminal 903 is electrically connected to the N pad 335 through a conductive block body 802 and the solder 700. Similarly, the external power terminal 903 is connected to the P pad 331 and the O pad 333. That is, in the semiconductor device 123, the same number of external power terminals 903 as the power connection portions are connected.

As illustrated in FIG. 83, the heat dissipation insulating layer 40 is thinner than the front surface heat dissipation insulating layer 40t. The back-surface metal layer 50 is thinner than the front-surface metal layer 50t. However, the heat dissipation insulating layer 40 and the front surface heat dissipation insulating layer 40t may have substantially the same thickness. The back-surface metal layer 50 and the front-surface metal layer 50t may have substantially the same thickness.

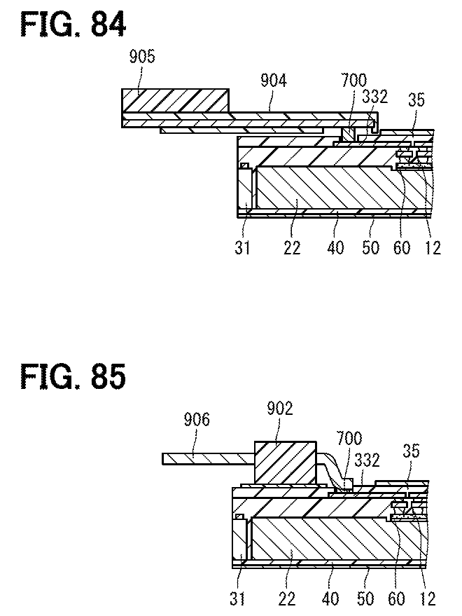

As illustrated in FIG. 84, the semiconductor device 123 may have a flexible substrate 904 connected in place of the connector 902. The flexible substrate 904 is provided with, for example, a reinforcing plate 905.

As illustrated in FIG. 85, the connector 902 includes an external signal terminal 906 including a bent portion. Thus, the connector 902 can be connected to the signal pad 332 through the solder 700 without using the block body 801.

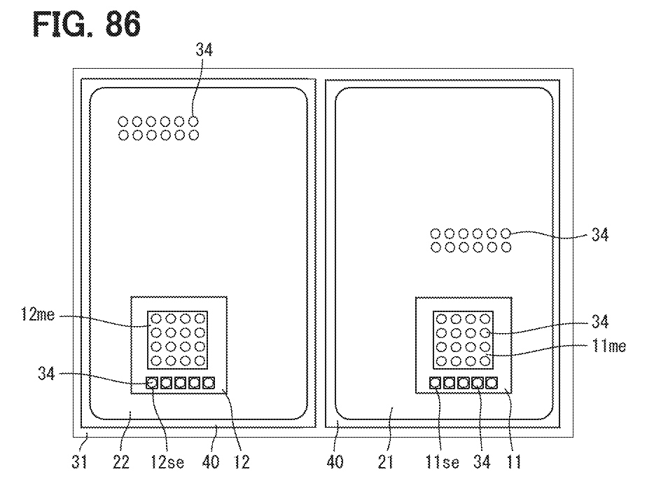

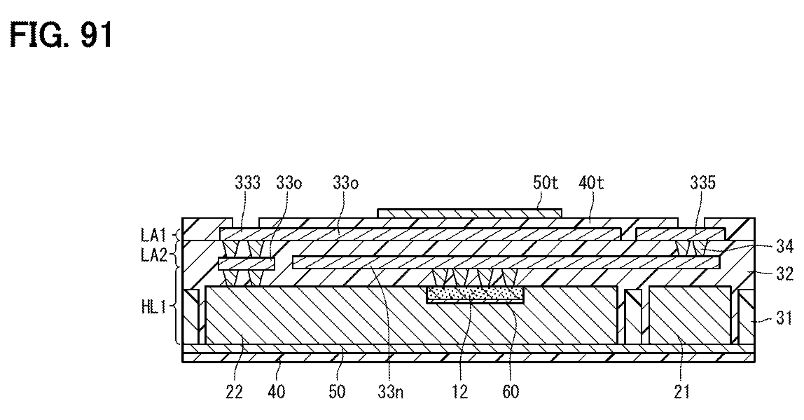

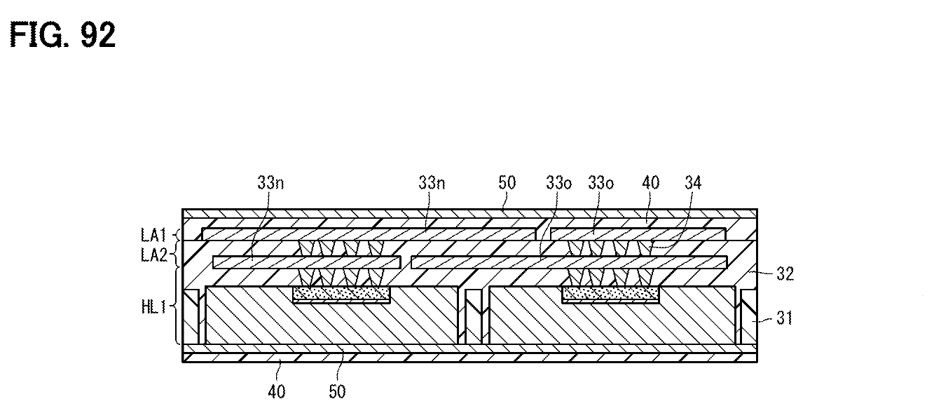

Here, an arrangement example of wiring in a semiconductor device having a double-sided heat dissipation structure such as the semiconductor device 123 will be described. First, one of wiring examples will be described with reference to FIGS. 86 to 92 (first wiring example). FIG. 86 illustrates the heat sink front surfaces S22 of the heat sinks 21, 22 and the element front surfaces S12 of the semiconductor elements 11, 12. In the first wiring example, similarly to the semiconductor device 123, the P pad 331, the O pad 333, and the N pad 335 are arranged closer to one side wall side, and the plurality of signal pads 332 are arranged closer to the other side wall side.

As illustrated in FIG. 86, a via group including a plurality of vias 34 is provided on the heat sink front surface S22. One via group is provided in each of the heat sinks 21, 22. There is a difference in the spacing between the semiconductor element 11 and the via group and between the semiconductor element 12 and the via group. The spacing between the via group and the first semiconductor element 11 is narrower than the spacing between the via group and the second semiconductor element 12.

On the element front surface S12 of the first semiconductor element 11, a source electrode as a main electrode 11me and a plurality of signal electrodes 11se are provided. On the element front surface S12 of the second semiconductor element 12, a source electrode as a main electrode 12me and a plurality of signal electrodes 12se are provided. The signal electrodes 11se, 12se are a gate electrode, a source electrode, a Kelvin source electrode, and the like.

The main electrodes 11me, 12me are provided with a plurality of vias 34. At least one via 34 is provided in each of the signal electrodes 11se, 12se.

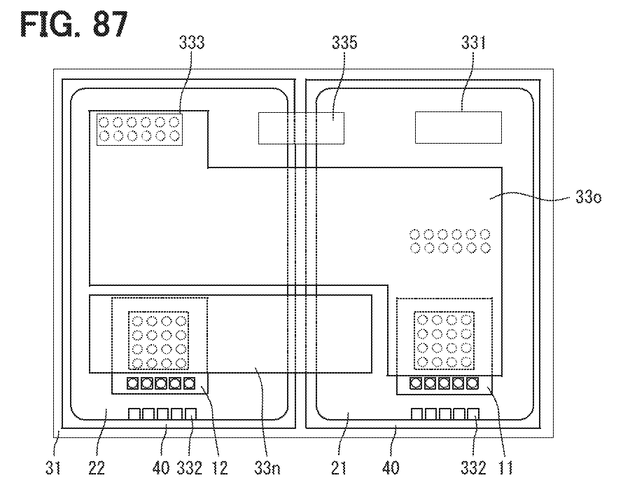

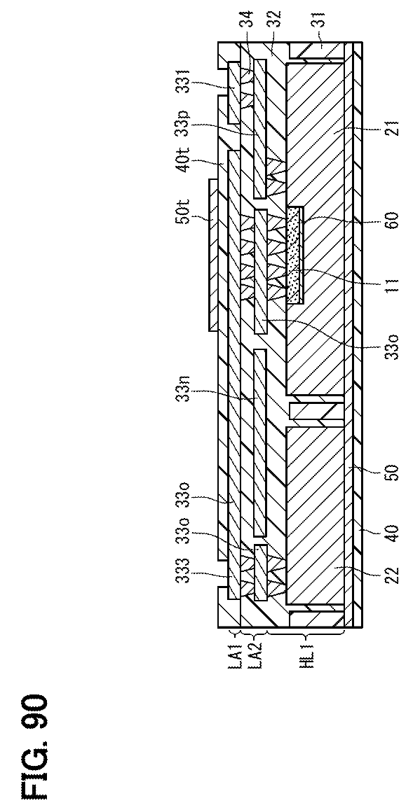

As illustrated in FIG. 87, a first layer LA1 is provided with the P pad 331, the O pad 333, and the N pad 335. The first layer LA1 is provided with an N wiring portion 33n and an O wiring portion 33o. As illustrated in FIG. 90 and the like, the first layer LA1 is a surface wiring layer.

The N wiring portion 33n is provided extending from above the second semiconductor element 12 to above the first heat sink 21. The N wiring portion 33n is connected to the main electrode 12me through the plurality of vias 34. The N wiring portion 33n functions as a thermal diffusion wiring portion by being extended to above the first heat sink 21.

The O wiring portion 33o is provided extending from above the first semiconductor element 11 to above the top of the via group of the second heat sink 22. The O wiring portion 33o is connected to the main electrode 11me through the plurality of vias 34. The O wiring portion 33o is connected to the second heat sink 22 through the via group of the second heat sink 22. The O pad 333 is a part of the O wiring portion 33o.

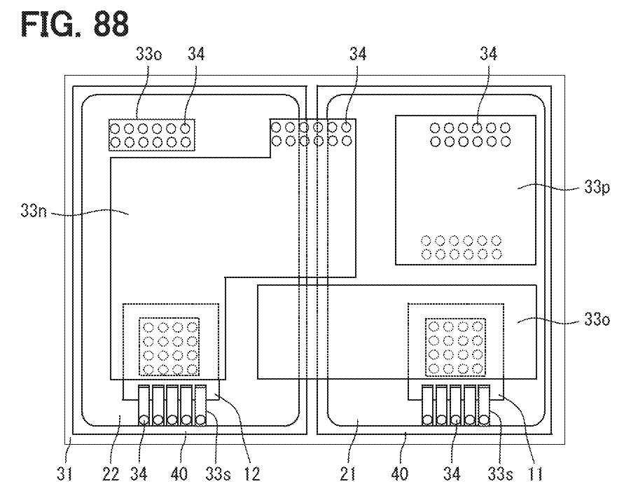

As illustrated in FIG. 88, the second layer LA2 is provided with the N wiring portion 33n, the O wiring portion 33o, and a P wiring portion 33p. The second layer LA2 is provided with a plurality of signal wiring portions 33s. The signal wiring portion 33s includes a first gate wiring portion, a second gate wiring portion, a first Kelvin source wiring portion, and a second Kelvin source wiring portion. As illustrated in FIG. 90 and the like, the second layer LA2 is a second wiring layer from the surface layer.

The N wiring portion 33n is provided extending from above the second semiconductor element 12 to the facing region of the N pad 335. The N wiring portion 33n is connected to the main electrode 12me through the plurality of vias 34. In addition, a plurality of vias for connecting to the N pad 335 are provided on the N wiring portion 33n.

The O wiring portions 33o are provided at two locations. The first O wiring portion 33o is provided extending from above the first semiconductor element 11 to above the second heat sink 22. The O wiring portion 33o is connected to the main electrode 11me through the plurality of vias 34. The O wiring portion 33o functions as a thermal diffusion wiring portion by being extended to above the second heat sink 22.

The second O wiring portion 33o is provided in the facing region of the O pad 333. A plurality of vias 34 for connecting to the O pad 333 are provided on the O wiring portion 33o.

The P wiring portion 33p is provided over the facing region of the via group of the first heat sink 21 and the P pad 331. The P wiring portion 33p is connected to the via group of the first heat sink 21. A plurality of vias 34 for connecting to the P pad 331 are provided on the P wiring portion 33p.

The signal wiring portion 33s extends from above the signal electrodes 11se, 12se. One end of the signal wiring portion 33s is connected to the signal electrodes 11se, 12se through the via 34. The via 34 is provided on the other end of the signal wiring portion 33s.

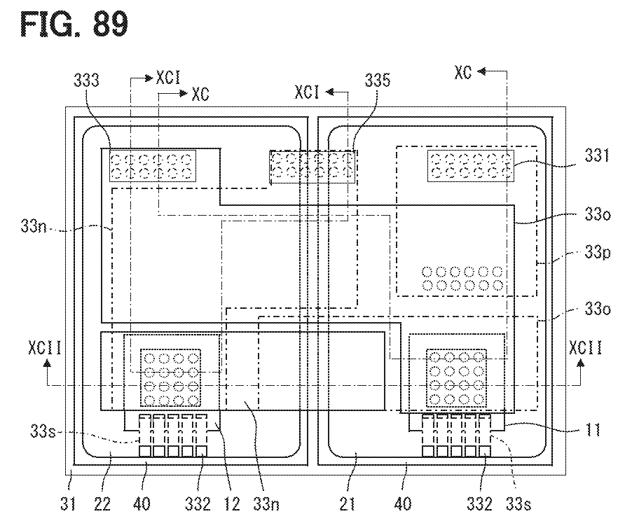

When the heat sinks 21, 22, the first layer LA1, and the second layer LA2 overlap, the wiring portions 33p, 33o, 33n overlap as illustrated in FIG. 89. As illustrated in FIGS. 90, 91, and 92, the O wiring portion 33o and the N wiring portion 33n are arranged in parallel. As a result, the semiconductor device 123 can reduce inductance. Therefore, the semiconductor device 123 enables size reduction and improved switching speed.

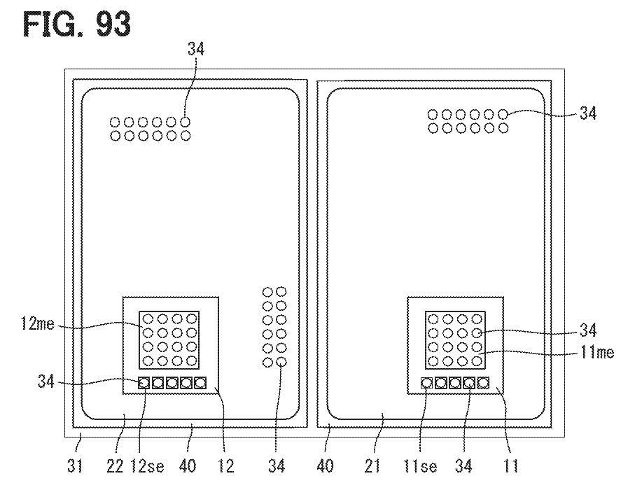

Next, another wiring example will be described with reference to FIGS. 93 to 95 (second wiring example). Here, differences from the first wiring example will be mainly described. In the second wiring example, the first layer LA1 is provided on the heat sinks 21, 22. In the second wiring example, the second layer LA2 is not provided.

As illustrated in FIG. 93, the second heat sink 22 is provided with two via groups. That is, in the second heat sink 22, a via group is also provided between the second semiconductor element 12 and the first semiconductor element 11.

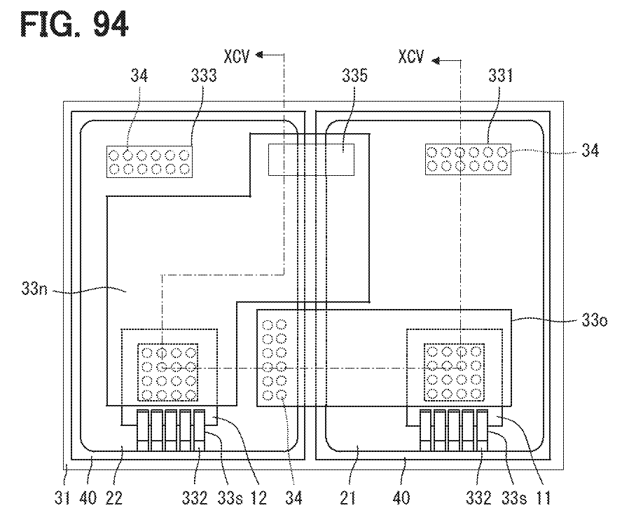

As illustrated in FIG. 94, the first layer LA1 is provided with the N wiring portion 33n and the O wiring portion 33o. The N wiring portion 33n is provided extending from above the second semiconductor element 12 to the facing region of the first heat sink 21. The N wiring portion 33n is connected to the main electrode 12me through the plurality of vias 34. The N wiring portion 33n includes the N pad 335 at a portion spanning the first heat sink 21 and the second heat sink 22.

The O wiring portion 33o is provided extending from above the first semiconductor element 11 to above the second heat sink 22. The O wiring portion 33o is connected to the main electrode 11me through the plurality of vias 34. The O wiring portion 33o functions as a thermal diffusion wiring portion by being extended to above the second heat sink 22. FIG. 94 illustrates wiring in a state where the heat sinks 21, 22 and the first layer LA1 overlap each other.

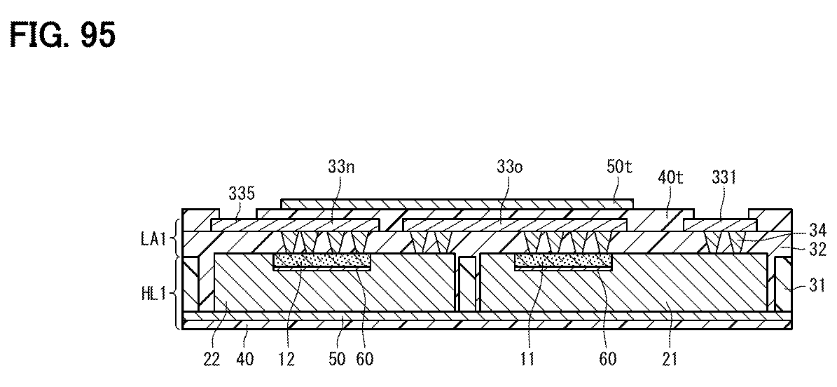

As illustrated in FIG. 95, in the second wiring example, the pattern wiring 33 can be formed with only one layer. Therefore, the semiconductor device 123 can reduce thickness variation. Moreover, the semiconductor device 123 can reduce the number of members of the build-up layer 32.

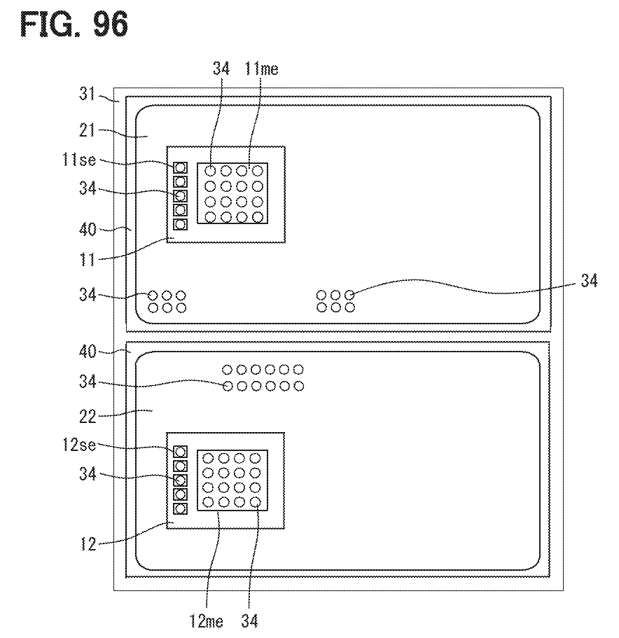

Another wiring example will be described with reference to FIGS. 96 to 101 (third wiring example). Here, differences from the first wiring example will be mainly described.

As illustrated in FIG. 96, a via group including a plurality of vias 34 is provided on the heat sink front surface S22. The first heat sink 21 is provided with two via groups. The second heat sink 22 is provided with one via group.

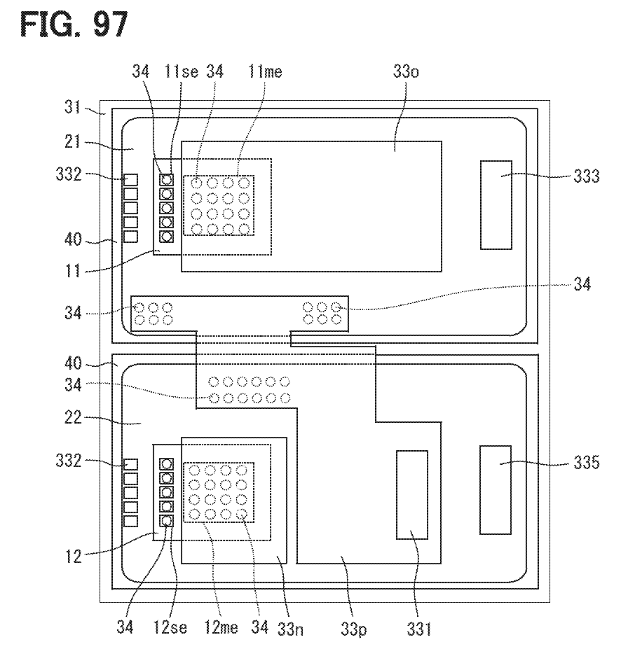

As illustrated in FIG. 97, the first layer LA1 is provided with the P pad 331, the O pad 333, and the N pad 335. The first layer LA1 is provided with the P wiring portion 33p, the O wiring portion 33o, and the N wiring portion 33n.

The N wiring portion 33n is provided on the second semiconductor element 12. The N wiring portion 33n is connected to the main electrode 12me through the plurality of vias 34.

The P wiring portion 33p is provided extending from above the first heat sink 21 to above the second heat sink 22. The P wiring portion 33p is connected to the first heat sink 21 through the plurality of vias 34. The P wiring portion 33p is connected to the second heat sink 22 through the plurality of vias 34. Moreover, in the P wiring portion 33p, the P pad 331 is provided between the N pad 335 and the N wiring portion 33n. That is, in the third wiring example, the P pad 331, the O pad 333, and the N pad 335 are not arranged in a row.

The O wiring portion 33o extends from above the first semiconductor element 11 to the front of the O pad 333. The O wiring portion 33o includes a portion above the first semiconductor element 11 and a portion to be the O pad 333. The O wiring portion 33o is connected to the main electrode 11me through the plurality of vias 34.

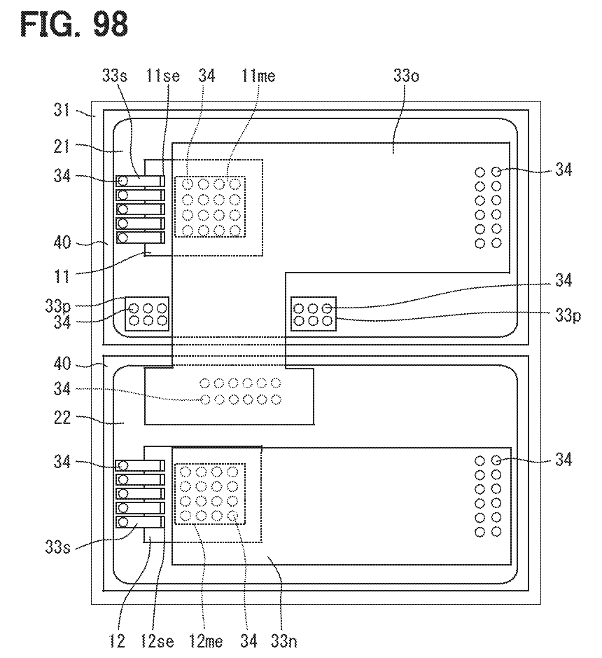

As illustrated in FIG. 98, the second layer LA2 is provided with the N wiring portion 33n, the O wiring portion 33o, and the P wiring portion 33p. The N wiring portion 33n is provided extending from above the second semiconductor element 12 to the facing region of the N pad 335. The N wiring portion 33n is connected to the main electrode 12me through the plurality of vias 34. In addition, a plurality of vias for connecting to the N pad 335 are provided on the N wiring portion 33n.

The O wiring portion 33o is provided extending from the first semiconductor element 11 to the second heat sink 22, and the facing region of the O pad 333. The O wiring portion 33o is connected to the main electrode 11me through the plurality of vias 34. The O wiring portion 33o is connected to the second heat sink 22 through the plurality of vias 34. In addition, a plurality of vias for connecting to the O pad 333 are provided on the O wiring portion 33o.

The P wiring portion 33p is provided to face the P wiring portion 33p in the first layer LA1 in the facing region of the first heat sink 21. The P wiring portions 33p are provided at two locations. That is, the P wiring portions 33p are provided on both sides of the O wiring portions 33o. The P wiring portion 33p is provided with a plurality of vias for connecting to the P wiring portion 33p in the first layer LA1.

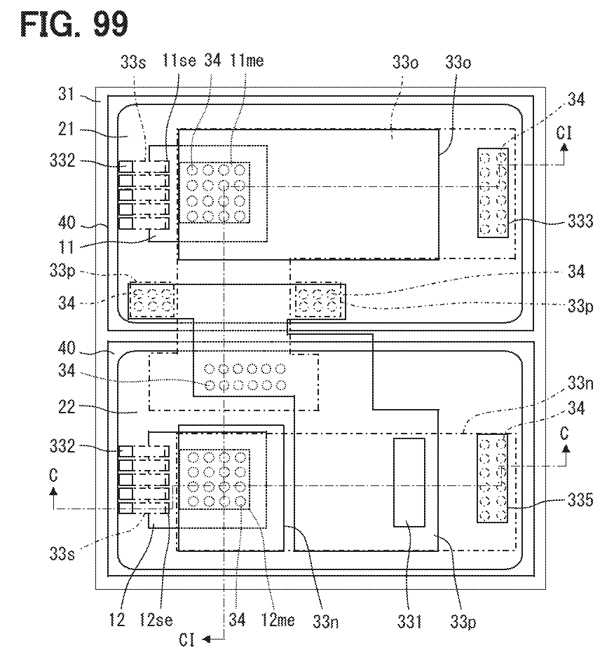

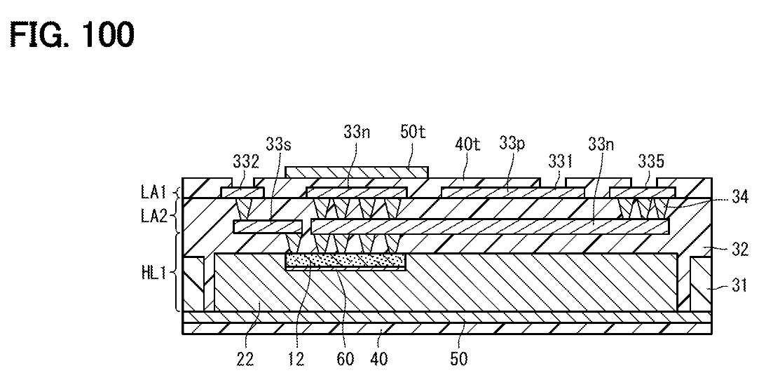

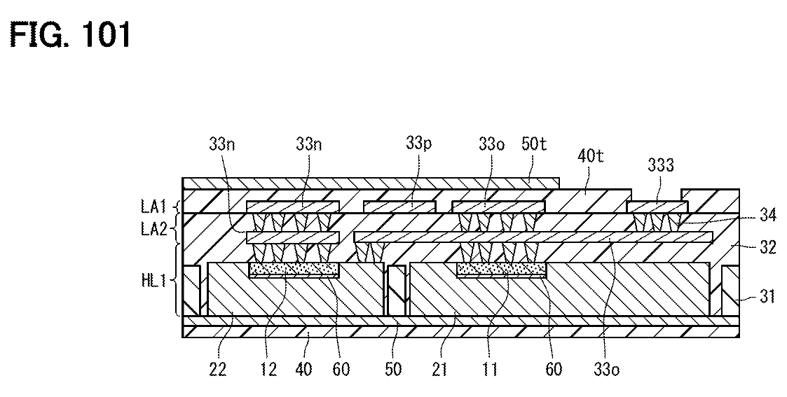

When the heat sinks 21, 22, the first layer LA1, and the second layer LA2 overlap, the wiring portions 33p, 33o, 33n overlap as illustrated in FIG. 99. As illustrated in FIG. 100, the P wiring portion 33p and the N wiring portion 33n are arranged in parallel. As illustrated in FIG. 101, the O wiring portion 33o and the P wiring portion 33p are arranged in parallel. As a result, the semiconductor device 123 can reduce inductance. Therefore, the semiconductor device 123 enables size reduction and improved switching speed. The first to third wiring examples can also be applied to configurations other than the semiconductor device 123.

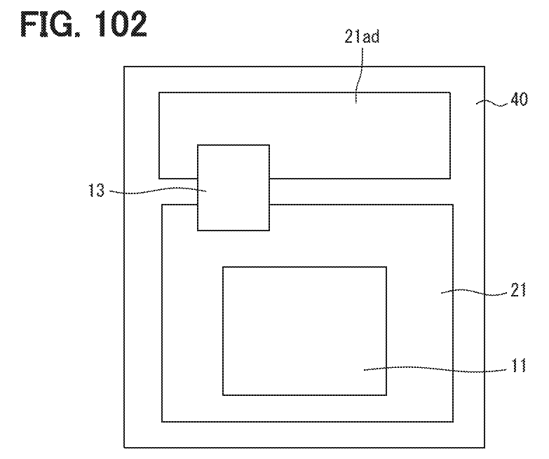

As in the modification illustrated in FIG. 102, in the semiconductor device 117, the first heat sink 21 in which a metal film is patterned and a mounting portion 21ad may be formed on the heat dissipation insulating layer 40. As described above, the semiconductor device 117 can employ the heat sinks 21, 22 and the back-surface metal layer 50 that can be patterned. That is, the first heat sink 21 and the mounting portion 21ad are metal films formed on the same surface of the heat dissipation insulating layer 40. The metal film is mainly composed of a metal such as aluminum or copper. It can also be said that the metal film is divided into a portion functioning as the first heat sink 21 and a portion functioning as the mounting portion 21ad.

This enables mounting of circuit components constituting the semiconductor device 117 on the first heat sink 21 and the mounting portion 21ad. That is, other circuit components can be mounted on the first integrated substrate in addition to the first semiconductor element 11. The circuit components include, for example, a resistive element and a capacitor element. The second integrated substrate can be similarly configured.

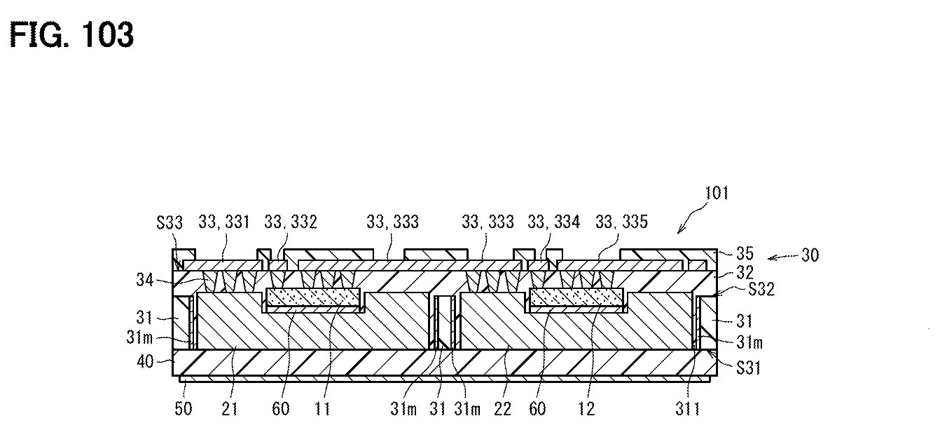

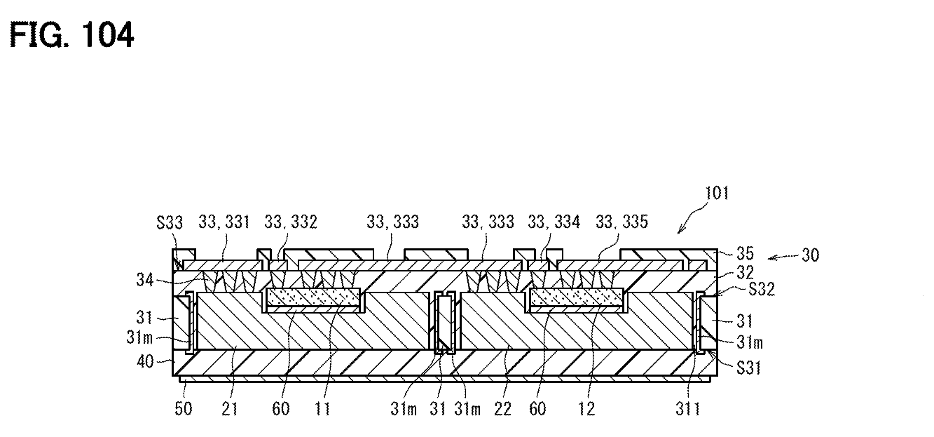

As in the modifications illustrated in FIGS. 103 and 104, the semiconductor device 101 may include a core layer 31 provided with a core plating film 31m. The core plating film 31m is mainly composed of metal. The core plating film 31m is preferably formed of the same material as each of the heat sinks 21, 22. The heat sinks 21, 22 and the core plating film 31m are mainly composed of, for example, copper. The core plating film 31m has a thickness of, for example, about 10 μm to 50 μm. The core plating film 31m corresponds to a wall film.

As illustrated in FIG. 103, the core plating film 31m only needs to be provided on at least the core side surface of the core layer 31. The core side surface is a surface along the stacking direction in the core layer 31. The core side surface is a surface continuous with the core front surface S32 and the core opposite surface S31. The core side surface corresponds to a side surface facing each of the heat sinks 21, 22.

As illustrated in FIG. 104, the core plating film 31m may be provided on the core front surface S32 and the core opposite surface S31. However, the first heat sink 21 and the second heat sink 22 have different potentials. The core layer 31 is also provided between the first heat sink 21 and the second heat sink 22.

Therefore, the core layer 31 between the heat sinks 21, 22 is preferably provided with the core plating film 31m separately on the first heat sink 21 side and the second heat sink 22 side. This makes it easier for the semiconductor device 101 to ensure electrical insulation between the heat sinks 21, 22.

As described above, the resin portion and the heat sinks 21, 22 have a large difference in linear expansion coefficient in the stacking direction. Similarly, the core layer 31 and the heat sinks 21, 22 have a large difference in linear expansion coefficient in the stacking direction. For this reason, stress associated with a difference in linear expansion coefficient tends to be applied to the portion where the resin portion and the heat sinks 21, 22 are in contact with each other. In particular, there is a possibility that cracks or delamination occur at the corner portion 21h1 of the resin portion and the heat sinks 21, 22 due to the stress.

Therefore, the semiconductor device 101 includes the core plating film 31m. The semiconductor device 101 can suppress thermal expansion in the stacking direction of the core layer 31 and the resin portion. Therefore, the semiconductor device 101 can reduce the stress applied to the portion where the resin portion and the heat sinks 21, 22 are in contact with each other. In addition, the semiconductor device 101 can suppress the occurrence of cracks and delamination in the portion where the resin portion and the heat sinks 21, 22 are in contact with each other, such as the corner portion 21h1. The core plating film 31m can also be applied to configurations other than the semiconductor device 101.

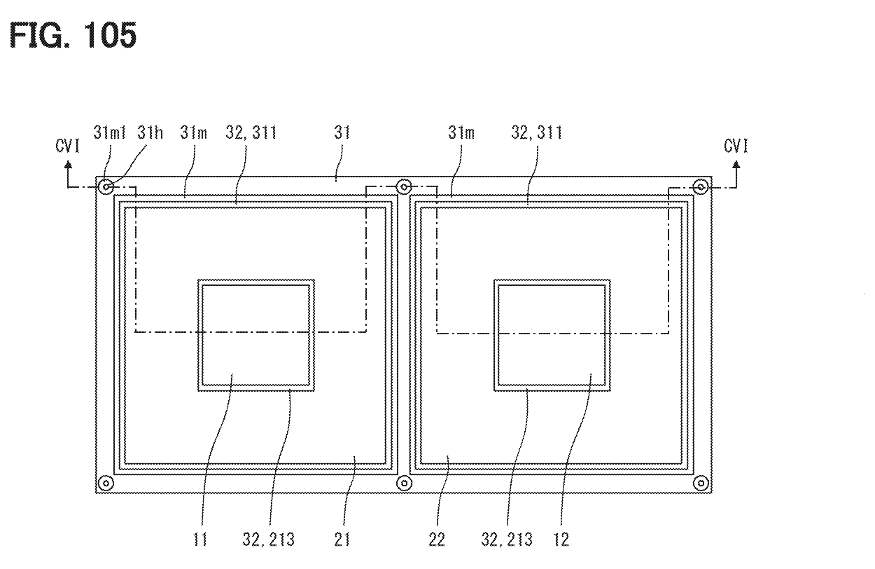

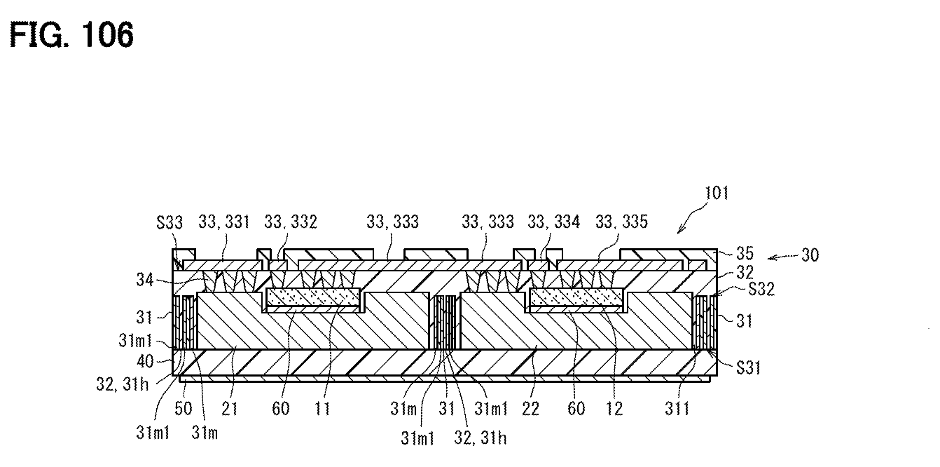

As in the modification illustrated in FIGS. 105 and 106, the semiconductor device 101 may include a core layer 31 provided with a through-plating film 31m1 and a plated through-hole 31h. The core plating film 31m may not be provided.

The core layer 31 is provided with a plated through-hole 31h penetrating from the core front surface S32 to the core opposite surface S31. The through-plating film 31m1 is disposed in the plated through-hole 31h. Here, as an example, the plated through-hole 31h surrounded by the through-plating film 31m1 is employed. The plated through-hole 31h is provided in the stacking direction.

The resin portion of the build-up layer 32 is filled in the through-hole 31h. That is, the through-hole 31h is filled with the resin portion. However, the through-hole 31h may be filled with a resin hole filler different from the resin portion. The resin hole filler is a resin member containing a metal filler. Moreover, the plated through-hole 31h may be filled with the through-plating film 31m1.

The through-plating film 31m1 is made of a material similar to the core plating film 31m. The through-plating film 31m1 has substantially the same thickness as the core plating film 31m. The plated through-hole 31h is provided in a circular shape. The through-plating film 31m1 corresponds to a through-wall film. The plated through-hole 31h corresponds to a metal through-hole.

As illustrated in FIG. 105, the plated through-holes 31h are provided at the four corners of the core layer 31 and at portions between the first heat sink 21 and the second heat sink 22. However, the plated through-holes 31h may be provided only at the four corners of the core layer 31. The plated through-hole 31h may be provided only at a portion facing the side surface S23 of the heat sinks 21, 22.

The plated through-hole 31h is not limited to a circular shape. The plated through-hole 31h may include a bent portion in plan view. For example, the plated through-hole 31h may be provided at the four corners of the core layer 31 and at a portion facing the two side surfaces S23 continuous with the heat sinks 21, 22.

Since the core layer 31 includes the plated through-hole 31h in which the through-plating film 31m1 is disposed, thermal expansion in the stacking direction can be suppressed. As described above, the resin portions of the core layer 31 and the build-up layer 32 have a large difference in linear expansion coefficient from the heat sinks 21, 22 in the stacking direction. The stress due to the difference in linear expansion coefficient tends to increase around the four corners of the core layer 31 and between the heat sinks 21, 22.

Thus, the plated through-holes 31h are preferably provided at the four corners of the core layer 31. That is, the stress applied to the boundary between the resin portion and the heat sinks 21, 22 can be reduced around the four corners of the core layer 31. Therefore, the occurrence of cracks and delamination at the boundaries between the resin portion and the heat sinks 21, 22 can be suppressed around the four corners of the core layer 31.

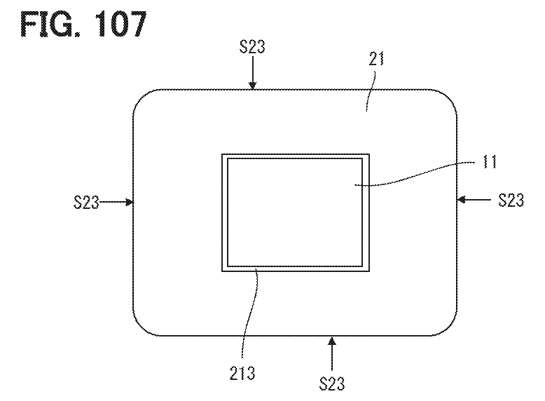

As in the modification illustrated in FIG. 107, the first heat sink 21 may have a shape in which the corner between the two side surfaces S23 is formed as a curved surface. It can also be said that the first heat sink 21 has a shape in which the corner between the two side surfaces S23 is formed with an R-chamfer. The same applies to the second heat sink 22. That is, the heat sinks 21, 22 may each have a shape in which the four corners are formed as curved surfaces. The heat sinks 21, 22 may each have a shape in which the four corners are formed with C-chamfers. That is, the heat sinks 21, 22 may each have a flat surface at the corner between the two side surfaces S23. For example, the semiconductor device 101 can employ a configuration that includes the heat sinks 21, 22 having a curved surface shape at the corners.

This makes it possible to suppress the application of stress associated with a difference in linear expansion coefficient, as described above, to the four corners of the heat sinks 21, 22. Therefore, at the four corners of the heat sinks 21, 22, the occurrence of cracks and delamination at the boundary with the resin portion can be suppressed.

Although the present disclosure has been described in accordance with the embodiments, it is understood that the present disclosure is not limited to the embodiments and structures. The present disclosure encompasses various modifications and modified examples within an equivalent scope. In addition, although various combinations and forms are shown in the present disclosure, other combinations and forms including only one element, more elements, or less than that, are also included in the scope and idea of the present disclosure.

What is claimed is:

1. A semiconductor device comprising:
a semiconductor element;
a heat sink having a front surface on which the semiconductor element is mounted, and a back surface opposite to the front surface;
a core layer having one surface and an opposite surface opposite to the one surface, the core layer being formed with a through-hole extending from the one surface to the opposite surface and in which the heat sink is disposed;
a build-up layer disposed to face the front surface and the one surface, and including a wiring that includes a portion electrically connected to the semiconductor element; and
a heat dissipation insulating layer in contact with the opposite surface and the back surface without passing through a via.

2. The semiconductor device according to claim 1, wherein
the semiconductor element is a vertical semiconductor element,
the semiconductor element has an element facing surface facing the heat sink and an element front surface opposite to the element facing surface, and includes electrodes on both the element facing surface and the element front surface, and
the electrode on the element facing surface is electrically connected to the wiring through the heat sink.

3. The semiconductor device according to claim 1, wherein
the semiconductor element is a lateral semiconductor element,
the semiconductor element has an element facing surface facing the heat sink and an element front surface opposite to the element facing surface,
the semiconductor element includes a plurality of electrodes on the element front surface, and
the element facing surface is electrically connected to one of the plurality of electrodes.

4. The semiconductor device according to claim 3, wherein
the semiconductor element includes a dummy electrode on the element front surface.

5. The semiconductor device according to claim 3, further comprising:
an element protective film disposed around the electrode on the element front surface to protect the semiconductor element, wherein
the electrode on the element front surface is higher than the element protective film.

6. The semiconductor device according to claim 5, wherein
a part of the wiring is exposed to an outside of the build-up layer, and
the element protective film partially covers the part of the wiring exposed to the outside.

7. The semiconductor device according to claim 1, wherein
a relative permittivity of the build-up layer is smaller than a relative permittivity of the heat dissipation insulating layer.

8. The semiconductor device according to claim 1, comprising:
two of the semiconductor elements; and
two of the heat sinks on which the two semiconductor elements are individually mounted, wherein
the core layer is formed with two of the through holes in which the two heat sinks are individually disposed, and
the wiring electrically connects the two semiconductor elements.

9. The semiconductor device according to claim 1, wherein
the wiring includes a layer wiring disposed on a layer front surface of the build-up layer, and
the layer wiring includes a main wiring electrically connected to the semiconductor element, and a dummy wiring disposed around the main wiring and electrically connected to a ground.

10. The semiconductor device according to claim 1, wherein
the heat sink is formed with a recess recessed relative to the front surface,
the semiconductor element is mounted in the recess through a connection member, and
a depth of the recess is shallower than a sum of a thickness of the semiconductor element and a thickness of the connection member.

11. The semiconductor device according to claim 10, wherein
an opening area of the recess of the heat sink increases stepwise.

12. The semiconductor device according to claim 1, wherein
the heat sink has a plurality of side surfaces continuous with the back surface,
the heat sink is formed with a groove-shaped recess extending between two of the side surfaces, and
the semiconductor element is mounted in the groove-shaped recess.

13. The semiconductor device according to claim 1, wherein
the semiconductor element is mounted on the heat sink through a connection member,
the heat sink has a silver plating layer disposed on the front surface of the heat sink, and
the connection member is a silver sintered material.

14. The semiconductor device according to claim 13, wherein
the silver plating layer is porous.

15. The semiconductor device according to claim 2, wherein
the heat sink has a plate shape, and
the semiconductor device further comprises a terminal member that is mounted on the front surface and electrically connects the heat sink and the wiring.

16. The semiconductor device according to claim 2, wherein
the heat sink includes a mounting portion on which the semiconductor element is mounted, and a groove portion provided around the mounting portion.

17. The semiconductor device according to claim 1, wherein
the heat dissipation insulating layer is formed with irregularities, and
a heat-dissipating spring member is attached to the irregularities.

18. The semiconductor device according to claim 1, wherein
a plurality of the semiconductor elements having the same configuration are mounted on one heat sink, and
the plurality of semiconductor elements are connected in parallel through the wiring.

19. The semiconductor device according to claim 1, wherein
the semiconductor element and a circuit element different from the semiconductor element are mounted on one heat sink, and
the semiconductor element and the circuit element are connected in parallel through the wiring.

20. The semiconductor device according to claim 1, wherein
the heat dissipation insulating layer contains a filler and an electrically insulating resin without containing glass fiber.

21. The semiconductor device according to claim 1, wherein
in the heat sink, a corner portion between the back surface and a side surface continuous with the back surface has a chamfered shape.

22. The semiconductor device according to claim 1, wherein
the build-up layer is provided with a floating conductor layer between the wiring and the heat sink.

23. The semiconductor device according to claim 1, wherein
the heat dissipation insulating layer includes a heat dissipation insulating adhesive layer in contact with the back surface.

24. The semiconductor device according to claim 23, wherein
the heat dissipation insulating layer is formed with a positioning recess in which the heat sink is disposed.

25. The semiconductor device according to claim 3, wherein
the semiconductor element is provided with a polyamide layer around the plurality of electrodes on at least the element front surface.

26. The semiconductor device according to claim 1, wherein
the build-up layer includes, above the heat sink, a first resin layer without containing glass cloth and a second resin layer containing the glass cloth.

27. The semiconductor device according to claim 1, wherein
a fiber filler is embedded in the build-up layer.

28. The semiconductor device according to claim 1, wherein
the core layer is covered with resin of the build-up layer.

29. The semiconductor device according to claim 1, wherein
the core layer is formed with the through-hole having an opening area that increases stepwise from a side of the heat dissipation insulating layer, and
the heat sink is in contact with a portion of the core layer having the narrowest opening area.

30. The semiconductor device according to claim 1, further comprising a front surface heat dissipation insulating layer in contact with the build-up layer.

31. The semiconductor device according to claim 30, further comprising a front-surface metal layer in contact with a surface of the front surface heat dissipation insulating layer opposite to the build-up layer.

32. The semiconductor device according to claim 30, wherein
the wiring includes a plurality of external connection portions exposed from the front surface heat dissipation insulating layer.

33. The semiconductor device according to claim 31, wherein
the wiring includes a signal connection portion and a power connection portion, and
the front-surface metal layer is disposed between the signal connection portion and the power connection portion.

34. The semiconductor device according to claim 30, wherein
the wiring includes a thermal diffusion wiring portion wider than the heat sink.

35. A semiconductor device comprising:
a plurality of semiconductor elements;
a plurality of heat sinks provided for the respective semiconductor elements and each having a front surface on which a corresponding semiconductor element is mounted and a back surface opposite to the front surface;
a plurality of heat dissipation insulating layers provided for the respective heat sinks and each being in contact with the back surface of a corresponding heat sink without passing through a via;
a plurality of back-surface metal layers each being in contact with a surface of a corresponding heat dissipation insulating layer opposite to the corresponding heat sink;
a core layer having one surface and an opposite surface opposite to the one surface and being formed with a plurality of through-holes extending from the one surface to the opposite surface, wherein a set of the semiconductor element, the heat sink, the heat dissipation insulating layer, and the back-surface metal layer is disposed in each of the through-holes; and
a build-up layer disposed to face the front surfaces and the one surface, and including a wiring that includes a portion electrically connected to the corresponding semiconductor element.

36. The semiconductor device according to claim 35, wherein
the heat dissipation insulating layer is disposed to project relative to a heat sink side surface of the heat sink and a back-surface metal layer side surface of the back-surface metal layer.

37. The semiconductor device according to claim 36, wherein
at least one of the heat sink side surface and the back-surface metal layer side surface is provided with an insulating member.

38. The semiconductor device according to claim 36, wherein
a direction in which the semiconductor element is stacked on the heat sink is defined as a stacking direction, and
the core layer includes a core projection that projects in a direction intersecting the stacking direction and is disposed in the stacking direction relative to the heat dissipation insulating layer.

39. The semiconductor device according to claim 35, wherein
the heat sink is composed of copper as a main component.

40. The semiconductor device according to claim 1, wherein
the wiring includes a high-potential-side wiring portion connected to a high-potential-side electrode of the semiconductor element, a low-potential-side wiring portion connected to a low-potential-side electrode of the semiconductor element, and heat-dissipating wiring disposed at least between the high-potential-side wiring portion and the low-potential-side wiring portion, and
the heat-dissipating wiring is connected to the heat sink.

41. The semiconductor device according to claim 1, wherein
the heat sink and the heat dissipation insulating layer are each formed with a positioning hole penetrating in a thickness direction.

42. The semiconductor device according to claim 1, wherein
the core layer includes a resin having an isotropic thermal expansion coefficient.

43. The semiconductor device according to claim 1, wherein
the heat sink is formed with a heat sink protrusion on a surface facing the core layer.

44. The semiconductor device according to claim 1, wherein
the heat sink is formed with a heat sink recess on a surface facing the core layer.

45. The semiconductor device according to claim 1, wherein
the semiconductor device is to be mounted on a cooler that is disposed on a heat dissipation insulating layer side, and
the semiconductor device further comprises, between the semiconductor device and the cooler, a heat dissipation connection member that is a sheet-shaped member composed of graphite as a main component and has an adhesive exposed on a surface of the sheet-shaped member.

46. The semiconductor device according to claim 28, further comprising a wall film composed of a metal as a main component and disposed on at least a side surface of the core layer facing the heat sink.

47. The semiconductor device according to claim 46, wherein
the core layer includes a metal through-hole that penetrates from the one surface to the opposite surface and in which a through-wall film composed of a metal as a main component is disposed.
